(19) United States
(12) Patent Application Publication
(10) Pub. No.: US 2026/0016756 A1
(43) Pub. Date: Jan. 15, 2026

(54) IMAGING EUV OPTICAL UNIT FOR IMAGING AN OBJECT FIELD INTO AN IMAGE FIELD

(71) Applicant: Carl Zeiss SMT GmbH, Oberkochen (DE)

(72) Inventor: Alexander WOLF, Essingen (DE)

(21) Appl. No.: 19/338,195

(22) Filed: Sep. 24, 2025

Related U.S. Application Data
(63) Continuation of application No. PCT/EP2024/058978, filed on Apr. 3, 2024.

(30) Foreign Application Priority Data
Apr. 6, 2023 (DE) 10 2023 203 224.4

(51) Int. Cl. G03F 7/00; G02B 5/08; G02B 19/00

(52) U.S. Cl. CPC G03F 7/70233; G02B 5/0891; G02B 19/0023; G02B 19/0095; G03F 7/70033; G03F 7/702; G03F 7/70316

(57) ABSTRACT

An imaging EUV optical unit serves images an object field into an image field. The imaging optical unit has a plurality of mirrors for guiding EUV imaging light along an imaging beam path. The plurality of the mirrors includes at least two normal incidence mirrors and at least one grazing incidence mirror. The last two mirrors in the imaging beam path are normal incidence mirrors and lack an imaging light passage opening. A reflection surface of an antepenultimate mirror in the imaging beam path faces the last mirror in the imaging beam path. This EUV optical unit can have improved usability for an EUV projection exposure apparatus.

### CROSS-REFERENCE TO RELATED APPLICATIONS

The present application is a continuation of, and claims benefit under 35 USC 120 to, international application No. PCT/EP2024/058978, filed Apr. 3, 2024, which claims benefit under 35 USC 119 of German Application No. 10 2023 203 224.4, filed Apr. 6, 2023. The entire disclosure of each of these applications is incorporated by reference herein.

### FIELD

The disclosure relates to an imaging EUV optical unit for imaging an object field into an image field. Further, the disclosure relates to an optical system having such an imaging optical unit, a projection exposure apparatus having such an optical system, a method for producing a micro- or nanostructured component using such a projection exposure apparatus, and a micro- or nanostructured component produced by the method.

### BACKGROUND

Projection optical units of the type set forth at the outset are known from, for example,
WO 2018/010 960 A1, DE 10 2015 209 827 A1, DE 10 2012 212 753 A1, US 2010/0149509 A1,
U.S. Pat. No. 4,964,706, DE 10 2008 033 341 A1 and DE 10 2011 076 752 A1.

### SUMMARY

The present disclosure seeks to develop an imaging EUV optical unit with improved usability thereof for an EUV projection exposure apparatus.

In an aspect, the disclosure provides an imaging EUV optical unit for imaging an object field into an image field. The imaging EUV optical unit has a plurality of mirrors for guiding EUV imaging light at a wavelength of shorter than 30 nm along an imaging beam path from the object field towards the image field. The plurality of mirrors comprises at least two normal incidence (NI) mirrors and at least two grazing incidence (GI) mirrors. The penultimate mirror in the imaging beam path is an NI mirror. The penultimate mirror in the imaging beam path lacks a passage opening for the imaging light. The last mirror in the imaging beam path is an NI mirror. The last mirror in the imaging beam path lacks a passage opening for the imaging light. A reflection surface of an antepenultimate mirror in the imaging beam path faces the last mirror in the imaging beam path.

According to the disclosure, it was recognised that an optical design of the imaging EUV optical unit in which an antepenultimate mirror in the imaging beam path has a reflection surface facing a last mirror leads to the possibility of guiding an imaging beam path around the last mirror in the imaging beam path while simultaneously ensuring a compact structure of the imaging EUV optical unit. This can be desirable because the last mirror, which determines the image-side numerical aperture of the imaging EUV optical unit, regularly has a large embodiment and guidance of the imaging beam path around this mirror saves installation space.

The reflection surface of the antepenultimate mirror faces the last mirror in the imaging beam path if it is possible to draw a direct line of sight, which is not shadowed by a main body of the antepenultimate mirror, from at least one point on the reflection surface of the antepenultimate mirror, and for example from all points of the reflection surface of the antepenultimate mirror used for reflecting the EUV imaging light, to the last mirror. This line of sight need not run directly to a point on the reflection surface of the last mirror but can also run to a main body of the last mirror in the imaging beam path.

The imaging EUV optical unit may have an image-side numerical aperture of less than 0.5 such as less than 0.4. The image-side numerical aperture may be greater than 0.25, such as greater than 0.3.

A mean wavefront aberration RMS may be less than 200 mλ (λ: wavelength of the used light), may be less than 100 mλ and may also be less than 50 mλ. This wavefront aberration RMS is regularly greater than 5 mλ.

The object field of the imaging EUV optical unit may be located in an object plane. The image field of the imaging EUV optical unit may be located in an image plane. The object plane may extend parallel to the image plane. The object plane may extend relative to the image plane at an angle which differs from 0°.

The GI mirrors can be directly in succession in the imaging beam path. The GI mirrors can amplify their deflection effect for the EUV imaging light.

Alternatively, at least one NI mirror may also be present between two GI mirrors.

The imaging EUV optical unit can have an overall transmission of the plurality of mirrors for the EUV imaging light of greater than 10%. For a given EUV used light source power, such an EUV overall transmission allows an increased EUV throughput to the image field, and hence an improved exposure power. Alternatively, for a given, desired exposure power on the image field, it is possible to use a reduced power source.

An object-image offset between a central object field point and a central image field point perpendicular to a normal of the object plane can be less than a distance between the object field and the image field. Such an imaging EUV optical unit can be designed compactly.

The object-image offset can be less than 75%, such as less than 50%, for example less than 40%, for example less than 30%, for example less than 25%, for example less than 20%, for example less than 10%, of the distance between the object field and the image field.

At least one intermediate image in at least one imaging light plane can contain a chief ray of a central field point, with the at least one GI mirror having a distance to the intermediate image along the imaging beam path which is less than 10% of a distance between the object field and the image field. Such a distance ratio can help enable a compact embodiment of the GI mirror arranged in the vicinity of the intermediate image. This GI mirror, which is adjacent to the intermediate image by at most one tenth of the field distance, can be the antepenultimate mirror of the imaging EUV optical unit. This distance ratio may apply to all GI mirrors of the imaging EUV optical unit.

The distance of the at least one GI mirror from the intermediate image along the imaging beam path can be less than 8%, such as less than 6%, for example less than 5%, for example less than 4%, for example less than 3%, for example less than 2%, on the order of 1%, of the distance between the object field and the image field.

The imaging EUV optical unit can be embodied as a choristikonal-type optical unit with a different number of intermediate images in the two imaging light planes. The difference between the number of intermediate images in the two imaging light planes can be exactly 1; however, it may also be larger, for example 2 or even larger than that. In this context of a choristikonal-type optical unit, reference is made to U.S. Pat. No. 10,656,400 B2.

The at least one intermediate image can be a real intermediate image or a virtual intermediate image. The imaging EUV optical unit may also comprise a plurality of real and/or virtual intermediate images.

The imaging EUV optical unit can comprise exactly one intermediate image.

The penultimate mirror and the last mirror can add in terms of their deflection effect for a chief ray of a central object field point. Such an addition of deflection angles was found to be a particularly suitable design variant in the context of turning the reflection surface of the antepenultimate mirror to face the last mirror.

The imaging EUV optical unit may include at least four NI mirrors and/or exactly two GI mirrors. Such numbers of mirrors were found to be particularly suitable. The imaging EUV optical unit may comprise exactly four NI mirrors.

The intermediate image can be located in a meridional plane of the imaging EUV optical unit, with the intermediate image having a spatial distance from the last mirror which is less than 60% of a maximum extent of the last mirror in the meridional plane. Such a distance of the intermediate image from the last mirror can help enable a compact guidance of the imaging beam path past the last mirror. The spatial distance between the intermediate image and the last mirror can be less than 50%, such as less than 40%, for example less than 30%, for example less than 25%, for example less than 20%, for example less than 15%, on the order of 10%, of the maximum extent of the last mirror in the meridional plane.

An image plane of the imaging optical unit in the imaging beam path perpendicular to the meridional plane can be the first field plane downstream of an object plane of the imaging optical unit. In such an embodiment, the imaging EUV optical unit does not have an intermediate image perpendicular to the meridional plane. Thus, there is choristikonal-type imaging within the meaning of U.S. Pat. No. 10,656,400 B2. There is an image flip in the sagittal plane perpendicular to the meridional plane.

The overall transmission of the imaging EUV optical unit may be greater than 10%, such as greater than 11%, for example greater than 12%, for example greater than 13%, for example greater than 14%, for example greater than 15%. On account of the number of mirrors and an individual EUV transmission of a mirror that guides the imaging light, which is regularly no more than 80%, the overall transmission is regularly less than 20%.

The image field of the imaging optical unit can have a maximum extent in the image plane of greater than 26 mm. Such an image field can help enable a high imaging throughput. In the image plane, the image field can have a maximum extent which is more than 30 mm, such as more than 35 mm, for example more than 40 mm, for example more than 45 mm, for example more than 50 mm. The maximum extent can also be of the order of 52 m.

The features of a corresponding optical system, projection exposure apparatus, production method, and/or microstructured or nanostructured can correspond to those which were explained above with reference to the projection optical unit according to the disclosure.

The EUV light source of the projection exposure apparatus may be designed so as to result in a used wavelength of no more than 13.5 nm, such as less than 13.5 nm, for example less than 10 nm, for example less than 8 nm, for example less than 7 nm, 6.7 nm, 6.9 nm. A used wavelength of less than 6.7 nm and, for example, of the order of 6 nm is also possible.

A semiconductor component, for example a memory chip, can be produced using the projection exposure apparatus.

### BRIEF DESCRIPTION OF THE DRAWINGS

Below, at least one exemplary embodiment of the disclosure is described on the basis of the drawings, in which:

FIG. 1 schematically shows a meridional section of a projection exposure apparatus for EUV projection lithography;

FIGS. 2 to 5 show, in each case in a meridional section, embodiments of an imaging optical unit which is used as a projection lens in the projection exposure apparatus according to FIG. 1, wherein an imaging beam path for chief rays and for an upper coma ray and a lower coma ray of three selected field points is depicted;

FIG. 6 shows a view of the imaging optical unit according to FIG. 5, as seen from the viewing direction VI in FIG. 5;

FIGS. 7 and 8 show, in each case in a meridional section, embodiments of an imaging optical unit which is used as a projection lens in the projection exposure apparatus according to FIG. 1, wherein an imaging beam path for chief rays and for an upper coma ray and a lower coma ray of three selected field points is depicted, and

FIG. 9 shows, in a meridional section, a further embodiment of an imaging optical unit which is used as a projection lens in the projection exposure apparatus according to FIG. 1, wherein an imaging beam path for selected individual rays of exactly one field point is depicted.

### DETAILED DESCRIPTION

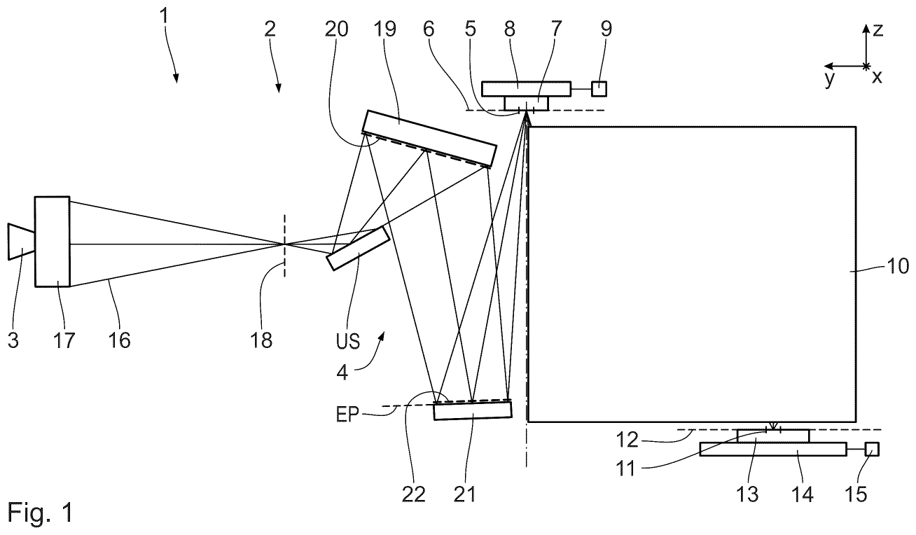

In the following text, certain components of a microlithographic projection exposure apparatus 1 are described first by way of example with reference to FIG. 1. The description of the basic structure of the projection exposure apparatus 1 and its components should not be construed as limiting here.

One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

A Cartesian xyz-coordinate system is shown in FIG. 1 for explanation purposes. The x-direction runs perpendicular to the plane of the drawing into the latter. The y-direction runs horizontally and the z-direction runs vertically. The scanning direction runs in the y-direction in FIG. 1. The z direction runs perpendicularly to the object plane 6.

The projection exposure apparatus 1 comprises a projection optical unit or imaging optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits EUV radiation 16 for example, which is also referred to below as used radiation or illumination radiation. For example, the used radiation has a wavelength in the range of between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 may be a collector with one or more ellipsoidal and/or hyperboloidal reflection surfaces. The illumination radiation 16 can be incident on the at least one reflection surface of the collector 17 with grazing incidence (GI), that is to say at angles of incidence of greater than 45°, or with normal incidence (NI), that is to say at angles of incidence of less than 45°. The collector 17 may be structured and/or coated on the one hand for optimizing its reflectivity for the used radiation and on the other hand for suppressing stray light.

The illumination radiation 16 propagates through an intermediate focus in an intermediate focal plane 18 downstream of the collector 17. The intermediate focal plane 18 can represent a separation between a radiation source module, comprising the radiation source 3 and the collector 17, and the illumination optical unit 4.

The illumination optical unit 4 comprises a first facet mirror 19. If the first facet mirror 19 is arranged in a plane of the illumination optical unit 4 which is optically conjugate to the object plane 6, then this facet mirror is also referred to as a field facet mirror. The first facet mirror 19 comprises a multiplicity of individual first facets 20, which are also referred to below as field facets. Only a few of these facets are illustrated in FIG. 1 in exemplary fashion.

The first facets 20 may be embodied as macroscopic facets, for example as rectangular facets or as facets with an arcuate edge contour or an edge contour of part of a circle. The first facets 20 may be embodied as plane facets or alternatively as facets with convex or concave curvature.

As known for example from DE 10 2008 009 600 A1, the first facets 20 themselves may also be composed in each case of a multiplicity of individual mirrors, for example a multiplicity of micromirrors. The first facet mirror 19 may for example be formed as a microelectromechanical system (MEMS system). For details, reference is made to DE 10 2008 009 600 A1.

A deflection mirror US, which may be embodied as a plane mirror but which may alternatively also have a beam shaping effect, is located in the beam path of the illumination optical unit 4, between the intermediate focus in the intermediate focal plane 18 and the first facet mirror 19.

In the beam path of the illumination optical unit 4, a second facet mirror 21 is arranged downstream of the first facet mirror 19. If the second facet mirror 21 is arranged in a pupil plane of the illumination optical unit 4, it is also referred to as a pupil facet mirror. The second facet mirror 21 may also be arranged at a distance from a pupil plane of the illumination optical unit 4. In this case, the combination of the first facet mirror 19 and the second facet mirror 21 is also referred to as a specular reflector. Specular reflectors are known from US 2006/0132747 A1, EP 1 614 008 B1, and U.S. Pat. No. 6,573,978.

The second facet mirror 21 comprises a plurality of second facets 22. In the case of a pupil facet mirror, the second facets 22 are also referred to as pupil facets.

The second facets 22 may likewise be macroscopic facets, which may for example have a round, rectangular or else hexagonal boundary, or may alternatively be facets composed of micromirrors. In this regard, reference is likewise made to DE 10 2008 009 600 A1.

The second facets 22 may have plane reflection surfaces or alternatively reflection surfaces with convex or concave curvature.

The illumination optical unit 4 consequently forms a doubly faceted system. This fundamental principle is also referred to as a fly's eye condenser (fly's eye integrator).

It may be desirable to arrange the second facet mirror 21 not exactly in a plane that is optically conjugate to a pupil plane of the projection optical unit 10. For example, the pupil facet mirror 22 can be arranged so as to be tilted relative to a pupil plane of the projection optical unit 10, as is described, for example, in DE 10 2017 220 586 A1.

The individual first facets 20 are imaged into the object field 5 with the aid of the second facet mirror 21 and optionally with the aid of an imaging optical assembly in the form of a transfer optical unit, which is not depicted in FIG. 1.

The transfer optical unit may have exactly one mirror, or alternatively have two or more mirrors, which are arranged one behind the other in the beam path of the illumination optical unit 4. The transfer optical unit may for example comprise one or two normal-incidence mirrors (NI mirrors) and/or one or two grazing-incidence mirrors (GI mirrors). The illumination optical unit 4 has exactly three mirrors in the embodiment shown in FIG. 1, that is to say downstream of the collector 17, specifically the deflection mirror US, the first facet mirror 19, and the second facet mirror 21.

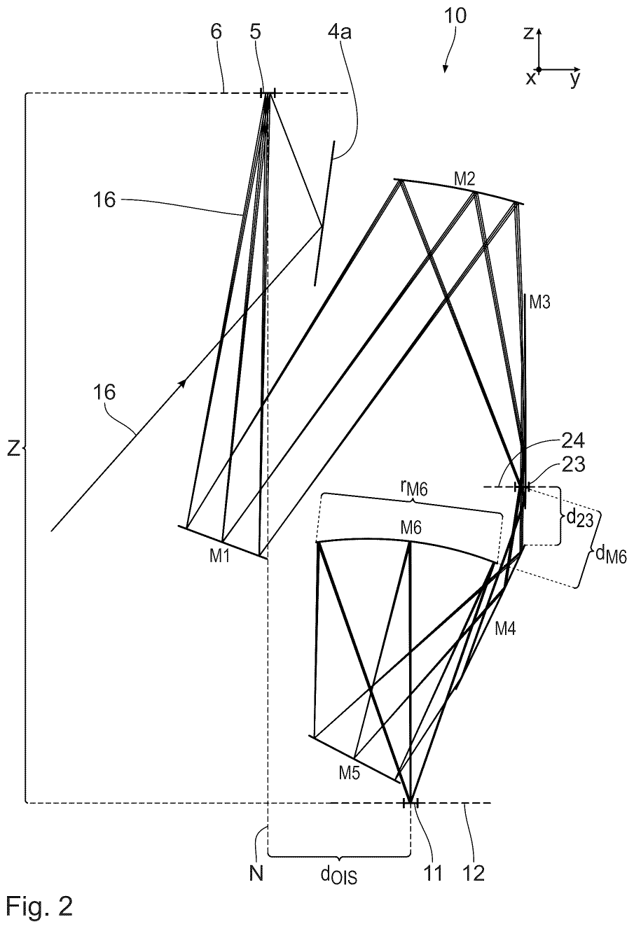

To the extent that the transfer optical unit downstream of the second facet mirror 21 is dispensed with, the second facet mirror 21 is the last beam shaping mirror or else indeed the last mirror for the illumination radiation 16 in the beam path upstream of the object field 5. An example of an illumination optical unit 4 without a transfer optical unit is disclosed in FIG. 2 of WO 2019/096654 A1.

The imaging of the first facets 20 into the object plane 6 via the second facets 22 or using the second facets 22 and a transfer optical unit is often only approximate imaging.

The projection optical unit 10 comprises a plurality of mirrors, namely six mirrors M1 to M6 (cf. FIG. 2), which are consecutively numbered in accordance with their order in the beam path of the projection exposure apparatus 1.

In the example illustrated in FIG. 1, the projection optical unit 10 comprises six mirrors M1 to M6. Alternatives with four, five or any other number of mirrors Mi are likewise possible.

The projection optical unit 10 is a non-obscured optical unit. None of the mirrors M1 to M6 includes a passage opening for the illumination radiation 16.

The projection optical unit 10 has an image-side numerical aperture of 0.33. Depending on the embodiment of the projection optical unit 10, the image-side numerical aperture may range between 0.25 and 0.4, for example. Depending on the embodiment, the image-side numerical aperture of the projection optical unit 10 may also adopt different values.

Reflection surfaces of the mirrors Mi are embodied as free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings can be designed as multilayer coatings, for example with alternating layers of molybdenum and silicon. A ruthenium coating is also possible, for example for coating mirrors for grazing incidence (GI mirrors).

The projection optical unit 10 leads to a reduction in size with a ratio of 4:1 in the x-direction, that is to say in a direction perpendicular to the scanning direction y. Moreover, the projection optical unit 10 leads to an image inversion in this x-direction. Thus, an imaging scale βₓ in the x-direction is −4.00.

In the scanning direction y, the projection optical unit 10 once again leads to a reduction in size of 4:1, but without an image inversion in this case (β_{y}=+4.00).

The projection optical unit 10 may also have an anamorphic design in an alternative embodiment. In that case, it has different imaging scales βₓ, β_{y} in the x- and y-directions. The two imaging scales βₓ, β_{y} of the projection optical unit 10 are preferably (βₓ, β_{y})=(+/−4, +/−8).

Other imaging scales are likewise possible. Imaging scales with the same sign are also possible in the x- and y-directions.

The image field 11 has an x-extent of 26 mm and a y-extent of 2.5 mm.

The image field may have a partial-ring-shaped embodiment.

Alternatively, the image field may also have a rectangular embodiment.

In each case one of the pupil facets 22 is assigned to exactly one of the field facets 20 for forming in each case an illumination channel for illuminating the object field 5. For example, this can yield illumination according to the Köhler principle. The far field is decomposed into a multiplicity of object fields 5 with the aid of the field facets 20. The field facets 20 generate a plurality of images of the intermediate focus on the pupil facets 22 respectively assigned thereto.

By way of an assigned pupil facet 22, the field facets 20 are imaged in each case onto the reticle 7 in a manner superposed on one another for the purposes of illuminating the object field 5. The illumination of the object field 5 is for example as homogeneous as possible. It preferably has a uniformity error of less than 2%. The field uniformity may be achieved by way of the overlay of different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, for example the subset of the pupil facets which guide light. This intensity distribution is also referred to as illumination setting or illumination pupil filling.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and for example of the entrance pupil of the projection optical unit 10 are described below.

The projection optical unit 10 may have for example a homocentric entrance pupil. It may be accessible, like in the embodiment of the projection optical unit 10 according to FIG. 2.

The projection optical unit 10 has an entrance pupil EP (cf. FIG. 1) which both in the x-direction and in the y-direction is located in the range between 1500 mm and 2000 mm upstream of the object field 5 in the beam path, and is for example located in the range between 1800 mm and 2200 mm. An arrangement plane of this entrance pupil is depicted at EP in FIG. 1. Thus, if the pupil facet mirror 21 is arranged approximately 2 m upstream of the object field 5 in the beam path of the illumination or imaging light 16, then the pupil facet mirror 21 satisfies the positional condition of “arrangement in the region of the entrance pupil of the projection optical unit”.

The entrance pupil may also be inaccessible in the case of an alternative embodiment of the projection optical unit 10, with the result that an arrangement plane of the pupil facet mirror 21 is imaged into the entrance pupil with the aid of further components of the illumination optical unit 4.

The entrance pupil of the projection optical unit 10 regularly cannot be exactly illuminated using the pupil facet mirror 21. In the case of imaging of the projection optical unit 10 which telecentrically images the centre of the pupil facet mirror 21 onto the wafer 13, the aperture rays often do not intersect at a single point. However, it is possible to find an area in which the distance of the aperture rays determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component part of the transfer optical unit, should be provided between the second facet mirror 21 and the reticle 7. With the aid of this optical element, the different poses of the tangential entrance pupil and sagittal entrance pupil can be taken into account.

In the arrangement of the components of the illumination optical unit 4 illustrated in FIG. 1, the pupil facet mirror 21 is arranged so as to be tilted with respect to the object plane 5. The second facet mirror 21 is furthermore arranged so as to be tilted with respect to an arrangement plane defined by the first facet mirror 19.

Further details relating to the projection optical unit 10 are described hereinafter on the basis of FIG. 2.

The projection optical unit 10 has four NI mirrors, namely the first two mirrors M1 and M2 and the last two mirrors M5 and M6 in the imaging beam path of the projection optical unit 10. The imaging light 16 is applied to these NI mirrors M1, M2, M5, M6 at angles of incidence of less than 45°. The maximum angle of incidence of the imaging light 16 incident on the respective NI mirror, can be less than 40°, can be less than 35°, can be less than 30°, can be less than 25°, can be less than 20°, can be less than 15° and can also be less than 10°.

The other mirrors M3 and M4 of the projection optical unit 10 are GI mirrors. For these mirrors M3 and M4, there are angles of incidence of the illumination light 16 on the mirrors of greater than 45° in each case. The minimum angle of incidence, which is incident on the respective GI mirror, can be greater than 50°, can be greater than 55°, can be greater than 60°, can be greater than 65°, can be greater than 70°, can be greater than 75° and can also be greater than 80°.

Information concerning reflection at a GI mirror can be found in WO 2012/126867 A. Further information concerning the reflectivity of NI mirrors can be found in DE 101 55 711 A.

None of the mirrors M1 to M6 has a passage opening and the mirrors are used in a reflective manner in a continuous region without gaps in each case.

FIG. 2 illustrates the calculated reflection surfaces of the mirrors M1 to M6. The used reflection surfaces of the mirrors M1 to M6 are carried in a known manner by mirror bodies (not shown).

FIG. 2 also indicates a course of a chief ray for an illumination beam 16 of the illumination optical unit 4 upstream of the object field 5. Upstream of the object field 5, this illumination beam 16 is deflected towards the object field 5 by a last mirror 4a of the illumination optical unit 4. The illumination optical unit mirror 4a is embodied as a GI mirror. The mirror 4a may be embodied as a plane mirror but may alternatively also have a beam-shaping effect on the illumination light beam. A beam path of the illumination beam 16 towards the object field 5 on the one hand crosses an imaging light beam path between the object field 5 and the mirror M1 on the other hand before the reflection at the mirror 4a.

The object plane 6 and the image plane 12 extend parallel to one another to a good approximation.

The reflection surface of the antepenultimate mirror M4 in the imaging beam path faces the last mirror M6. As a consequence, the imaging beam path is guided around the last mirror M6. Between the mirror M2 and the mirror M5, the imaging beam path of the imaging light 16 is guided around the mirror M6 with the aid of the two GI mirrors M3 and M4.

The number of intermediate image planes in the x-direction and in the y-direction in the beam path between the object field 5 and the image field 11 differ in the case of the projection optical unit 10. In the yz-plane, the projection optical unit 10 has an intermediate image 23 in an intermediate image plane 24, as shown in the meridional section according to FIG. 2. In the imaging direction perpendicular thereto with the imaging scale βₓ=−4.00, the projection optical unit 10 has no intermediate image. The intermediate image 23 is present in the meridional plane of the projection optical unit 10, i.e. in a plane containing a chief ray of a central field point of the projection optical unit 10.

Examples of projection optical units with different numbers of such intermediate images in the x- and y-directions or in mutually perpendicular imaging light planes are known from US 2018/10656400 B2. Alternatively, the projection optical unit 10 may also be designed without an intermediate image or with the same number of intermediate images in the x- and y-directions.

The image plane 12 is the first field plane after the object plane 6 in the xz-main plane of the projection optical unit 10 perpendicular to the meridional plane, i.e. in the imaging beam path of the projection optical unit 10 perpendicular to the yz-meridional plane. Thus, the projection optical unit 10 does not have an intermediate image perpendicular to the meridional plane. Thus, there is an image flip perpendicular to the meridional plane.

The intermediate image 23 is located in the region of a reflection of a beam of illumination light 16 at the mirror M3. Thus, a distance between the mirror M3 and the intermediate image 23 is 0. A distance d₂₃ between the further GI mirror M4 and the intermediate image 23 along the imaging beam path of the illumination light 16 is also less than 10% of a z-distance Z between the object field 5 and the image field 11. In turn, this distance Z is less than the actual spatial distance between the object field 5 and the image field 11 since the object field 5 and the image field 11 are once again offset from one another by a distance d_{OIS} (object-image offset) in the y-direction.

The distance Z is 1621.86 mm. The object-image offset d_{OIS} is 318.43 mm.

The distance d₂₃ is 84.65 mm in the embodiment according to FIG. 2 for the projection optical unit 10.

The object-image offset d_{OIS} is measured between a central field point of the object field 5 and a central field point of the image field 11 in a manner perpendicular to a normal N of the object plane 6. This object-image offset d_{OIS} is smaller than the distance Z, and so it is also smaller than the spatial distance between the object field 5 and the image field 11.

The two mirrors M1 and M2 have a subtractive deflection effect for the chief ray of the central object field point.

The two GI mirrors M3 and M4 add in terms of their deflection effect for a chief ray of the central object field point.

The penultimate mirror M5 and the last mirror M6 once again add in terms of their deflection effect for the chief ray of the central object field point.

More than four NI mirrors and/or more than two GI mirrors may also be present, depending on the embodiment of the projection optical unit 10.

The intermediate image 23 has a spatial distance d_{M6} from the last mirror M6 of less than 60% of a maximum extent r_{M6} of the last mirror M6 in the meridional plane. Here, r_{M6} corresponds to a diameter of the last mirror M6 which specifies the image-side numerical aperture of the projection optical unit 10.

The distance d_{M6} is 45.84 mm in the embodiment according to FIG. 2 for the projection optical unit 10.

The image field 11 has an extent of 26 mm in the x-direction and an extent of 2.5 mm in the y-direction.

An image field radius of the image field 11 is 40 mm.

An overall transmission of the projection optical unit 10, which emerges as a product of the EUV reflectivities of the mirrors M1 to M6 for the illumination light 16 along the imaging beam path through the projection optical unit 10, has a value of 11.72% in the projection optical unit 10 according to FIG. 2. On average, each individual one of the mirrors M1 to M6 thus has a reflectivity of 70%.

Thus, the overall transmission of the mirrors M1 to M6, i.e. the overall transmission of the projection optical unit 10, is greater than 10%.

In the yz-plane, a first pupil plane of the projection optical unit 10 is located in the beam path of the imaging light between the mirrors M1 and M2. A second pupil plane in the yz-plane is located at the same location as the pupil plane in the xz-plane perpendicular thereto, at a location in the imaging beam path adjacent to the reflection of the imaging light 16 at the mirror M5. An aperture can be limited in the case of the projection optical unit 10 by way of an aperture stop, which bounds the imaging beam path on the edge side, for example, and which may be attached to the mirror M5. If desired, an inner obscuration may also be defined on the mirror M5 with the aid of an appropriate stop portion.

A z-distance between the mirror M5 and the image field 11 is 52 mm.

The entire projection optical unit 10 can be accommodated in a cuboid with the xyz-edge lengths of 427 mm, 774 mm and 1371 mm.

The imaging beam path of the projection optical unit 10 contains a crossing region 25, in which two imaging beam path sections of the imaging beam path cross. A first of these crossing imaging beam path sections is the one between the mirrors M4 and M5. A second of these crossing imaging beam path sections is the section between the mirror M6 and the image field 11.

The projection optical unit 10 is telecentric on the image side.

The mirrors M1 to M6 carry a coating that optimizes the reflectivity of the mirrors M1 to M6 for the imaging light 16. For the GI mirrors for example, this may be a lanthanum coating, a boron coating or a boron coating with an uppermost layer of lanthanum, or else a ruthenium coating. Other coating materials may also be used, for example lanthanum nitride and/or B₄C. In the mirrors M3 and M4 for grazing incidence, use can be made of a coating with one ply of boron or lanthanum, for example. The highly reflecting layers, for example of the mirrors M1, M2, M5 and M6 for normal incidence, can be configured as multi-ply layers, wherein successive layers can be manufactured from different materials. Alternating material layers can also be used. A typical multi-ply layer can have fifty bilayers, respectively made of a layer of boron and a layer of lanthanum. Layers containing lanthanum nitride and/or boron, for example B₄C, may also be used.

Table 1, below, summarizes parameters of the projection optical unit 10. In addition to the data already explained above, Table 1 also specifies values for an angle of a chief ray of a central field point with respect to the z-axis (5.80°) and a usable étendue of the projection optical unit and a mean wavefront aberration RMS.

Table 1 for FIG. 2

| Wavelength | 13.5 | nm |
|---|---|---|
| Image-side numerical aperture | 0.33 | |
| Image field size in the x- and y- | 26 mm x 2.50 mm | |
| directions | | |
| βₓ | −4.00 (without intermediate | |
| | image) | |
| β_{y} | 4.00 (with intermediate image) | |
| Chief ray angle | 5.80° | |
| Étendue | 7.08 | mm² |
| Mean wavefront aberration RMS | 41.67 | mλ |
| Overall transmission | 11.72% | |
| Position of the entrance pupil (x) | −20568.55 | mm |
| Position of the entrance pupil (y) | 1119.34 | mm |
| Object-image offset in the y-direction | 318.43 | mm |
| Distance between M5 and image plane | 52 | mm |
| Distance between the object plane and | 1621.86 | mm |

| | |
|---|---|
| image plane | |
| Tilt between the object and | −0.1° |
| Image plane | |
| Installation space cuboid | (427 × 774 × 1371) mm |

Tables 2a, 2b below summarize the parameters “maximum angle of incidence”. “extent of the reflection surface in the x-direction”. “extent of the reflection surface in the y-direction” and “maximum mirror diameter” for the mirrors M1 to M6 of the projection optical unit 10.

Table 2a for FIG. 2

| | M1 | M2 | M3 |
|---|---|---|---|
| Maximum angle of incidence [°] | 17.8 | 26.5 | 88.6 |
| Minimum angle of incidence [°] | 9.8 | 19.1 | 69.2 |
| Extent of the reflection surface | 280.1 | 350.5 | 330.2 |
| in the x-direction [mm] | | | |
| Extent of the reflection surface | 179.1 | 284.0 | 453.6 |
| in the y-direction [mm] | | | |
| Maximum mirror diameter [mm] | 280.3 | 352.5 | 489.1 |

Table 2b for FIG. 2

| | M4 | M5 | M6 |
|---|---|---|---|
| Maximum angle of incidence [°] | 83.7 | 23.6 | 11.9 |
| Minimum angle of incidence [°] | 66.1 | 3.9 | 2.6 |
| Extent of the reflection surface | 323.4 | 348.4 | 427.3 |
| in the x-direction [mm] | | | |
| Extent of the reflection surface | 342.6 | 207.0 | 409.3 |
| in the y-direction [mm] | | | |
| Maximum mirror diameter [mm] | 364.8 | 348.5 | 428.2 |

For the two GI mirrors M3 and M4, there is a minimum angle of incidence of the imaging light 16 of 66.1° and a maximum angle of incidence of 88.6°. For the NI mirrors M1, M2, M5, M6, there is a minimum angle of incidence of 2.6° and a maximum angle of incidence of 26.5°. The maximum angle of incidence is less than 12° on the last mirror M6.

The mirror with the smallest reflection surface extent in the x-direction is the mirror M1, whose extent is approximately 280 mm. The mirror with the smallest reflection surface extent in the y-direction is also the mirror M1, with an extent of less than 180 mm.

The mirrors M1 to M6 are embodied as free-form surfaces which cannot be described by a rotationally symmetric function. Other embodiments of the projection optical unit 10, in which at least one of the mirrors M1 to M6 is embodied as a rotationally symmetric asphere, are also possible. It is also possible for all mirrors M1 to M6 to be embodied as such aspheres.

A free-form surface can be described by the following free-form surface equation (Equation 1):

$$Z = \frac{{c}_{x} {x}^{2} + {c}_{y} {y}^{2}}{1 + \sqrt{1 - ( 1 + {k}_{x} ) {( {c}_{x} x )}^{2} - ( 1 + {k}_{y} ) {( {c}_{y} y )}^{2}}} + {C}_{1} x + {C}_{2} y + {C}_{3} {x}^{2} + {C}_{4} x y + {C}_{5} {y}^{2} + {C}_{6} {x}^{3} + … + {C}_{9} {y}^{3} + {C}_{10} {x}^{4} + … + {C}_{12} {x}^{2} {y}^{2} + … + {C}_{14} {y}^{4} + {C}_{15} {x}^{5} + … + {C}_{20} {y}^{5} + {C}_{21} {x}^{6} + … + {C}_{24} {x}^{3} {y}^{3} + … + {C}_{27} {y}^{6} + … \qquad ( 1 )$$

The following applies to the parameters of this Equation (1):

Z is the sagittal height of the free-form surface at the point x, y, where x²+y²=r². Here, r is the distance from the reference axis of the free-form surface equation

$$( x = 0 ; y = 0 ) .$$

In the free-form surface Equation (1), C₁, C₂, C₃ . . . denote the coefficients of the free-form surface series expansion in powers of x and y.

In the case of a conical base area, cₓ, c_{y} is a constant corresponding to the vertex curvature of a corresponding asphere. Thus, cₓ=1/Rₓ (1/RDX) and c_{y}=1/R_{y} (1/RDY) applies. kₓ and k_{y} (CCX, CCY) each correspond to a conic constant of a corresponding asphere. Thus, Equation (1) describes a biconical free-form surface.

An alternative possible free-form surface can be produced from a rotationally symmetric reference surface. Such free-form surfaces for reflection surfaces of the mirrors of projection optical units of microlithographic projection exposure apparatuses are known from

### US 2007 0 058 269 A1.

Alternatively, free-form surfaces can also be described with the aid of two-dimensional spline surfaces. Examples for this are Bezier curves or non-uniform rational basis splines (NURBS). By way of example, two-dimensional spline surfaces can be described by a grid of points in an xy-plane and associated z-values, or by these points and gradients associated therewith. Depending on the respective type of the spline surface, the complete surface is obtained by interpolation between the grid points using for example polynomials or functions which have specific properties in respect of the continuity and differentiability thereof. Examples for this are analytical functions.

The optical design data of the reflection surfaces of the mirrors M1 to M6 of the projection optical unit 10 can be gathered from the further tables below.

Table 3 specifies coordinates of a surface origin of a respective mirror surface and of an area of the object field 5, in relation to a xyz-coordinate system of the image field 11.

The first column specifies the distance of the respective mirror or of the object field 5 from a coordinate origin in the centre of the image field 11 in the x-direction (first column), in the y-direction (second column) and in the z-direction (third column).

The additional columns of Table 3 (Table 3b) additionally specify tilt values of the respective surface of the mirror M1 to M6 or of the object field 5 in relation to the x-, y- and z-axis. In the embodiment according to FIG. 2, neither the object field 5 nor the image field 11 are tilted with respect to the x-axis and extend parallel to one another.

Table 4 tabulates, separately for the mirrors M1 to M6, the parameters RDX, RDY, CCX, CCY and, sorted according to the powers in x and y, the values of the coefficients C1, C2, C3 . . . of the free-form surface series expansion according to Equation (1) above.

Table 5 tabulates opening data for an aperture stop AS of the projection optical unit 10 arranged in the region of the mirror M6. This aperture opening is defined by a polygon, the x- and y-values of which are specified in Table 5.

Table 3a for FIG. 2

| | x-distance [mm] | y-distance [mm] | z-distance [mm] |
|---|---|---|---|
| Object field | 0 | 318.4304326 | 1621.85951 |
| M1 | 0 | 428.902948 | 595.5774823 |
| M2 | 0 | −146.9875253 | 1395.34341 |
| M3 | 0 | −261.4170597 | 771.5679705 |
| M4 | 0 | −218.2521466 | 497.1993974 |
| M5 | 0 | 129.8790981 | 102.9448624 |
| M6 | 0 | 0 | 597.6891879 |
| Stop (AS) | 0 | 129.8790981 | 102.9448624 |
| Image field | 0 | 0 | 0 |

Table 3b for FIG. 2

| | Tilt about the x- | Tilt about the y- | Tilt about the z- |
|---|---|---|---|
| | axis [degrees] | axis [degrees] | axis [degrees] |
| Object field | 0.143857143 | 0 | 0 |
| M1 | 20.95026413 | 180 | 0 |
| M2 | 12.68076512 | 0 | 0 |
| M3 | 89.27280423 | 0 | 180 |
| M4 | 115.19281 | 0 | 0 |
| M5 | 28.07705921 | 180 | 0 |
| M6 | 7.354623929 | 0 | 0 |
| Stop (AS) | 28.71148327 | 0 | 0 |
| Image field | 0 | 0 | 0 |

Table 4 for FIG. 2

| x**i * y**j | Coefficient |
|---|---|
| M1 | |
| RDX | −5495.450214 |
| RDY | −3704.050263 |
| CCX | 0 |
| CCY | 0 |
| x**2*y**1 | 6.7058E−08 |
| x**0*y**3 | 7.58532E−07 |
| x**4*y**0 | 6.96296E−12 |
| x**2*y**2 | 9.25761E−12 |
| x**0*y**4 | 1.08372E−09 |
| x**4*y**1 | 6.68272E−16 |
| x**2*y**3 | 1.92873E−13 |
| x**0*y**5 | −1.30135E−13 |
| x**6*y**0 | −8.0812E−19 |
| x**4*y**2 | −2.66507E−16 |
| x**2*y**4 | −1.04703E−15 |
| x**0*y**6 | 1.33632E−15 |
| x**6*y**1 | 5.32497E−19 |
| x**4*y**3 | −6.89364E−19 |
| x**2*y**5 | −1.88426E−17 |
| x**0*y**7 | 1.47634E−16 |
| x**8*y**0 | 4.68951E−22 |
| x**6*y**2 | 2.4179E−20 |
| x**4*y**4 | 3.36375E−20 |
| x**2*y**6 | −9.40264E−20 |
| x**0*y**8 | −6.77024E−19 |
| x**8*y**1 | −2.41798E−23 |
| x**6*y**3 | −6.4575E−23 |
| x**4*y**5 | 1.9105E−22 |
| x**2*y**7 | 2.40711E−21 |
| x**0*y**9 | −2.9784E−20 |
| x**10*y**0 | 1.98381E−27 |
| x**8*y**2 | −8.57405E−25 |
| x**6*y**4 | −2.68535E−24 |
| x**4*y**6 | 1.87833E−24 |
| x**2*y**8 | 3.82682E−24 |
| x**0*y**10 | −2.5035E−22 |
| x**10*y**1 | 6.06444E−28 |
| x**8*y**3 | 3.69866E−27 |
| x**6*y**5 | 5.92486E−28 |
| x**4*y**7 | −1.04817E−26 |
| x**2*y**9 | −3.17294E−25 |
| x**0*y**11 | −7.56216E−25 |
| x**12*y**0 | −6.38483E−31 |
| x**10*y**2 | 1.3546E−29 |
| x**8*y**4 | 2.76197E−29 |
| x**6*y**6 | 1.42296E−28 |
| x**4*y**8 | −3.30342E−28 |
| x**2*y**10 | −1.75052E−27 |
| x**0*y**12 | −4.25449E−28 |
| M2 | |
| RDX | −6399.756035 |
| RDY | −1329.568884 |
| CCX | 0 |
| CCY | 0 |
| x**2*y**1 | 2.65212E−08 |
| x**0*y**3 | −1.61991E−08 |
| x**4*y**0 | −2.7508E−11 |
| x**2*y**2 | 5.47281E−12 |
| x**0*y**4 | 9.8535E−12 |
| x**4*y**1 | 3.91558E−14 |
| x**2*y**3 | −1.05066E−13 |
| x**0*y**5 | −2.55097E−13 |
| x**6*y**0 | −7.92456E−18 |
| x**4*y**2 | −1.01551E−17 |
| x**2*y**4 | 7.80046E−16 |
| x**0*y**6 | 4.09457E−17 |
| x**6*y**1 | −3.72667E−19 |
| x**4*y**3 | −8.40933E−19 |
| x**2*y**5 | −2.23279E−18 |
| x**0*y**7 | 8.31367E−18 |
| x**8*y**0 | −7.45375E−22 |
| x**6*y**2 | −2.3067E−21 |
| x**4*y**4 | −6.46585E−23 |
| x**2*y**6 | −5.64821E−21 |
| x**0*y**8 | −3.28298E−20 |
| x**8*y**1 | 5.16549E−24 |
| x**6*y**3 | 4.30816E−23 |
| x**4*y**5 | 6.3812E−23 |
| x**2*y**7 | −1.58696E−22 |
| x**0*y**9 | −3.5604E−22 |
| x**10*y**0 | 2.62763E−26 |
| x**8*y**2 | 8.25404E−26 |
| x**6*y**4 | −1.02361E−25 |
| x**4*y**6 | −4.24624E−25 |
| x**2*y**8 | 3.59575E−24 |
| x**0*y**10 | 2.65622E−24 |
| x**10*y**1 | −4.93229E−29 |
| x**8*y**3 | −7.99065E−28 |
| x**6*y**5 | −1.38618E−27 |
| x**4*y**7 | −4.20586E−28 |
| x**2*y**9 | −1.98811E−26 |
| x**0*y**11 | −6.87535E−27 |
| x**12*y**0 | −2.11103E−31 |
| x**10*y**2 | −1.28023E−30 |
| x**8*y**4 | 3.59906E−30 |
| x**6*y**6 | 5.99026E−30 |
| x**4*y**8 | 5.39649E−30 |
| x**2*y**10 | 3.54238E−29 |
| x**0*y**12 | 4.48535E−30 |
| M3 | |
| RDX | 47942.67839 |
| RDY | −5869779.353 |
| CCX | 0 |
| CCY | 0 |
| x**2*y**1 | −1.59946E−08 |
| x**0*y**3 | −1.89551E−10 |
| x**4*y**0 | 1.93795E−10 |
| x**2*y**2 | −9.55219E−11 |
| x**0*y**4 | 2.42446E−13 |
| x**4*y**1 | −2.88447E−14 |
| x**2*y**3 | −2.52749E−13 |
| x**0*y**5 | 3.15064E−14 |
| x**6*y**0 | 4.37161E−17 |
| x**4*y**2 | 2.51507E−16 |
| x**2*y**4 | −1.00551E−15 |
| x**0*y**6 | 4.14405E−16 |
| x**6*y**1 | 1.89777E−18 |
| x**4*y**3 | 3.59856E−18 |
| x**2*y**5 | −5.04931E−18 |
| x**0*y**7 | 9.76042E−19 |
| x**8*y**0 | 1.43204E−20 |
| x**6*y**2 | 1.43377E−20 |
| x**4*y**4 | 1.48395E−20 |
| x**2*y**6 | −3.42973E−20 |
| x**0*y**8 | −1.71286E−20 |
| x**8*y**1 | −6.28741E−23 |
| x**6*y**3 | −1.37101E−22 |
| x**4*y**5 | 4.83485E−23 |
| x**2*y**7 | −9.03504E−23 |
| x**0*y**9 | −1.53259E−22 |
| x**10*y**0 | −3.27064E−25 |
| x**8*y**2 | −8.76576E−25 |
| x**6*y**4 | −3.11998E−25 |
| x**4*y**6 | 1.13746E−24 |
| x**2*y**8 | 4.08345E−25 |
| x**0*y**10 | −5.44675E−25 |
| x**10*y**1 | 1.6996E−27 |
| x**8*y**3 | 2.34942E−27 |
| x**6*y**5 | −1.3724E−27 |
| x**4*y**7 | 6.87591E−27 |
| x**2*y**9 | 2.52242E−27 |
| x**0*y**11 | −9.22404E−28 |
| x**12*y**0 | −1.44058E−30 |
| x**10*y**2 | 1.65899E−29 |
| x**8*y**4 | 4.24306E−30 |
| x**6*y**6 | −1.98373E−29 |
| x**4*y**8 | 1.19463E−29 |
| x**2*y**10 | 3.42609E−30 |
| x**0*y**12 | −6.15208E−31 |
| M4 | |
| RDX | 2725.392156 |
| RDY | −7955.269177 |
| CCX | 0 |
| CCY | 0 |
| x**2*y**1 | 1.16068E−07 |
| x**0*y**3 | −7.54447E−08 |
| x**4*y**0 | 3.56487E−10 |
| x**2*y**2 | 5.40241E−11 |
| x**0*y**4 | −6.29289E−11 |
| x**4*y**1 | 4.75875E−13 |
| x**2*y**3 | 5.5855E−13 |
| x**0*y**5 | 3.38156E−13 |
| x**6*y**0 | 6.33282E−16 |
| x**4*y**2 | 7.75694E−16 |
| x**2*y**4 | 2.05981E−15 |
| x**0*y**6 | 6.01302E−16 |
| x**6*y**1 | −2.44881E−18 |
| x**4*y**3 | −2.77671E−18 |
| x**2*y**5 | −4.08353E−18 |
| x**0*y**7 | −3.17007E−18 |
| x**8*y**0 | −5.41436E−21 |
| x**6*y**2 | 2.30733E−20 |
| x**4*y**4 | 2.98722E−20 |
| x**2*y**6 | 6.64579E−21 |
| x**0*y**8 | 3.49171E−21 |
| x**8*y**1 | 1.39516E−22 |
| x**6*y**3 | 2.49093E−22 |
| x**4*y**5 | 7.88937E−22 |
| x**2*y**7 | 1.32076E−21 |
| x**0*y**9 | 1.3426E−22 |
| x**10*y**0 | 5.0364E−26 |
| x**8*y**2 | −8.71718E−25 |
| x**6*y**4 | 9.40377E−26 |
| x**4*y**6 | 4.70484E−24 |
| x**2*y**8 | 1.22911E−23 |
| x**0*y**10 | 5.30892E−25 |
| x**10*y**1 | −3.04022E−27 |
| x**8*y**3 | −1.30183E−27 |
| x**6*y**5 | −4.43468E−27 |
| x**4*y**7 | 1.02731E−26 |
| x**2*y**9 | 4.57E−26 |
| x**0*y**11 | 9.45916E−28 |
| x**12*y**0 | 2.859E−30 |
| x**10*y**2 | 1.23528E−29 |
| x**8*y**4 | 1.28116E−29 |
| x**6*y**6 | −1.74226E−29 |
| x**4*y**8 | 4.00644E−30 |
| x**2*y**10 | 6.25933E−29 |
| x**0*y**12 | 7.77975E−31 |
| M5 | |
| RDX | 114658.6339 |
| RDY | 3749.47119 |
| CCX | 0 |
| CCY | 0 |
| x**2*y**1 | 1.70876E−08 |
| x**0*y**3 | 7.92405E−07 |
| x**4*y**0 | 1.239E−10 |
| x**2*y**2 | 1.32477E−09 |
| x**0*y**4 | 1.49775E−09 |
| x**4*y**1 | 2.96583E−13 |
| x**2*y**3 | 4.63692E−13 |
| x**0*y**5 | −2.63536E−12 |
| x**6*y**0 | 1.97802E−16 |
| x**4*y**2 | 2.02246E−15 |
| x**2*y**4 | 2.33504E−15 |
| x**0*y**6 | 5.98472E−15 |
| x**6*y**1 | 1.22445E−18 |
| x**4*y**3 | 2.46884E−18 |
| x**2*y**5 | −1.52836E−18 |
| x**0*y**7 | −4.09182E−17 |
| x**8*y**0 | 1.81711E−22 |
| x**6*y**2 | −8.41314E−22 |
| x**4*y**4 | 3.3291E−21 |
| x**2*y**6 | −2.90785E−20 |
| x**0*y**8 | 1.37712E−18 |
| x**8*y**1 | −6.72038E−24 |
| x**6*y**3 | −3.73359E−24 |
| x**4*y**5 | 3.99539E−23 |
| x**2*y**7 | 5.65062E−22 |
| x**0*y**9 | −8.12007E−21 |
| x**10*y**0 | 1.69568E−26 |
| x**8*y**2 | 2.04863E−25 |
| x**6*y**4 | 1.28961E−25 |
| x**4*y**6 | −1.50551E−24 |
| x**2*y**8 | −1.2632E−23 |
| x**0*y**10 | 1.81224E−23 |
| x**10*y**1 | 1.64044E−28 |
| x**8*y**3 | −2.75568E−28 |
| x**6*y**5 | −1.97984E−27 |
| x**4*y**7 | −2.24148E−26 |
| x**2*y**9 | 4.52404E−26 |
| x**0*y**11 | −2.12766E−26 |
| x**12*y**0 | −2.62324E−31 |
| x**10*y**2 | −2.55851E−30 |
| x**8*y**4 | −2.08754E−30 |
| x**6*y**6 | 2.17444E−29 |
| x**4*y**8 | 1.82641E−28 |
| x**2*y**10 | −1.7323E−28 |
| x**0*y**12 | 1.62635E−28 |
| M6 | |
| RDX | −1035.642043 |
| RDY | −762.4900669 |
| CCX | 0 |
| CCY | 0 |
| x**2*y**1 | 8.42976E−09 |
| x**0*y**3 | −4.77336E−08 |
| x**4*y**0 | −4.62691E−11 |
| x**2*y**2 | −1.45819E−10 |
| x**0*y**4 | −6.47413E−11 |
| x**4*y**1 | −1.06641E−15 |
| x**2*y**3 | −4.90073E−14 |
| x**0*y**5 | −8.88547E−14 |
| x**6*y**0 | −6.77364E−17 |
| x**4*y**2 | −3.33802E−16 |
| x**2*y**4 | −4.6434E−16 |
| x**0*y**6 | −7.09875E−18 |
| x**6*y**1 | −7.6408E−20 |
| x**4*y**3 | −1.59775E−19 |
| x**2*y**5 | −1.54533E−20 |
| x**0*y**7 | 1.63622E−19 |
| x**8*y**0 | 3.48849E−24 |
| x**6*y**2 | −3.87067E−22 |
| x**4*y**4 | −1.13832E−21 |
| x**2*y**6 | −7.46912E−22 |
| x**0*y**8 | −7.03615E−21 |
| x**8*y**1 | 3.90531E−25 |
| x**6*y**3 | −6.06706E−25 |
| x**4*y**5 | −2.44734E−24 |
| x**2*y**7 | −1.78712E−24 |
| x**0*y**9 | 7.92368E−24 |
| x**10*y**0 | −2.81631E−27 |
| x**8*y**2 | −6.72118E−27 |
| x**6*y**4 | 1.54211E−27 |
| x**4*y**6 | 8.46415E−27 |
| x**2*y**8 | −6.08204E−27 |
| x**0*y**10 | 1.00354E−25 |
| x**10*y**1 | −6.75139E−30 |
| x**8*y**3 | 1.13237E−29 |
| x**6*y**5 | 2.83724E−29 |
| x**4*y**7 | 6.08697E−29 |
| x**2*y**9 | 1.08866E−28 |
| x**0*y**11 | −4.5322E−28 |
| x**12*y**0 | 2.54885E−32 |
| x**10*y**2 | 4.76444E−32 |
| x**8*y**4 | −6.65506E−32 |
| x**6*y**6 | −2.53654E−31 |
| x**4*y**8 | −3.30217E−31 |
| x**2*y**10 | −2.08414E−31 |
| x**0*y**12 | 5.98418E−31 |

Table 5 for FIG. 2

| x [mm] | y [mm] |
|---|---|
| 174.1494025 | −5.153356621 |
| 171.7664983 | 15.02440097 |
| 162.5825701 | 34.63695842 |
| 146.8952625 | 52.88104585 |
| 125.3017959 | 68.99081934 |
| 98.66472744 | 82.27711463 |
| 68.0611652 | 92.17230418 |
| 34.72643714 | 98.26742372 |
| 1.09025E−14 | 100.3246433 |
| −34.72643714 | 98.26742372 |
| −68.0611652 | 92.17230418 |
| −98.66472744 | 82.27711463 |
| −125.3017959 | 68.99081934 |
| −146.8952625 | 52.88104585 |
| −162.5825701 | 34.63695842 |
| −171.7664983 | 15.02440097 |
| −174.1494025 | −5.153356621 |
| −169.7436421 | −25.09439669 |
| −158.8555208 | −44.04174042 |
| −142.0457188 | −61.31061274 |
| −120.0757489 | −76.30538464 |
| −93.85291923 | −88.55466104 |
| −64.38408406 | −97.70153432 |
| −32.73649391 | −103.4121022 |
| −3.07965E−14 | −105.3643513 |
| 32.73649391 | −103.4121022 |
| 64.38408406 | −97.70153432 |
| 93.85291923 | −88.55466104 |
| 120.0757489 | −76.30538464 |
| 142.0457188 | −61.31061274 |
| 158.8555208 | −44.04174042 |
| 169.7436421 | −25.09439669 |

Mirrors with different signs for the values RDX and RDY have a saddle point-type or minimax basic shape.

In the case of the projection optical unit 10, the GI mirror M4 is located spatially directly next to the last mirror M6.

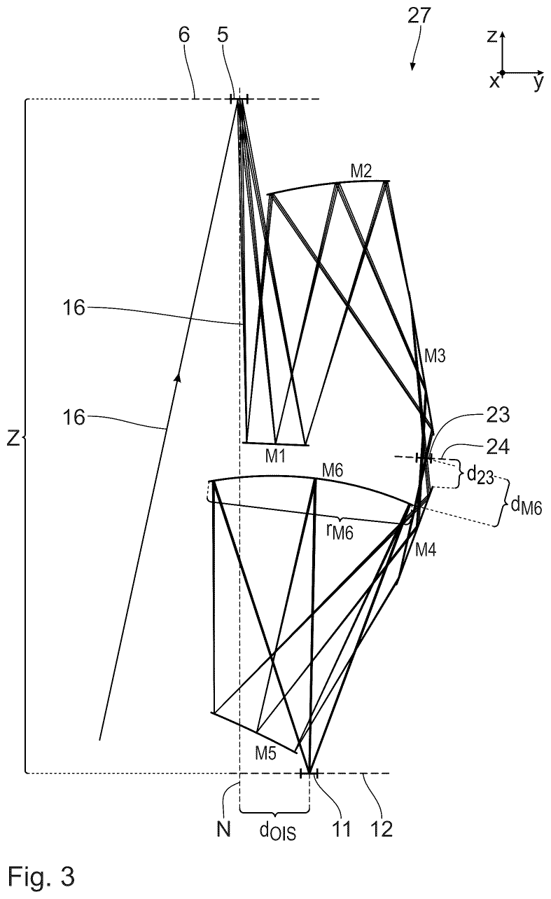

FIG. 3 shows a further embodiment of a projection optical unit or imaging optical unit 27, which can be used in the projection exposure apparatus 1 instead of the projection optical unit 10 of the embodiment according to FIG. 2. Components and functions corresponding to those which have already been explained above in conjunction with FIGS. 1 and 2, and for example in conjunction with FIG. 2, are denoted by the same reference signs and are not discussed in detail again.

The basic structure of the projection optical unit 27 corresponds to that of the projection optical unit 10. In the projection optical unit 27, the chief ray angle of the central field point with respect to the normal N of the object plane 6 extends exactly counter to the case of the projection optical unit 10 and is 6.07° in the projection optical unit 27. On account of the opposite orientation, an illumination beam 16 of the illumination optical unit 4 can be guided without an intermediate deflection (cf. mirror 4a of the embodiment according to FIG. 2) and can for example, as indicated in FIG. 1, be reflected directly from the second facet mirror 21 towards the object field 5. Crossing between the illumination light in the beam path directly upstream of the object field and the imaging light can be avoided in the case of this design of the projection optical unit 27.

The distance d₂₃ of the GI mirror M4 from the intermediate image 23 along the imaging beam path of the illumination light 16 is 137.84 mm in the case of the embodiment according to FIG. 3 for the projection optical unit 27; the distance d_{M6} between the intermediate image 23 and the last mirror M6 is 18.00 mm.

An image field radius of the image field 11 is 160 mm.

The following tables summarize parameters and the optical design of the projection optical unit 27. In terms of their structure, these tables correspond to those already explained above in conjunction with FIG. 2.

Table 1 for FIG. 3

| Wavelength | 13.5 | nm |
|---|---|---|
| Image-side numerical aperture | 0.33 | |
| Image field size in the x- and y- | 26 mm x 2.5 mm | |
| directions | | |
| βₓ | −4.00 (without intermediate | |
| | image) | |
| β_{y} | 4.00 (with intermediate image) | |
| Chief ray angle | 6.07° | |
| Étendue | 7.08 | mm² |
| Mean wavefront aberration RMS | 157.67 | mλ |
| Overall transmission | 11.79% | |
| Position of the entrance pupil (x) | 6196.60 | mm |
| Position of the entrance pupil (y) | 819.60 | mm |
| Object-image offset in the y-direction | 204.50 | mm |
| Distance between M5 and image plane | 51 | mm |
| Distance between the object plane and | 1635.21 | mm |

| | |
|---|---|
| image plane | |
| Tilt between the object and | 1.2° |
| Image plane | |
| Installation space cuboid | (509 × 532 × 1392) mm |

Table 2a for FIG. 3

| | M1 | M2 | M3 |
|---|---|---|---|
| Maximum angle of incidence [°] | 14.2 | 20.2 | 87.2 |
| Minimum angle of incidence [°] | 3.1 | 14.3 | 66.1 |
| Extent of the reflection surface | 229.2 | 282.4 | 333.8 |
| in the x-direction [mm] | | | |
| Extent of the reflection surface | 142.6 | 289.5 | 340.5 |
| in the y-direction [mm] | | | |
| Maximum mirror diameter [mm] | 229.4 | 302.6 | 377.3 |

Table 2b for FIG. 3

| | M4 | M5 | M6 |
|---|---|---|---|
| Maximum angle of incidence [°] | 81.4 | 22.4 | 10.9 |
| Minimum angle of incidence [°] | 64.9 | 2.7 | 2.1 |
| Extent of the reflection surface | 360.1 | 429.0 | 508.8 |
| in the x-direction [mm] | | | |
| Extent of the reflection surface | 241.0 | 217.8 | 484.9 |
| in the y-direction [mm] | | | |
| Maximum mirror diameter [mm] | 360.7 | 429.1 | 509.2 |

Table 3a for FIG. 3

| | x-distance [mm] | y-distance [mm] | z-distance [mm] |
|---|---|---|---|
| Object field | 0 | 204.5044041 | 1635.212341 |
| M1 | 0 | 98.94500265 | 799.1475527 |
| M2 | 0 | −36.86589073 | 1436.494565 |
| M3 | 0 | −263.8382346 | 929.9985403 |
| M4 | 0 | −252.819751 | 609.4523297 |
| M5 | 0 | 130.6954784 | 96.08838877 |
| M6 | 0 | 0 | 716.5404348 |
| Stop (AS) | 0 | 130.6954784 | 96.08838877 |
| Image field | 0 | 0 | 0 |

Table 3b for FIG. 3

| | Tilt about the x- | Tilt about the y- | Tilt about the z- |
|---|---|---|---|
| | axis [degrees] | axis [degrees] | axis [degrees] |
| Object field | −1.195943055 | 0 | 0 |
| M1 | 2.416588774 | 180 | 0 |
| M2 | −6.05455584 | 0 | 0 |
| M3 | 78.91524136 | 0 | 180 |
| M4 | 109.3653823 | 0 | 0 |
| M5 | 24.32862533 | 180 | 0 |
| M6 | 5.947600484 | 0 | 0 |
| Stop (AS) | 25.52875624 | 0 | 0 |
| Image field | 0 | 0 | 0 |

Table 4 for FIG. 3

| x**i * y**j | Coefficient |
|---|---|
| M1 | |
| RDX | −6792.671581 |
| RDY | −13453.91761 |
| CCX | 0 |
| CCY | 0 |
| x**2*y**1 | 3.93962E−08 |
| x**0*y**3 | 8.6356E−07 |
| x**4*y**0 | −1.119E−11 |
| x**2*y**2 | −1.05586E−10 |
| x**0*y**4 | 4.68647E−09 |
| x**4*y**1 | −8.79998E−15 |
| x**2*y**3 | −6.49659E−14 |
| x**0*y**5 | 3.61968E−11 |
| x**6*y**0 | −2.68011E−17 |
| x**4*y**2 | 7.9611E−17 |
| x**2*y**4 | −2.37375E−15 |
| x**0*y**6 | 3.67122E−13 |
| x**6*y**1 | 2.33837E−19 |
| x**4*y**3 | −6.68483E−18 |
| x**2*y**5 | −4.69388E−17 |
| x**0*y**7 | −3.54964E−15 |
| x**8*y**0 | 1.23087E−20 |
| x**6*y**2 | −3.35175E−20 |
| x**4*y**4 | −3.55384E−19 |
| x**2*y**6 | −9.17777E−19 |
| x**0*y**8 | −1.29769E−17 |
| x**8*y**1 | −3.4174E−23 |
| x**6*y**3 | 2.8694E−22 |
| x**4*y**5 | 5.86869E−21 |
| x**2*y**7 | 1.25307E−20 |
| x**0*y**9 | 2.91719E−19 |
| x**10*y**0 | −2.08958E−24 |
| x**8*y**2 | 2.08149E−24 |
| x**6*y**4 | 6.51443E−23 |
| x**4*y**6 | 2.26587E−22 |
| x**2*y**8 | 7.13038E−22 |
| x**0*y**10 | 1.55937E−20 |
| x**10*y**1 | 3.24387E−27 |
| x**8*y**3 | 2.38124E−26 |
| x**6*y**5 | −3.61537E−25 |
| x**4*y**7 | −2.15023E−24 |
| x**2*y**9 | −5.27176E−24 |
| x**0*y**11 | 2.07097E−22 |
| x**12*y**0 | 1.85996E−28 |
| x**10*y**2 | 1.79256E−28 |
| x**8*y**4 | −5.8298E−27 |
| x**6*y**6 | −2.78496E−26 |
| x**4*y**8 | −6.96569E−26 |
| x**2*y**10 | −2.71129E−25 |
| x**0*y**12 | −2.89045E−24 |
| x**12*y**1 | −1.34713E−31 |
| x**10*y**3 | −1.90926E−30 |
| x**8*y**5 | 2.01077E−30 |
| x**6*y**7 | 1.16232E−28 |
| x**4*y**9 | 3.82927E−28 |
| x**2*y**11 | 9.15625E−28 |
| x**0*y**13 | −3.20274E−26 |
| x**14*y**0 | −8.33578E−33 |
| x**12*y**2 | −2.19678E−32 |
| x**10*y**4 | 2.43763E−31 |
| x**8*y**6 | 1.75172E−30 |
| x**6*y**8 | 5.01327E−30 |
| x**4*y**10 | 1.10726E−29 |
| x**2*y**12 | 4.35626E−29 |
| x**0*y**14 | 4.01135E−28 |
| x**14*y**1 | 2.96666E−36 |
| x**12*y**3 | 6.38593E−36 |
| x**10*y**5 | 2.33706E−34 |
| x**8*y**7 | −1.6424E−33 |
| x**6*y**9 | −1.12438E−32 |
| x**4*y**11 | −2.55154E−32 |
| x**2*y**13 | −8.88939E−32 |
| x**0*y**15 | 1.66946E−30 |
| x**16*y**0 | 1.47499E−37 |
| x**14*y**2 | 5.85364E−37 |
| x**12*y**4 | −5.16906E−36 |
| x**10*y**6 | −3.7125E−35 |
| x**8*y**8 | −1.61946E−34 |
| x**6*y**10 | −3.42666E−34 |
| x**4*y**12 | −6.90747E−34 |
| x**2*y**14 | −2.79074E−33 |
| x**0*y**16 | −1.45207E−32 |
| M2 | |
| RDX | 66376.74655 |
| RDY | −1012.952416 |
| CCX | 0 |
| CCY | 0 |
| x**2*y**1 | 3.44837E−08 |
| x**0*y**3 | 4.73321E−08 |
| x**4*y**0 | −7.14882E−12 |
| x**2*y**2 | −2.9985E−11 |
| x**0*y**4 | −6.76046E−10 |
| x**4*y**1 | 5.50104E−14 |
| x**2*y**3 | 7.34384E−14 |
| x**0*y**5 | 1.20529E−12 |
| x**6*y**0 | 6.84598E−17 |
| x**4*y**2 | 6.03209E−18 |
| x**2*y**4 | 1.9107E−16 |
| x**0*y**6 | −7.87867E−15 |
| x**6*y**1 | −5.081E−19 |
| x**4*y**3 | −2.29487E−19 |
| x**2*y**5 | 1.69449E−19 |
| x**0*y**7 | 1.00536E−16 |
| x**8*y**0 | −1.70487E−20 |
| x**6*y**2 | −2.20035E−20 |
| x**4*y**4 | −8.65828E−21 |
| x**2*y**6 | −1.78511E−20 |
| x**0*y**8 | −7.85064E−19 |
| x**8*y**1 | 4.66264E−23 |
| x**6*y**3 | 1.05985E−22 |
| x**4*y**5 | −5.21703E−23 |
| x**2*y**7 | 3.12981E−22 |
| x**0*y**9 | 2.92937E−22 |
| x**10*y**0 | 1.468E−24 |
| x**8*y**2 | 2.67469E−24 |
| x**6*y**4 | 2.59699E−24 |
| x**4*y**6 | 5.72556E−26 |
| x**2*y**8 | −2.0981E−24 |
| x**0*y**10 | 1.8064E−23 |
| x**10*y**1 | −3.41246E−27 |
| x**8*y**3 | −9.74646E−27 |
| x**6*y**5 | −1.25274E−26 |
| x**4*y**7 | 9.78937E−27 |
| x**2*y**9 | −5.47831E−27 |
| x**0*y**11 | −4.93069E−26 |
| x**12*y**0 | −6.86722E−29 |
| x**10*y**2 | −1.57314E−28 |
| x**8*y**4 | −2.54225E−28 |
| x**6*y**6 | −1.02692E−28 |
| x**4*y**8 | 8.26563E−30 |
| x**2*y**10 | 2.00294E−28 |
| x**0*y**12 | −9.03779E−29 |
| x**12*y**1 | 1.36191E−31 |
| x**10*y**3 | 4.2632E−31 |
| x**8*y**5 | 1.07671E−30 |
| x**6*y**7 | 7.55574E−31 |
| x**4*y**9 | −6.69429E−31 |
| x**2*y**11 | −5.93703E−31 |
| x**0*y**13 | 3.77535E−30 |
| x**14*y**0 | 1.66645E−33 |
| x**12*y**2 | 4.20494E−33 |
| x**10*y**4 | 8.92788E−33 |
| x**8*y**6 | 6.54409E−33 |
| x**6*y**8 | 3.55116E−34 |
| x**4*y**10 | 9.3181E−35 |
| x**2*y**12 | −7.39121E−33 |
| x**0*y**14 | −4.71034E−32 |
| x**14*y**1 | −2.26791E−36 |
| x**12*y**3 | −7.44271E−36 |
| x**10*y**5 | −2.54133E−35 |
| x**8*y**7 | −3.20949E−35 |
| x**6*y**9 | −2.58825E−35 |
| x**4*y**11 | 2.50478E−35 |
| x**2*y**13 | 5.34437E−35 |
| x**0*y**15 | 2.30203E−34 |
| x**16*y**0 | −1.61488E−38 |
| x**14*y**2 | −3.99831E−38 |
| x**12*y**4 | −5.74791E−38 |
| x**10*y**6 | −1.23616E−37 |
| x**8*y**8 | 3.31244E−38 |
| x**6*y**10 | 9.38E−38 |
| x**4*y**12 | −7.62212E−38 |
| x**2*y**14 | −9.97184E−38 |
| x**0*y**16 | −3.91615E−37 |
| M3 | |
| RDX | −19236.58624 |
| RDY | 10149.09253 |
| CCX | 0 |
| CCY | 0 |
| x**2*y**1 | −5.90216E−08 |
| x**0*y**3 | 5.4526E−08 |
| x**4*y**0 | 1.05161E−10 |
| x**2*y**2 | −1.77301E−10 |
| x**0*y**4 | 3.57974E−10 |
| x**4*y**1 | −2.26859E−13 |
| x**2*y**3 | −6.6076E−13 |
| x**0*y**5 | 1.99753E−12 |
| x**6*y**0 | −2.64829E−16 |
| x**4*y**2 | 2.05515E−16 |
| x**2*y**4 | −3.13513E−15 |
| x**0*y**6 | 8.51715E−15 |
| x**6*y**1 | 7.3042E−18 |
| x**4*y**3 | 8.69094E−18 |
| x**2*y**5 | −1.04044E−17 |
| x**0*y**7 | −1.1075E−17 |
| x**8*y**0 | 3.69951E−20 |
| x**6*y**2 | 1.74046E−20 |
| x**4*y**4 | 8.89828E−20 |
| x**2*y**6 | 2.85615E−20 |
| x**0*y**8 | 8.04482E−22 |
| x**8*y**1 | −7.16834E−22 |
| x**6*y**3 | −1.16133E−21 |
| x**4*y**5 | −9.87233E−22 |
| x**2*y**7 | −5.06051E−22 |
| x**0*y**9 | 6.56626E−21 |
| x**10*y**0 | −1.54117E−24 |
| x**8*y**2 | 6.52333E−25 |
| x**6*y**4 | −7.67805E−24 |
| x**4*y**6 | −1.17901E−23 |
| x**2*y**8 | −1.75069E−23 |
| x**0*y**10 | 5.92355E−23 |
| x**10*y**1 | 3.62306E−26 |
| x**8*y**3 | 7.29897E−26 |
| x**6*y**5 | 9.94231E−26 |
| x**4*y**7 | 1.34754E−26 |
| x**2*y**9 | −1.59385E−25 |
| x**0*y**11 | −4.14926E−26 |
| x**12*y**0 | 2.67564E−29 |
| x**10*y**2 | −1.3974E−28 |
| x**8*y**4 | 1.81264E−28 |
| x**6*y**6 | 8.72579E−28 |
| x**4*y**8 | 5.59332E−28 |
| x**2*y**10 | −5.28631E−28 |
| x**0*y**12 | −3.67583E−27 |
| x**12*y**1 | −9.1989E−31 |
| x**10*y**3 | −2.30884E−30 |
| x**8*y**5 | −3.98455E−30 |
| x**6*y**7 | −6.8872E−31 |
| x**4*y**9 | 2.83773E−30 |
| x**2*y**11 | 1.48633E−30 |
| x**0*y**13 | −2.62684E−29 |
| x**14*y**0 | −6.79372E−36 |
| x**12*y**2 | 5.87842E−33 |
| x**10*y**4 | 6.47444E−33 |
| x**8*y**6 | −1.70413E−32 |
| x**6*y**8 | −2.20259E−32 |
| x**4*y**10 | 1.2581E−32 |
| x**2*y**12 | 1.92749E−32 |
| x**0*y**14 | −9.05705E−32 |
| x**14*y**1 | 9.46775E−36 |
| x**12*y**3 | 2.88363E−35 |
| x**10*y**5 | 6.21794E−35 |
| x**8*y**7 | −1.55544E−35 |
| x**6*y**9 | −5.10547E−35 |
| x**4*y**11 | 5.49813E−35 |
| x**2*y**13 | 6.37537E−35 |
| x**0*y**15 | −1.6057E−34 |
| x**16*y**0 | −3.87789E−39 |
| x**14*y**2 | −7.90089E−38 |
| x**12*y**4 | −2.4267E−37 |
| x**10*y**6 | −1.24656E−37 |
| x**8*y**8 | −7.11189E−38 |
| x**6*y**10 | −2.17826E−39 |
| x**4*y**12 | 1.02015E−37 |
| x**2*y**14 | 7.48068E−38 |
| x**0*y**16 | −1.17607E−37 |
| M4 | |
| RDX | 9633.600538 |
| RDY | −4607.473226 |
| CCX | 0 |
| CCY | 0 |
| x**2*y**1 | 2.67987E−08 |
| x**0*y**3 | −1.56082E−07 |
| x**4*y**0 | 1.59468E−10 |
| x**2*y**2 | −2.62243E−12 |
| x**0*y**4 | −2.63357E−10 |
| x**4*y**1 | 2.1791E−13 |
| x**2*y**3 | 2.3504E−13 |
| x**0*y**5 | −1.33584E−12 |
| x**6*y**0 | 3.74213E−16 |
| x**4*y**2 | 3.37099E−16 |
| x**2*y**4 | −8.30193E−16 |
| x**0*y**6 | −3.89509E−15 |
| x**6*y**1 | 1.5809E−19 |
| x**4*y**3 | −3.09781E−18 |
| x**2*y**5 | −1.96533E−18 |
| x**0*y**7 | 1.19107E−16 |
| x**8*y**0 | −1.22833E−20 |
| x**6*y**2 | 2.59692E−21 |
| x**4*y**4 | 2.93677E−20 |
| x**2*y**6 | 7.73886E−20 |
| x**0*y**8 | 7.81967E−19 |
| x**8*y**1 | −1.7325E−23 |
| x**6*y**3 | 6.6401E−23 |
| x**4*y**5 | 4.03286E−22 |
| x**2*y**7 | −1.47112E−21 |
| x**0*y**9 | −1.76944E−20 |
| x**10*y**0 | 3.30427E−25 |
| x**8*y**2 | −1.50683E−25 |
| x**6*y**4 | −3.23971E−24 |
| x**4*y**6 | −3.98281E−24 |
| x**2*y**8 | −1.17092E−23 |
| x**0*y**10 | −1.83207E−22 |
| x**10*y**1 | 1.40473E−27 |
| x**8*y**3 | −2.19658E−27 |
| x**6*y**5 | −2.33409E−26 |
| x**4*y**7 | −6.97757E−28 |
| x**2*y**9 | 2.62002E−25 |
| x**0*y**11 | 7.9641E−25 |
| x**12*y**0 | −8.28736E−31 |
| x**10*y**2 | −1.87304E−30 |
| x**8*y**4 | 1.37508E−28 |
| x**6*y**6 | 3.42595E−28 |
| x**4*y**8 | 2.44385E−28 |
| x**2*y**10 | 5.2848E−28 |
| x**0*y**12 | 1.62923E−26 |
| x**12*y**1 | −3.88752E−32 |
| x**10*y**3 | 1.93686E−31 |
| x**8*y**5 | 1.3086E−30 |
| x**6*y**7 | 1.56541E−30 |
| x**4*y**9 | −8.4397E−30 |
| x**2*y**11 | −2.88096E−29 |
| x**0*y**13 | 2.82056E−29 |
| x**14*y**0 | −1.12864E−34 |
| x**12*y**2 | 3.21896E−34 |
| x**10*y**4 | −1.05836E−34 |
| x**8*y**6 | −6.35732E−33 |
| x**6*y**8 | −1.70435E−32 |
| x**4*y**10 | −3.31674E−32 |
| x**2*y**12 | −5.82229E−32 |
| x**0*y**14 | −5.01115E−31 |
| x**14*y**1 | 3.68373E−37 |
| x**12*y**3 | −4.12326E−36 |
| x**10*y**5 | −3.26012E−35 |
| x**8*y**7 | −5.76316E−35 |
| x**6*y**9 | 1.54417E−35 |
| x**4*y**11 | 7.08541E−34 |
| x**2*y**13 | 1.34306E−33 |
| x**0*y**15 | −2.90776E−33 |
| x**16*y**0 | 1.53482E−39 |
| x**14*y**2 | −5.74708E−39 |
| x**12*y**4 | −5.8462E−38 |
| x**10*y**6 | −1.29929E−37 |
| x**8*y**8 | −4.28537E−39 |
| x**6*y**10 | 6.85439E−37 |
| x**4*y**12 | 3.67071E−36 |
| x**2*y**14 | 5.39185E−36 |
| x**0*y**16 | −4.76692E−36 |
| M5 | |
| RDX | −11890.09546 |
| RDY | 1948.501643 |
| CCX | 0 |
| CCY | 0 |
| x**2*y**1 | 3.91582E−08 |
| x**0*y**3 | 1.5761E−07 |
| x**4*y**0 | 7.43501E−11 |
| x**2*y**2 | 7.05009E−10 |
| x**0*y**4 | −3.68053E−10 |
| x**4*y**1 | 1.19197E−13 |
| x**2*y**3 | −7.97747E−13 |
| x**0*y**5 | 7.8445E−12 |
| x**6*y**0 | 6.36753E−17 |
| x**4*y**2 | 6.58903E−16 |
| x**2*y**4 | 5.43444E−15 |
| x**0*y**6 | −4.42479E−14 |
| x**6*y**1 | 2.3605E−19 |
| x**4*y**3 | 9.3044E−19 |
| x**2*y**5 | −3.3358E−17 |
| x**0*y**7 | −8.37373E−16 |
| x**8*y**0 | 2.52371E−22 |
| x**6*y**2 | −2.36839E−21 |
| x**4*y**4 | −1.45942E−20 |
| x**2*y**6 | −4.40299E−19 |
| x**0*y**8 | 5.22947E−19 |
| x**8*y**1 | −1.18964E−24 |
| x**6*y**3 | 1.53316E−24 |
| x**4*y**5 | 1.14129E−22 |
| x**2*y**7 | 2.93367E−21 |
| x**0*y**9 | 8.76134E−20 |
| x**10*y**0 | 1.93051E−28 |
| x**8*y**2 | 1.11538E−25 |
| x**6*y**4 | 4.69174E−25 |
| x**4*y**6 | −3.001E−25 |
| x**2*y**8 | 3.61875E−23 |
| x**0*y**10 | −4.25823E−22 |
| x**10*y**1 | 3.60183E−29 |
| x**8*y**3 | −3.77434E−28 |
| x**6*y**5 | −1.38725E−26 |
| x**4*y**7 | −7.4725E−26 |
| x**2*y**9 | −6.65131E−25 |
| x**0*y**11 | −2.45371E−24 |
| x**12*y**0 | −9.67967E−32 |
| x**10*y**2 | −1.79458E−30 |
| x**8*y**4 | −7.7584E−30 |
| x**6*y**6 | 8.49318E−29 |
| x**4*y**8 | 3.82137E−28 |
| x**2*y**10 | 2.20461E−27 |
| x**0*y**12 | 3.76558E−26 |
| x**12*y**1 | −4.93323E−34 |
| x**10*y**3 | 5.39021E−33 |
| x**8*y**5 | 3.08066E−31 |
| x**6*y**7 | 2.67732E−30 |
| x**4*y**9 | 1.03906E−29 |
| x**2*y**11 | 4.79294E−29 |
| x**0*y**13 | −4.1849E−29 |
| x**14*y**0 | 1.75708E−36 |
| x**12*y**2 | 1.20844E−35 |
| x**10*y**4 | −3.17403E−35 |
| x**8*y**6 | −2.53584E−33 |
| x**6*y**8 | −2.07181E−32 |
| x**4*y**10 | −5.88132E−32 |
| x**2*y**12 | −3.80798E−31 |
| x**0*y**14 | −1.76132E−30 |
| x**14*y**1 | 2.95101E−39 |
| x**12*y**3 | −1.82158E−38 |
| x**10*y**5 | −2.24997E−36 |
| x**8*y**7 | −2.87492E−35 |
| x**6*y**9 | −1.42187E−34 |
| x**4*y**11 | −4.38699E−34 |
| x**2*y**13 | −1.1531E−33 |
| x**0*y**15 | 1.85014E−33 |
| x**16*y**0 | −1.03238E−41 |
| x**14*y**2 | −1.72605E−41 |
| x**12*y**4 | 1.2568E−39 |
| x**10*y**6 | 2.61985E−38 |
| x**8*y**8 | 2.60004E−37 |
| x**6*y**10 | 1.09248E−36 |
| x**4*y**12 | 2.55413E−36 |
| x**2*y**14 | 1.13059E−35 |
| x**0*y**16 | 3.74112E−35 |
| M6 | |
| RDX | −1280.21818 |
| RDY | −869.0931662 |
| CCX | 0 |
| CCY | 0 |
| x**2*y**1 | 5.7076E−09 |
| x**0*y**3 | 5.65117E−09 |
| x**4*y**0 | −2.41077E−11 |
| x**2*y**2 | −8.39235E−11 |
| x**0*y**4 | 1.3144E−11 |
| x**4*y**1 | −2.45263E−15 |
| x**2*y**3 | 1.48181E−14 |
| x**0*y**5 | −8.32295E−14 |
| x**6*y**0 | −2.47133E−17 |
| x**4*y**2 | −1.33784E−16 |
| x**2*y**4 | −1.45038E−16 |
| x**0*y**6 | 1.57803E−16 |
| x**6*y**1 | −1.62095E−20 |
| x**4*y**3 | −2.14742E−20 |
| x**2*y**5 | 8.43669E−20 |
| x**0*y**7 | 1.40077E−18 |
| x**8*y**0 | −2.46983E−23 |
| x**6*y**2 | 5.99364E−23 |
| x**4*y**4 | −1.87305E−22 |
| x**2*y**6 | −1.39671E−22 |
| x**0*y**8 | 4.49649E−21 |
| x**8*y**1 | 1.97491E−25 |
| x**6*y**3 | −2.68015E−25 |
| x**4*y**5 | −2.17106E−24 |
| x**2*y**7 | −3.87791E−24 |
| x**0*y**9 | −3.4243E−23 |
| x**10*y**0 | −4.35114E−28 |
| x**8*y**2 | −5.9536E−27 |
| x**6*y**4 | −5.45942E−27 |
| x**4*y**6 | 8.97011E−27 |
| x**2*y**8 | 1.12261E−26 |
| x**0*y**10 | −3.93354E−26 |
| x**10*y**1 | −4.34164E−30 |
| x**8*y**3 | 1.19219E−29 |
| x**6*y**5 | 7.95985E−29 |
| x**4*y**7 | 1.29796E−28 |
| x**2*y**9 | 1.55411E−28 |
| x**0*y**11 | 3.82456E−28 |
| x**12*y**0 | 1.19556E−32 |
| x**10*y**2 | 7.49719E−32 |
| x**8*y**4 | 9.46131E−32 |
| x**6*y**6 | −2.62551E−31 |
| x**4*y**8 | −5.69034E−31 |
| x**2*y**10 | −2.45877E−31 |
| x**0*y**12 | 1.33488E−30 |
| x**12*y**1 | 4.99519E−35 |
| x**10*y**3 | −1.49741E−34 |
| x**8*y**5 | −1.3064E−33 |
| x**6*y**7 | −2.71769E−33 |
| x**4*y**9 | −2.7525E−33 |
| x**2*y**11 | −2.28529E−33 |
| x**0*y**13 | −3.62272E−33 |
| x**14*y**0 | −1.25765E−37 |
| x**12*y**2 | −3.98544E−37 |
| x**10*y**4 | −4.35287E−37 |
| x**8*y**6 | 3.92499E−36 |
| x**6*y**8 | 1.10698E−35 |
| x**4*y**10 | 1.17537E−35 |
| x**2*y**12 | 1.69317E−36 |
| x**0*y**14 | −1.91788E−35 |
| x**14*y**1 | −2.37116E−40 |
| x**12*y**3 | 5.89057E−40 |
| x**10*y**5 | 7.57224E−39 |
| x**8*y**7 | 2.07265E−38 |
| x**6*y**9 | 2.63188E−38 |
| x**4*y**11 | 1.86594E−38 |
| x**2*y**13 | 1.39015E−38 |
| x**0*y**15 | 1.12768E−38 |
| x**16*y**0 | 4.86795E−43 |
| x**14*y**2 | 3.43026E−43 |
| x**12*y**4 | −2.40386E−42 |
| x**10*y**6 | −2.5635E−41 |
| x**8*y**8 | −8.10158E−41 |
| x**6*y**10 | −1.0911E−40 |
| x**4*y**12 | −7.75965E−41 |
| x**2*y**14 | 5.42808E−42 |
| x**0*y**16 | 1.64467E−40 |

Table 5 for FIG. 3

| x [mm] | y [mm] |
|---|---|
| 214.702543 | −3.825087971 |
| 211.3102113 | 16.54027102 |
| 199.5622577 | 36.82504573 |
| 179.9087488 | 56.20376678 |
| 153.1528935 | 73.85417137 |
| 120.3912328 | 88.96627989 |
| 82.9435883 | 100.7426815 |
| 42.2870241 | 108.3778905 |
| 1.32727E−14 | 111.0574173 |
| −42.2870241 | 108.3778905 |
| −82.9435883 | 100.7426815 |
| −120.3912328 | 88.96627989 |
| −153.1528935 | 73.85417137 |
| −179.9087488 | 56.20376678 |
| −199.5622577 | 36.82504573 |
| −211.3102113 | 16.54027102 |
| −214.702543 | −3.825087971 |
| −209.6746343 | −23.52568469 |
| −196.5420455 | −41.97169988 |
| −175.9617075 | −58.72205986 |
| −148.86935 | −73.46207291 |
| −116.4086757 | −85.94067603 |
| −79.8657956 | −95.79662783 |
| −40.60510613 | −102.3470385 |
| −3.81965E−14 | −104.6844586 |
| 40.60510613 | −102.3470385 |
| 79.8657956 | −95.79662783 |
| 116.4086757 | −85.94067603 |
| 148.86935 | −73.46207291 |
| 175.9617075 | −58.72205986 |
| 196.5420455 | −41.97169988 |
| 209.6746343 | −23.52568469 |

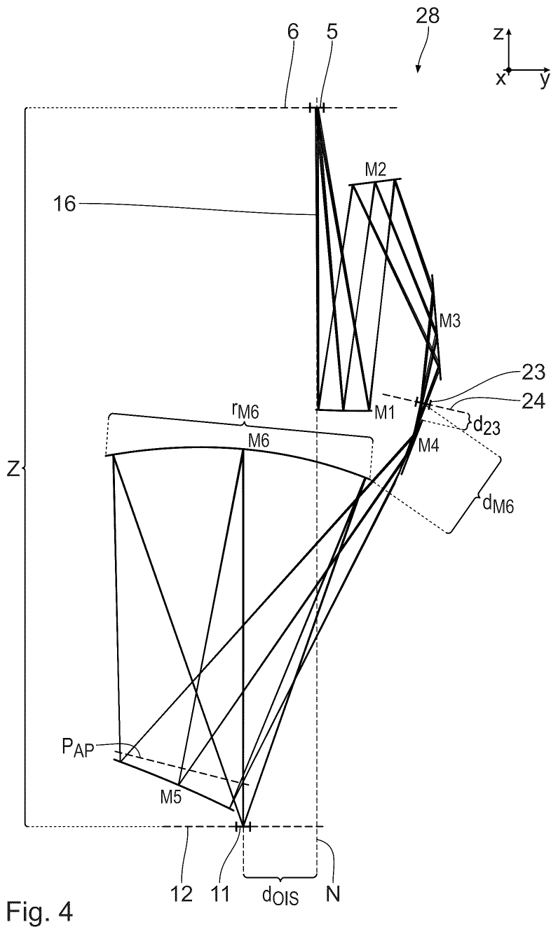

FIG. 4 shows a further embodiment of a projection optical unit or imaging optical unit 28, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

In terms of basic structure, the projection optical unit 28 according to FIG. 4 is similar to the projection optical unit 27 according to FIG. 3. A difference lies in the fact that a reflection surface of the mirror M6 in the projection optical unit 28 is significantly larger in relation to the mirror M1, for example.

The distance d₂₃ of a further GI mirror M4 from the intermediate image 23 along the imaging beam path of the illumination light 16 is 161.74 mm in the case of the embodiment according to FIG. 4 for the projection optical unit 28; the distance d_{M6} between the intermediate image 23 and the last mirror M6 is 144.96 mm.

The image field 11 is rectangular.

The following tables summarize parameters and the optical design of the projection optical unit 28. In terms of their structure, these tables correspond to those already explained above in conjunction with FIG. 2.

Table 1 for FIG. 4

| Wavelength | 13.5 | nm |
|---|---|---|
| Image-side numerical aperture | 0.33 | |
| Image field size in the x- and y- | 52 mm x 2.00 mm | |
| directions | | |
| βₓ | −4.00 (without intermediate | |
| | image) | |
| β_{y} | 4.00 (with intermediate image) | |
| Chief ray angle | 5.00° | |
| Étendue | 11.33 | mm² |
| Mean wavefront aberration RMS | 11.48 | mλ |
| Overall transmission | 12.53% | |
| Position of the entrance pupil (x) | 3462.74 | mm |
| Position of the entrance pupil (y) | 1425.17 | mm |
| Object-image offset in the y-direction | 204.45 | mm |
| Distance between M5 and image plane | 53 | mm |
| Distance between the object plane and | 2000.06 | mm |

| image plane | |
|---|---|
| Tilt between the object and | 0.0° |
| Image plane | |
| Installation space cuboid | (755 × 906 × 1748) mm |

Table 2a for FIG. 4

| | M1 | M2 | M3 |
|---|---|---|---|
| Maximum angle of incidence [°] | 9.5 | 17.6 | 77.8 |
| Minimum angle of incidence [°] | 4.3 | 12.1 | 67.2 |
| Extent of the reflection surface | 297.4 | 330.2 | 421.2 |
| in the x-direction [mm] | | | |
| Extent of the reflection surface | 145.0 | 121.0 | 231.8 |
| in the y-direction [mm] | | | |
| Maximum mirror diameter [mm] | 297.4 | 330.3 | 421.3 |

Table 2b for FIG. 4

| | M4 | M5 | M6 |
|---|---|---|---|
| Maximum angle of incidence [°] | 86.9 | 21.7 | 10.9 |
| Minimum angle of incidence [°] | 71.9 | 2.2 | 1.5 |
| Extent of the reflection surface | 476.1 | 636.4 | 754.9 |
| in the x-direction [mm] | | | |
| Extent of the reflection surface | 170.2 | 329.9 | 705.5 |
| in the y-direction [mm] | | | |
| Maximum mirror diameter [mm] | 476.1 | 636.5 | 755.3 |

Table 3a for FIG. 4

| | x-distance [mm] | y-distance [mm] | z-distance [mm] |
|---|---|---|---|
| Object field | 0 | −204.4467288 | 2000.061519 |
| M1 | 0 | −278.2371827 | 1156.584388 |
| M2 | 0 | −365.9821683 | 1793.842161 |
| M3 | 0 | −537.2410973 | 1367.635051 |
| M4 | 0 | −464.6569758 | 1054.504604 |
| M5 | 0 | 179.9241685 | 115.4174127 |
| M6 | 0 | 0 | 1048.078508 |
| Stop (AS) | 0 | 178.9757725 | 116.7991262 |
| Image field | 0 | 0 | 0 |

Table 3b for FIG. 4

| | Tilt about the x- | Tilt about the y- | Tilt about the z- |
|---|---|---|---|
| | axis [degrees] | axis [degrees] | axis [degrees] |
| Object field | 0.000285352 | 0 | 0 |
| M1 | 1.420065382 | 180 | 0 |
| M2 | −7.02572384 | 0 | 0 |
| M3 | 85.57973383 | 0 | 180 |
| M4 | 113.7580602 | 0 | 0 |
| M5 | 22.69221468 | 180 | 0 |
| M6 | 5.459534903 | 0 | 0 |
| Stop (AS) | 22.8746781 | 0 | 0 |
| Image field | 0 | 0 | 0 |

Table 4 for FIG. 4

| x**i * y**j | Coefficient |
|---|---|
| M1 | |
| RDX | −11208.07255 |
| RDY | −1344.738824 |
| CCX | 0 |
| CCY | 0 |
| x**2*y**1 | 1.39259E−09 |
| x**0*y**3 | 1.48047E−07 |
| x**4*y**0 | −2.56848E−11 |
| x**2*y**2 | −9.23789E−11 |
| x**0*y**4 | 6.72024E−10 |
| x**4*y**1 | 4.8165E−15 |
| x**2*y**3 | −2.18656E−13 |
| x**0*y**5 | 1.69836E−12 |
| x**6*y**0 | 1.28673E−17 |
| x**4*y**2 | 2.13817E−17 |
| x**2*y**4 | −7.37916E−16 |
| x**0*y**6 | −3.70761E−14 |
| x**6*y**1 | 5.10103E−20 |
| x**4*y**3 | −5.36937E−20 |
| x**2*y**5 | 1.86242E−17 |
| x**0*y**7 | 1.11843E−16 |
| x**8*y**0 | 3.06069E−22 |
| x**6*y**2 | 1.91516E−21 |
| x**4*y**4 | 1.11407E−21 |
| x**2*y**6 | −1.05139E−19 |
| x**0*y**8 | 2.8173E−18 |
| x**8*y**1 | −5.92391E−24 |
| x**6*y**3 | −2.54507E−24 |
| x**4*y**5 | 1.34242E−22 |
| x**2*y**7 | −2.08057E−21 |
| x**0*y**9 | 2.1043E−23 |
| x**10*y**0 | −3.22169E−26 |
| x**8*y**2 | −1.49074E−25 |
| x**6*y**4 | −4.65411E−25 |
| x**4*y**6 | 1.82554E−24 |
| x**2*y**8 | 3.38783E−24 |
| x**0*y**10 | −1.35796E−22 |
| x**10*y**1 | 3.30908E−28 |
| x**8*y**3 | 1.36715E−27 |
| x**6*y**5 | −7.04728E−27 |
| x**4*y**7 | −8.48476E−27 |
| x**2*y**9 | 1.36793E−25 |
| x**0*y**11 | 6.00218E−24 |
| x**12*y**0 | 1.40497E−30 |
| x**10*y**2 | 8.1775E−30 |
| x**8*y**4 | 3.00775E−29 |
| x**6*y**6 | −3.81189E−29 |
| x**4*y**8 | −3.00653E−28 |
| x**2*y**10 | −4.34186E−27 |
| x**0*y**12 | 3.33539E−27 |
| x**12*y**1 | −6.27848E−33 |
| x**10*y**3 | −4.77988E−32 |
| x**8*y**5 | −8.54973E−33 |
| x**6*y**7 | 1.23721E−30 |
| x**4*y**9 | −1.1171E−30 |
| x**2*y**11 | 8.01216E−30 |
| x**0*y**13 | −6.14003E−28 |
| x**14*y**0 | −2.23647E−35 |
| x**12*y**2 | −1.80485E−34 |
| x**10*y**4 | −5.69631E−34 |
| x**8*y**6 | −1.83695E−33 |
| x**6*y**8 | 1.67586E−32 |
| x**4*y**10 | −9.68665E−33 |
| x**2*y**12 | 5.23363E−31 |
| x**0*y**14 | −1.32984E−30 |
| M2 | |
| RDX | 4476.764772 |
| RDY | −3218.313329 |
| CCX | 0 |
| CCY | 0 |
| x**2*y**1 | 6.95868E−08 |
| x**0*y**3 | −1.67782E−07 |
| x**4*y**0 | 6.92405E−12 |
| x**2*y**2 | −3.97072E−11 |
| x**0*y**4 | −3.67006E−10 |
| x**4*y**1 | 1.04231E−13 |
| x**2*y**3 | −1.21968E−13 |
| x**0*y**5 | 1.23333E−12 |
| x**6*y**0 | −6.33385E−17 |
| x**4*y**2 | −3.92992E−16 |
| x**2*y**4 | 5.21048E−16 |
| x**0*y**6 | −3.64515E−15 |
| x**6*y**1 | 1.57188E−19 |
| x**4*y**3 | 2.98303E−18 |
| x**2*y**5 | −3.62833E−17 |
| x**0*y**7 | −1.03682E−16 |
| x**8*y**0 | −3.27748E−22 |
| x**6*y**2 | −1.8942E−20 |
| x**4*y**4 | −1.25287E−19 |
| x**2*y**6 | 1.6742E−19 |
| x**0*y**8 | 1.78107E−18 |
| x**8*y**1 | −3.07948E−24 |
| x**6*y**3 | −5.12163E−23 |
| x**4*y**5 | 1.70477E−22 |
| x**2*y**7 | 4.1822E−21 |
| x**0*y**9 | −6.77057E−20 |
| x**10*y**0 | 2.90207E−26 |
| x**8*y**2 | 1.23282E−24 |
| x**6*y**4 | 1.08272E−23 |
| x**4*y**6 | 2.16306E−23 |
| x**2*y**8 | −1.95156E−23 |
| x**0*y**10 | 3.64732E−22 |
| x**10*y**1 | −5.82884E−29 |
| x**8*y**3 | 1.82739E−27 |
| x**6*y**5 | 1.27832E−26 |
| x**4*y**7 | −6.74549E−26 |
| x**2*y**9 | −1.00505E−24 |
| x**0*y**11 | 4.58356E−24 |
| x**12*y**0 | −9.29616E−31 |
| x**10*y**2 | −4.35975E−29 |
| x**8*y**4 | −5.20312E−28 |
| x**6*y**6 | −1.94333E−27 |
| x**4*y**8 | −7.53353E−28 |
| x**2*y**10 | 7.70646E−28 |
| x**0*y**12 | 2.49496E−26 |
| x**12*y**1 | 1.71017E−33 |
| x**10*y**3 | −6.70729E−33 |
| x**8*y**5 | −1.50536E−31 |
| x**6*y**7 | −5.88449E−32 |
| x**4*y**9 | 9.37637E−30 |
| x**2*y**11 | −1.683E−29 |
| x**0*y**13 | 1.49788E−29 |
| x**14*y**0 | 1.1104E−35 |
| x**12*y**2 | 6.01085E−34 |
| x**10*y**4 | 8.61102E−33 |
| x**8*y**6 | 5.61135E−32 |
| x**6*y**8 | 8.5523E−33 |
| x**4*y**10 | −1.79226E−32 |
| x**2*y**12 | −7.49518E−32 |
| x**0*y**14 | 4.41352E−32 |
| M3 | |
| RDX | −6357.283858 |
| RDY | −3164.492834 |
| CCX | 0 |
| CCY | 0 |
| x**2*y**1 | −5.26662E−08 |
| x**0*y**3 | −1.66786E−07 |
| x**4*y**0 | 5.7459E−11 |
| x**2*y**2 | −5.62733E−11 |
| x**0*y**4 | −3.47019E−10 |
| x**4*y**1 | −1.1364E−13 |
| x**2*y**3 | −6.34073E−14 |
| x**0*y**5 | −1.17695E−12 |
| x**6*y**0 | 1.0888E−16 |
| x**4*y**2 | 1.73811E−16 |
| x**2*y**4 | −1.92565E−16 |
| x**0*y**6 | −4.62673E−15 |
| x**6*y**1 | −1.45351E−19 |
| x**4*y**3 | 2.60847E−19 |
| x**2*y**5 | 5.65235E−18 |
| x**0*y**7 | −2.16621E−17 |
| x**8*y**0 | −1.94793E−22 |
| x**6*y**2 | 5.0184E−21 |
| x**4*y**4 | 2.77732E−20 |
| x**2*y**6 | 5.29097E−20 |
| x**0*y**8 | −1.24278E−19 |
| x**8*y**1 | −1.7836E−25 |
| x**6*y**3 | −3.50734E−23 |
| x**4*y**5 | −1.51844E−22 |
| x**2*y**7 | −4.03222E−22 |
| x**0*y**9 | −8.40885E−22 |
| x**10*y**0 | −2.6709E−27 |
| x**8*y**2 | −2.08359E−25 |
| x**6*y**4 | −1.48176E−24 |
| x**4*y**6 | −3.72362E−24 |
| x**2*y**8 | −5.46052E−24 |
| x**0*y**10 | −6.93516E−24 |
| x**10*y**1 | 6.54735E−29 |
| x**8*y**3 | 9.69143E−28 |
| x**6*y**5 | 5.95188E−27 |
| x**4*y**7 | 1.13428E−26 |
| x**2*y**9 | 1.5801E−26 |
| x**0*y**11 | −4.61236E−26 |
| x**12*y**0 | 9.2175E−32 |
| x**10*y**2 | 4.26464E−30 |
| x**8*y**4 | 4.00127E−29 |
| x**6*y**6 | 1.47559E−28 |
| x**4*y**8 | 2.17941E−28 |
| x**2*y**10 | 3.42105E−28 |
| x**0*y**12 | −1.09681E−28 |
| x**12*y**1 | −5.69934E−34 |
| x**10*y**3 | −9.11529E−33 |
| x**8*y**5 | −8.47406E−32 |
| x**6*y**7 | −2.38366E−31 |
| x**4*y**9 | −2.79919E−31 |
| x**2*y**11 | 8.70008E−31 |
| x**0*y**13 | 4.76414E−31 |
| x**14*y**0 | −7.48404E−37 |
| x**12*y**2 | −3.4991E−35 |
| x**10*y**4 | −3.94589E−34 |
| x**8*y**6 | −2.05389E−33 |
| x**6*y**8 | −4.33045E−33 |
| x**4*y**10 | −4.57826E−33 |
| x**2*y**12 | −7.73019E−34 |
| x**0*y**14 | 2.20808E−33 |
| M4 | |
| RDX | −11494.41885 |
| RDY | 17252.5534 |
| CCX | 0 |
| CCY | 0 |
| x**2*y**1 | −1.43828E−08 |
| x**0*y**3 | 4.78741E−08 |
| x**4*y**0 | 7.64913E−11 |
| x**2*y**2 | 6.35361E−11 |
| x**0*y**4 | 2.81984E−10 |
| x**4*y**1 | 1.35268E−13 |
| x**2*y**3 | 4.37973E−13 |
| x**0*y**5 | 1.04544E−12 |
| x**6*y**0 | 5.83814E−17 |
| x**4*y**2 | 4.24163E−16 |
| x**2*y**4 | 9.87846E−16 |
| x**0*y**6 | 4.4741E−15 |
| x**6*y**1 | 4.20752E−19 |
| x**4*y**3 | 8.51707E−19 |
| x**2*y**5 | 1.84254E−17 |
| x**0*y**7 | 1.481E−16 |
| x**8*y**0 | 4.28586E−22 |
| x**6*y**2 | 8.2818E−23 |
| x**4*y**4 | 3.26923E−20 |
| x**2*y**6 | 4.40008E−19 |
| x**0*y**8 | 1.91877E−18 |
| x**8*y**1 | −5.59036E−24 |
| x**6*y**3 | −6.69376E−24 |
| x**4*y**5 | 3.86504E−22 |
| x**2*y**7 | 1.48277E−21 |
| x**0*y**9 | 8.56074E−21 |
| x**10*y**0 | −4.49144E−27 |
| x**8*y**2 | −4.57706E−27 |
| x**6*y**4 | 2.21714E−25 |
| x**4*y**6 | −2.94309E−24 |
| x**2*y**8 | −1.82355E−23 |
| x**0*y**10 | 3.79549E−24 |
| x**10*y**1 | 7.90151E−29 |
| x**8*y**3 | 7.43336E−28 |
| x**6*y**5 | −2.19337E−27 |
| x**4*y**7 | −5.11815E−26 |
| x**2*y**9 | −6.35799E−26 |
| x**0*y**11 | −2.40885E−26 |
| x**12*y**0 | 5.00227E−32 |
| x**10*y**2 | 4.58931E−31 |
| x**8*y**4 | −3.08152E−30 |
| x**6*y**6 | −4.70656E−29 |
| x**4*y**8 | −8.15637E−29 |
| x**2*y**10 | 2.04801E−28 |
| x**0*y**12 | 8.04697E−29 |
| x**12*y**1 | −4.55471E−34 |
| x**10*y**3 | −8.36628E−33 |
| x**8*y**5 | −5.76303E−32 |
| x**6*y**7 | −2.20067E−32 |
| x**4*y**9 | 6.87778E−32 |
| x**2*y**11 | −1.96002E−31 |
| x**0*y**13 | −5.53956E−32 |
| x**14*y**0 | −2.4706E−37 |
| x**12*y**2 | −5.2623E−36 |
| x**10*y**4 | −4.27356E−35 |
| x**8*y**6 | 6.2967E−35 |
| x**6*y**8 | −1.62748E−34 |
| x**4*y**10 | −1.06077E−34 |
| x**2*y**12 | 3.62958E−34 |
| x**0*y**14 | 1.1159E−34 |
| M5 | |
| RDX | −9680.194133 |
| RDY | 3937.487507 |
| CCX | 0 |
| CCY | 0 |
| x**2*y**1 | 3.46417E−08 |
| x**0*y**3 | −8.30817E−10 |
| x**4*y**0 | 2.36037E−11 |
| x**2*y**2 | 1.40381E−10 |
| x**0*y**4 | −2.56285E−10 |
| x**4*y**1 | 2.0699E−14 |
| x**2*y**3 | −3.93035E−14 |
| x**0*y**5 | 5.06265E−13 |
| x**6*y**0 | 9.07882E−18 |
| x**4*y**2 | 6.67634E−17 |
| x**2*y**4 | −8.88078E−18 |
| x**0*y**6 | 3.48909E−16 |
| x**6*y**1 | 1.09493E−20 |
| x**4*y**3 | 4.65264E−22 |
| x**2*y**5 | 9.04955E−19 |
| x**0*y**7 | 3.36833E−18 |
| x**8*y**0 | 1.92656E−24 |
| x**6*y**2 | 6.88398E−24 |
| x**4*y**4 | −1.34222E−22 |
| x**2*y**6 | −2.241E−21 |
| x**0*y**8 | −5.15486E−20 |
| x**8*y**1 | 1.29985E−26 |
| x**6*y**3 | 6.78294E−26 |
| x**4*y**5 | −2.1986E−25 |
| x**2*y**7 | −1.07563E−23 |
| x**0*y**9 | 2.38469E−22 |
| x**10*y**0 | 1.89331E−29 |
| x**8*y**2 | 3.99594E−28 |
| x**6*y**4 | 4.40048E−27 |
| x**4*y**6 | 1.37894E−26 |
| x**2*y**8 | 8.01009E−26 |
| x**0*y**10 | 5.5896E−26 |
| x**10*y**1 | −4.66011E−32 |
| x**8*y**3 | −5.79742E−31 |
| x**6*y**5 | −3.08318E−31 |
| x**4*y**7 | 4.86371E−29 |
| x**2*y**9 | 2.35714E−28 |
| x**0*y**11 | −1.96925E−27 |
| x**12*y**0 | −1.22427E−34 |
| x**10*y**2 | −2.78418E−33 |
| x**8*y**4 | −3.8088E−32 |
| x**6*y**6 | −2.32134E−31 |
| x**4*y**8 | −5.24814E−31 |
| x**2*y**10 | −1.30113E−30 |
| x**0*y**12 | 4.12924E−30 |
| x**12*y**1 | 1.4078E−37 |
| x**10*y**3 | 2.24413E−36 |
| x**8*y**5 | 7.04046E−36 |
| x**6*y**7 | −3.56567E−35 |
| x**4*y**9 | −6.92191E−34 |
| x**2*y**11 | 3.67887E−33 |
| x**0*y**13 | −7.616E−33 |
| x**14*y**0 | 3.52911E−40 |
| x**12*y**2 | 8.85878E−39 |
| x**10*y**4 | 1.3064E−37 |
| x**8*y**6 | 1.07199E−36 |
| x**6*y**8 | 3.97978E−36 |
| x**4*y**10 | 6.67045E−36 |
| x**2*y**12 | −1.91692E−35 |
| x**0*y**14 | −1.35038E−35 |
| M6 | |
| RDX | −1893.654231 |
| RDY | −1300.90978 |
| CCX | 0 |
| CCY | 0 |
| x**2*y**1 | −7.80857E−10 |
| x**0*y**3 | 6.88271E−09 |
| x**4*y**0 | −5.79661E−12 |
| x**2*y**2 | −2.07313E−11 |
| x**0*y**4 | 1.08957E−11 |
| x**4*y**1 | −2.28206E−15 |
| x**2*y**3 | −1.60976E−15 |
| x**0*y**5 | −1.55499E−15 |
| x**6*y**0 | −3.31103E−18 |
| x**4*y**2 | −1.58343E−17 |
| x**2*y**4 | −8.00512E−18 |
| x**0*y**6 | 8.92389E−18 |
| x**6*y**1 | −1.04621E−21 |
| x**4*y**3 | −3.78192E−21 |
| x**2*y**5 | −9.76699E−21 |
| x**0*y**7 | −2.30873E−20 |
| x**8*y**0 | −6.2611E−25 |
| x**6*y**2 | −5.23E−24 |
| x**4*y**4 | −4.80813E−24 |
| x**2*y**6 | 1.05872E−23 |
| x**0*y**8 | 5.51964E−23 |
| x**8*y**1 | −1.05338E−27 |
| x**6*y**3 | −2.31487E−27 |
| x**4*y**5 | −5.76479E−27 |
| x**2*y**7 | −4.47362E−26 |
| x**0*y**9 | −1.57888E−25 |
| x**10*y**0 | −5.46916E−30 |
| x**8*y**2 | −3.36658E−29 |
| x**6*y**4 | −1.03331E−28 |
| x**4*y**6 | −1.16879E−28 |
| x**2*y**8 | 7.06067E−29 |
| x**0*y**10 | 1.73327E−28 |
| x**10*y**1 | 3.18617E−33 |
| x**8*y**3 | −3.00755E−33 |
| x**6*y**5 | −4.09653E−32 |
| x**4*y**7 | −6.6151E−32 |
| x**2*y**9 | 6.03947E−33 |
| x**0*y**11 | −2.54763E−32 |
| x**12*y**0 | 2.62629E−35 |
| x**10*y**2 | 1.61765E−34 |
| x**8*y**4 | 5.83302E−34 |
| x**6*y**6 | 1.15924E−33 |
| x**4*y**8 | 9.76661E−34 |
| x**2*y**10 | −3.25583E−34 |
| x**0*y**12 | −1.03576E−33 |
| x**12*y**1 | −7.16739E−39 |
| x**10*y**3 | −1.2194E−39 |
| x**8*y**5 | 8.85416E−38 |
| x**6*y**7 | 1.3296E−37 |
| x**4*y**9 | −3.96863E−37 |
| x**2*y**11 | −1.9069E−36 |
| x**0*y**13 | −1.38944E−36 |
| x**14*y**0 | −5.60301E−41 |
| x**12*y**2 | −3.79077E−40 |
| x**10*y**4 | −1.42906E−39 |
| x**8*y**6 | −3.61592E−39 |
| x**6*y**8 | −4.49566E−39 |
| x**4*y**10 | −1.80657E−39 |
| x**2*y**12 | 4.47525E−39 |
| x**0*y**14 | 6.36335E−39 |

Table 5 for FIG. 4

| x [mm] | y [mm] |
|---|---|
| 317.4971505 | −5.026251913 |
| 312.0878594 | 26.59479452 |
| 294.3844538 | 58.24391499 |
| 265.1021087 | 88.62369496 |
| 225.4596609 | 116.2808952 |
| 177.0882574 | 139.7131073 |
| 121.9292747 | 157.5401264 |
| 62.13795678 | 168.6836645 |
| 1.95005E−14 | 172.473578 |
| −62.13795678 | 168.6836645 |
| −121.9292747 | 157.5401264 |
| −177.0882574 | 139.7131073 |
| −225.4596609 | 116.2808952 |
| −265.1021087 | 88.62369496 |
| −294.3844538 | 58.24391499 |
| −312.0878594 | 26.59479452 |
| −317.4971505 | −5.026251913 |
| −310.4582673 | −35.52014872 |
| −291.3835411 | −63.97903121 |
| −261.2011607 | −89.65811725 |
| −221.2626781 | −111.9428853 |
| −173.2341102 | −130.2877634 |
| −118.994665 | −144.1220482 |
| −60.55533452 | −152.8102628 |
| −5.69841E−14 | −155.7850835 |
| 60.55533452 | −152.8102628 |
| 118.994665 | −144.1220482 |
| 173.2341102 | −130.2877634 |
| 221.2626781 | −111.9428853 |
| 261.2011607 | −89.65811725 |
| 291.3835411 | −63.97903121 |
| 310.4582673 | −35.52014872 |

The projection optical unit 28 has an image field with an x-extent of 52 mm and a y-extent of 2.0 mm. The image field 11 of the projection optical unit 28 thus has a maximum extent of more than 26 mm.

In the case of the projection optical unit 28, an arrangement plane PAP for the aperture stop AP is located in the beam path between the mirrors M5 and M6.

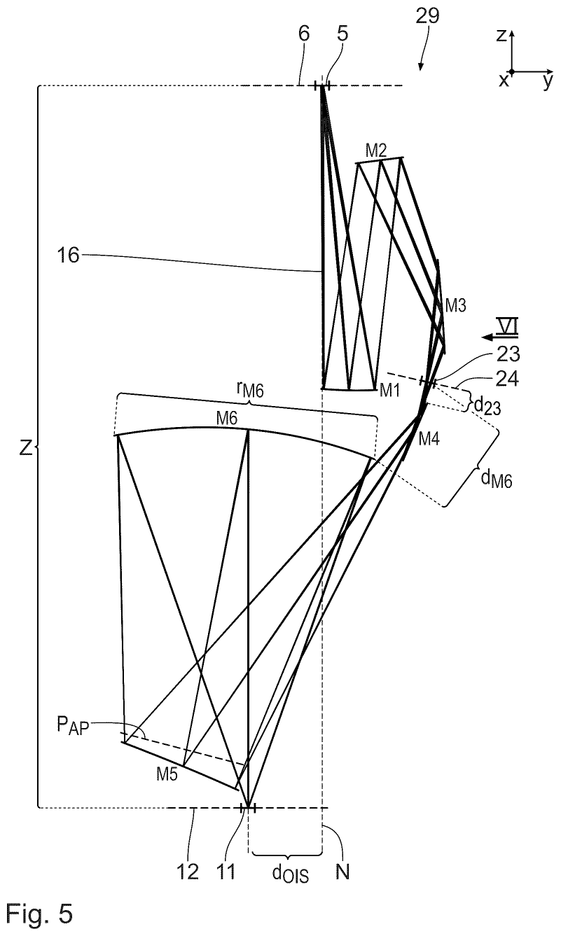

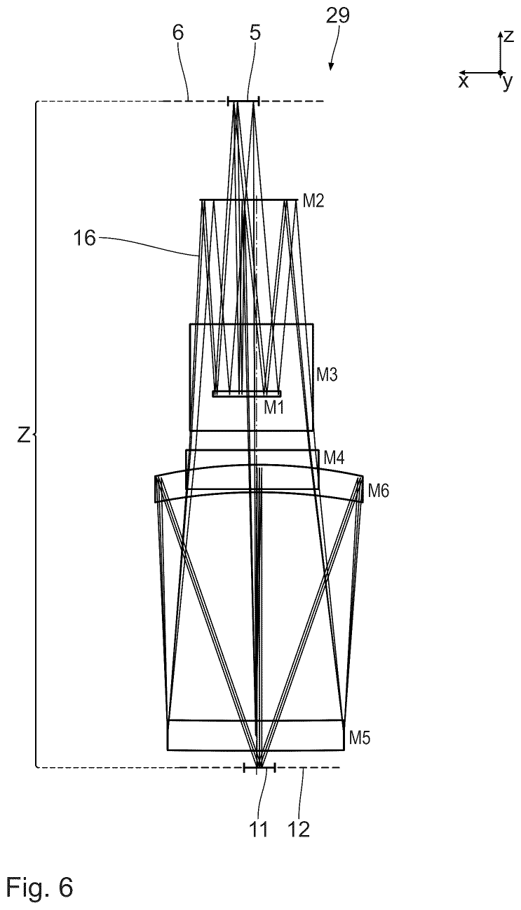

FIGS. 5 and 6 show a further embodiment of a projection optical unit or imaging optical unit 29, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

From the sagittal xz-view according to FIG. 6 of the projection optical unit 29, it is possible to gather that no sagittal intermediate image is present at the location of the meridional intermediate image 23, i.e. in the region of the reflection at the mirror M4. Overall, the projection optical unit 29 has a compact embodiment, i.e. has comparatively low spatial properties with regards to the installation space cuboid.

The distance d₂₃ of a further GI mirror M4 from the intermediate image 23 along the imaging beam path of the illumination light 16 is 39.86 mm in the case of the embodiment according to FIG. 5/6 for the projection optical unit 29; the distance d_{M6} between the intermediate image 23 and the last mirror M6 is 60.59 mm.

The image field 11 is rectangular.

The following tables summarize parameters and the optical design of the projection optical unit 29. In terms of their structure, these tables correspond to those already explained above in conjunction with FIG. 2.

Table 1 for FIG. 5/6

| Wavelength | 13.5 | nm |
|---|---|---|
| Image-side numerical aperture | 0.33 | |
| Image field size in the x- and y- | 26 mm x 2.00 mm | |
| directions | | |
| βₓ | −4.00 (without intermediate | |
| | image) | |
| β_{y} | 4.00 (with intermediate image) | |
| Chief ray angle | 5.00° | |
| Étendue | 5.66 | mm² |
| Mean wavefront aberration RMS | 31.47 | mλ |
| Overall transmission | 12.89% | |
| Position of the entrance pupil (x) | 1674.40 | mm |
| Position of the entrance pupil (y) | 468.96 | mm |
| Object-image offset in the y-direction | 1.20 | mm |
| Distance between M5 and image plane | 32 | mm |
| Distance between the object plane and | 1368.51 | mm |

| image plane | |
|---|---|
| Tilt between the object and | −0.0° |
| Image plane | |
| Installation space cuboid | (437 × 505 × 1135) mm |

Table 2a for FIGS. 5/6

| | M1 | M2 | M3 |
|---|---|---|---|
| Maximum angle of incidence [°] | 14.5 | 18.6 | 80.6 |
| Minimum angle of incidence [°] | 7.1 | 14.3 | 68.0 |
| Extent of the reflection surface | 179.4 | 229.7 | 271.7 |
| in the x-direction [mm] | | | |
| Extent of the reflection surface | 105.0 | 137.5 | 219.4 |
| in the y-direction [mm] | | | |
| Maximum mirror diameter [mm] | 179.6 | 229.8 | 285.3 |

Table 2b for FIGS. 5/6

| | M4 | M5 | M6 |
|---|---|---|---|
| Maximum angle of incidence [°] | 87.5 | 22.3 | 10.8 |
| Minimum angle of incidence [°] | 73.1 | 1.4 | 2.3 |
| Extent of the reflection surface | 288.1 | 365.0 | 437.4 |
| in the x-direction [mm] | | | |
| Extent of the reflection surface | 88.7 | 157.6 | 413.4 |
| in the y-direction [mm] | | | |
| Maximum mirror diameter [mm] | 288.7 | 365.1 | 437.9 |

Table 3a for FIGS. 5/6

| | x-distance [mm] | y-distance [mm] | z-distance [mm] |
|---|---|---|---|
| Object field | 0 | 1.20224662 | 1368.507919 |
| M1 | 0 | −51.4014965 | 765.0469133 |
| M2 | 0 | −179.3761567 | 1165.800717 |
| M3 | 0 | −291.8877694 | 757.0706101 |
| M4 | 0 | −250.7098238 | 595.1769777 |
| M5 | 0 | 115.0922085 | 66.35102455 |
| M6 | 0 | 0 | 613.2488448 |
| Stop (AS) | 0 | 114.1388219 | 67.72929892 |
| Image field | 0 | 0 | 0 |

Table 3b for FIGS. 5/6

| | Tilt about the x- | Tilt about the y- | Tilt about the z- |
|---|---|---|---|
| | axis [degrees] | axis [degrees] | axis [degrees] |
| Object field | 0.018115433 | 0 | 0 |
| M1 | 6.364105333 | 180 | 0 |
| M2 | 1.159700358 | 0 | 0 |
| M3 | 89.43999162 | 0 | 180 |
| M4 | 114.4716245 | 0 | 0 |
| M5 | 23.27839882 | 180 | 0 |
| M6 | 5.942113206 | 0 | 0 |
| Stop (AS) | 23.31313401 | 0 | 0 |
| Image field | 0 | 0 | 0 |

Table 4 for FIG. 5/6

| x**i * y**j | Coefficient |
|---|---|
| M1 | |
| RDX | −76757.53347 |
| RDY | −1823.181864 |
| CCX | 0 |
| CCY | 0 |
| x**2*y**1 | −2.96647E−08 |
| x**0*y**3 | 1.02865E−06 |
| x**4*y**0 | −8.79668E−11 |
| x**2*y**2 | −3.54281E−10 |
| x**0*y**4 | 1.79201E−09 |
| x**4*y**1 | 9.9452E−14 |
| x**2*y**3 | −2.3127E−12 |
| x**0*y**5 | 6.81358E−11 |
| x**6*y**0 | 2.91716E−16 |
| x**4*y**2 | 4.90766E−15 |
| x**2*y**4 | −1.59904E−14 |
| x**0*y**6 | −1.47266E−12 |
| x**6*v**1 | −5.12794E−18 |
| x**4*y**3 | −4.57353E−17 |
| x**2*y**5 | 3.53868E−16 |
| x**0*y**7 | −3.54722E−16 |
| x**8*y**0 | 9.50579E−22 |
| x**6*y**2 | −2.18644E−18 |
| x**4*y**4 | −8.626E−18 |
| x**2*y**6 | −4.56548E−18 |
| x**0*y**8 | 7.42628E−16 |
| x**8*y**1 | 6.43677E−22 |
| x**6*y**3 | 1.26997E−20 |
| x**4*y**5 | 4.1895E−20 |
| x**2*y**7 | −3.51693E−19 |
| x**0*y**9 | 1.28964E−18 |
| x**10*y**0 | −1.08953E−23 |
| x**8*y**2 | 3.8514E−22 |
| x**6*y**4 | 2.38505E−21 |
| x**4*y**6 | 5.11296E−21 |
| x**2*y**8 | 7.67627E−22 |
| x**0*y**10 | −9.16818E−20 |
| x**10*y**1 | −4.11553E−26 |
| x**8*y**3 | −1.76516E−24 |
| x**6*y**5 | −8.81545E−24 |
| x**4*y**7 | −1.55827E−23 |
| x**2*y**9 | 1.02804E−22 |
| x**0*y**11 | −1.23567E−21 |
| x**12*y**0 | 1.79711E−27 |
| x**10*y**2 | −3.25441E−26 |
| x**8*y**4 | −2.9225E−25 |
| x**6*y**6 | −9.38254E−25 |
| x**4*y**8 | −1.39596E−24 |
| x**2*y**10 | 1.92697E−25 |
| x**0*y**12 | −1.57074E−23 |
| x**12*y**1 | 7.48098E−31 |
| x**10*y**3 | 9.30945E−29 |
| x**8*y**5 | 5.92016E−28 |
| x**6*y**7 | 1.78072E−27 |
| x**4*y**9 | 1.76917E−27 |
| x**2*y**11 | −1.35173E−26 |
| x**0*y**13 | 3.20963E−25 |
| x**14*y**0 | −8.93437E−32 |
| x**12*y**2 | 1.02663E−30 |
| x**10*y**4 | 1.37946E−29 |
| x**8*y**6 | 5.68267E−29 |
| x**6*y**8 | 1.30235E−28 |
| x**4*y**10 | 1.50004E−28 |
| x**2*y**12 | −1.1688E−28 |
| x**0*y**14 | 4.84939E−27 |
| M2 | |
| RDX | −17716.26891 |
| RDY | −1067.099779 |
| CCX | 0 |
| CCY | 0 |
| x**2*y**1 | 1.55058E−07 |
| x**0*y**3 | −7.19941E−07 |
| x**4*y**0 | 3.3529E−11 |
| x**2*y**2 | 1.74934E−11 |
| x**0*y**4 | 1.93131E−09 |
| x**4*y**1 | 1.5889E−14 |
| x**2*y**3 | 1.77221E−12 |
| x**0*y**5 | −2.42811E−11 |
| x**6*y**0 | 1.95168E−16 |
| x**4*y**2 | 1.19812E−15 |
| x**2*y**4 | −3.4763E−15 |
| x**0*y**6 | 2.20432E−13 |
| x**6*v**1 | 1.06351E−18 |
| x**4*y**3 | 1.81969E−17 |
| x**2*y**5 | 5.073E−17 |
| x**0*y**7 | −3.29293E−15 |
| x**8*y**0 | −6.86756E−20 |
| x**6*y**2 | −1.17505E−19 |
| x**4*y**4 | 2.79086E−19 |
| x**2*y**6 | −4.51151E−18 |
| x**0*y**8 | 9.06881E−18 |
| x**8*y**1 | −2.25269E−23 |
| x**6*y**3 | −3.28192E−21 |
| x**4*y**5 | −9.2968E−21 |
| x**2*y**7 | 6.53957E−20 |
| x**0*y**9 | 3.2257E−19 |
| x**10*y**0 | 7.79092E−24 |
| x**8*y**2 | 2.59577E−23 |
| x**6*y**4 | −9.7412E−24 |
| x**4*y**6 | −1.22676E−22 |
| x**2*y**8 | 1.21436E−21 |
| x**0*y**10 | −3.29131E−21 |
| x**10*y**1 | −3.67413E−27 |
| x**8*y**3 | 2.68105E−25 |
| x**6*y**5 | 1.33714E−24 |
| x**4*y**7 | 3.60936E−25 |
| x**2*y**9 | −2.7827E−23 |
| x**0*y**11 | −1.62132E−23 |
| x**12*y**0 | −4.48523E−28 |
| x**10*y**2 | −2.19954E−27 |
| x**8*y**4 | −1.48052E−27 |
| x**6*y**6 | 1.43224E−26 |
| x**4*y**8 | 3.16543E−26 |
| x**2*y**10 | −6.19994E−26 |
| x**0*y**12 | 7.18634E−25 |
| x**12*y**1 | 2.22735E−31 |
| x**10*y**3 | −8.19217E−30 |
| x**8*y**5 | −5.1631E−29 |
| x**6*y**7 | −1.30052E−28 |
| x**4*y**9 | 4.35293E−28 |
| x**2*y**11 | 4.10076E−27 |
| x**0*y**13 | −8.71461E−27 |
| x**14*y**0 | 1.01981E−32 |
| x**12*y**2 | 6.91184E−32 |
| x**10*y**4 | 7.13566E−32 |
| x**8*y**6 | −5.42987E−31 |
| x**6*y**8 | −2.16827E−30 |
| x**4*y**10 | −7.21486E−30 |
| x**2*y**12 | −2.22065E−29 |
| x**0*y**14 | 3.82463E−29 |
| M3 | |
| RDX | 23117.10554 |
| RDY | −6765.445534 |
| CCX | 0 |
| CCY | 0 |
| x**2*y**1 | −1.25775E−07 |
| x**0*y**3 | −5.97146E−08 |
| x**4*y**0 | 2.60512E−10 |
| x**2*y**2 | −3.76402E−10 |
| x**0*y**4 | −2.43756E−10 |
| x**4*y**1 | 5.57095E−14 |
| x**2*y**3 | −2.53695E−12 |
| x**0*y**5 | −5.36974E−13 |
| x**6*y**0 | 5.31443E−18 |
| x**4*y**2 | 7.80816E−16 |
| x**2*y**4 | −2.06928E−14 |
| x**0*y**6 | −8.54455E−15 |
| x**6*v**1 | 7.18793E−18 |
| x**4*y**3 | 2.46572E−17 |
| x**2*y**5 | −1.45494E−16 |
| x**0*y**7 | −1.95483E−17 |
| x**8*y**0 | 4.43009E−20 |
| x**6*y**2 | 5.22449E−20 |
| x**4*y**4 | 3.66033E−19 |
| x**2*y**6 | −3.26317E−19 |
| x**0*y**8 | 1.86457E−18 |
| x**8*y**1 | −6.12571E−22 |
| x**6*y**3 | −1.00955E−21 |
| x**4*y**5 | −3.24426E−21 |
| x**2*y**7 | −7.2677E−21 |
| x**0*y**9 | 2.16101E−20 |
| x**10*y**0 | −2.05562E−24 |
| x**8*y**2 | −5.59558E−24 |
| x**6*y**4 | −2.53433E−23 |
| x**4*y**6 | −7.64898E−23 |
| x**2*y**8 | −3.76992E−22 |
| x**0*y**10 | −6.7624E−23 |
| x**10*y**1 | 2.89223E−26 |
| x**8*y**3 | 5.13698E−26 |
| x**6*y**5 | 2.18544E−25 |
| x**4*y**7 | 8.6476E−25 |
| x**2*y**9 | −5.86211E−24 |
| x**0*y**11 | −3.06666E−24 |
| x**12*y**0 | 4.14886E−29 |
| x**10*y**2 | 2.77176E−28 |
| x**8*y**4 | 1.83142E−27 |
| x**6*y**6 | 3.15343E−27 |
| x**4*y**8 | 2.44973E−26 |
| x**2*y**10 | −4.36291E−26 |
| x**0*y**12 | −2.55364E−26 |
| x**12*y**1 | −5.55262E−31 |
| x**10*y**3 | −9.74406E−31 |
| x**8*y**5 | −5.67959E−30 |
| x**6*y**7 | −2.19373E−29 |
| x**4*y**9 | 1.73312E−28 |
| x**2*y**11 | −1.63888E−28 |
| x**0*y**13 | −9.46313E−29 |
| x**14*y**0 | −3.77553E−35 |
| x**12*y**2 | −5.95095E−33 |
| x**10*y**4 | −4.46759E−32 |
| x**8*y**6 | −1.2154E−31 |
| x**6*y**8 | −2.02799E−31 |
| x**4*y**10 | 4.16871E−31 |
| x**2*y**12 | −2.52553E−31 |
| x**0*y**14 | −1.36743E−31 |
| M4 | |
| RDX | 5938.99065 |
| RDY | 25304.67341 |
| CCX | 0 |
| CCY | 0 |
| x**2*y**1 | 2.68576E−08 |
| x**0*y**3 | −1.7018E−08 |
| x**4*y**0 | 2.88772E−10 |
| x**2*y**2 | 4.93127E−10 |
| x**0*y**4 | −2.99189E−10 |
| x**4*y**1 | 2.82937E−13 |
| x**2*y**3 | 2.09254E−12 |
| x**0*y**5 | 1.42765E−11 |
| x**6*y**0 | 8.80387E−16 |
| x**4*y**2 | −5.20032E−15 |
| x**2*y**4 | −3.19055E−14 |
| x**0*y**6 | −9.31977E−14 |
| x**6*v**1 | 2.576E−18 |
| x**4*y**3 | −1.07765E−16 |
| x**2*y**5 | −1.86489E−15 |
| x**0*y**7 | −1.94397E−14 |
| x**8*y**0 | −9.94101E−21 |
| x**6*y**2 | 1.28046E−18 |
| x**4*y**4 | 1.04105E−17 |
| x**2*y**6 | 1.24052E−16 |
| x**0*y**8 | 6.33598E−16 |
| x**8*y**1 | −2.31724E−22 |
| x**6*y**3 | 1.76728E−20 |
| x**4*y**5 | 3.91532E−19 |
| x**2*y**7 | −8.94255E−19 |
| x**0*y**9 | −9.43216E−19 |
| x**10*y**0 | −1.53105E−25 |
| x**8*y**2 | −1.17669E−22 |
| x**6*y**4 | −1.30492E−21 |
| x**4*y**6 | −2.09453E−20 |
| x**2*y**8 | −3.82113E−20 |
| x**0*y**10 | −2.18598E−19 |
| x**10*y**1 | 1.19817E−26 |
| x**8*y**3 | −9.07106E−25 |
| x**6*y**5 | −3.44658E−23 |
| x**4*y**7 | 2.29999E−22 |
| x**2*y**9 | 5.36689E−22 |
| x**0*y**11 | 2.88167E−21 |
| x**12*y**0 | 2.85335E−29 |
| x**10*y**2 | 5.22801E−27 |
| x**8*y**4 | 7.46157E−26 |
| x**6*y**6 | 1.27411E−24 |
| x**4*y**8 | 5.93048E−25 |
| x**2*y**10 | −1.69665E−24 |
| x**0*y**12 | −4.10382E−24 |
| x**12*y**1 | −2.17741E−31 |
| x**10*y**3 | 1.47452E−29 |
| x**8*y**5 | 9.54576E−28 |
| x**6*y**7 | −6.39973E−27 |
| x**4*y**9 | −2.09498E−26 |
| x**2*y**11 | 1.77839E−26 |
| x**0*y**13 | −5.60114E−26 |
| x**14*y**0 | −6.99826E−34 |
| x**12*y**2 | −8.82989E−32 |
| x**10*y**4 | −1.50936E−30 |
| x**8*y**6 | −2.83278E−29 |
| x**6*y**8 | −1.09124E−29 |
| x**4*y**10 | 1.18864E−28 |
| x**2*y**12 | −8.4441E−29 |
| x**0*y**14 | −2.43657E−28 |
| M5 | |
| RDX | −8337.853628 |
| RDY | 1333.008808 |
| CCX | 0 |
| CCY | 0 |
| x**2*y**1 | 1.92262E−07 |
| x**0*y**3 | 8.8025E−07 |
| x**4*y**0 | 1.45035E−10 |
| x**2*y**2 | 1.23084E−09 |
| x**0*y**4 | 8.30562E−10 |
| x**4*y**1 | 3.92552E−13 |
| x**2*y**3 | 2.11617E−12 |
| x**0*y**5 | 8.05148E−12 |
| x**6*y**0 | 1.95121E−16 |
| x**4*y**2 | 2.55894E−15 |
| x**2*y**4 | 7.21596E−15 |
| x**0*y**6 | −1.15454E−13 |
| x**6*v**1 | 8.82102E−19 |
| x**4*y**3 | 8.5796E−18 |
| x**2*y**5 | −2.66249E−17 |
| x**0*y**7 | 6.91264E−16 |
| x**8*y**0 | −1.22637E−23 |
| x**6*y**2 | 2.49645E−21 |
| x**4*y**4 | −4.2267E−20 |
| x**2*y**6 | −4.30724E−19 |
| x**0*y**8 | 1.58807E−17 |
| x**8*y**1 | −5.1449E−24 |
| x**6*y**3 | −1.35611E−22 |
| x**4*y**5 | −1.51771E−21 |
| x**2*y**7 | 8.05072E−22 |
| x**0*y**9 | −8.62052E−21 |
| x**10*y**0 | 1.21884E−26 |
| x**8*y**2 | 1.99909E−26 |
| x**6*y**4 | 2.45036E−25 |
| x**4*y**6 | 1.20443E−23 |
| x**2*y**8 | 1.49929E−22 |
| x**0*y**10 | −9.50237E−22 |
| x**10*y**1 | 1.91115E−28 |
| x**8*y**3 | 4.42148E−27 |
| x**6*y**5 | 4.59135E−26 |
| x**4*y**7 | 3.65482E−25 |
| x**2*y**9 | 2.12303E−24 |
| x**0*y**11 | 5.55484E−24 |
| x**12*y**0 | −2.2538E−31 |
| x**10*y**2 | 1.69891E−30 |
| x**8*y**4 | 4.8402E−29 |
| x**6*y**6 | 7.25058E−29 |
| x**4*y**8 | 1.74858E−29 |
| x**2*y**10 | −3.77312E−27 |
| x**0*y**12 | −2.41586E−26 |
| x**12*y**1 | −1.86278E−33 |
| x**10*y**3 | −4.98423E−32 |
| x**8*y**5 | −6.1875E−31 |
| x**6*y**7 | −4.31027E−30 |
| x**4*y**9 | −2.63578E−29 |
| x**2*y**11 | −2.61932E−28 |
| x**0*y**13 | −6.95388E−28 |
| x**14*y**0 | 1.79811E−36 |
| x**12*y**2 | −2.54687E−35 |
| x**10*y**4 | −8.58451E−34 |
| x**8*y**6 | −7.30375E−33 |
| x**6*y**8 | −1.1732E−33 |
| x**4*y**10 | −1.15539E−31 |
| x**2*y**12 | −1.14744E−30 |
| x**0*y**14 | 5.17913E−31 |
| M6 | |
| RDX | −1088.317435 |
| RDY | −726.2084467 |
| CCX | 0 |
| CCY | 0 |
| x**2*y**1 | −1.52565E−08 |
| x**0*y**3 | −3.60892E−08 |
| x**4*y**0 | −3.62509E−11 |
| x**2*y**2 | −1.07566E−10 |
| x**0*y**4 | −3.3914E−12 |
| x**4*y**1 | −3.29075E−14 |
| x**2*y**3 | −1.16794E−13 |
| x**0*y**5 | −1.17034E−13 |
| x**6*y**0 | −5.65726E−17 |
| x**4*y**2 | −2.56041E−16 |
| x**2*y**4 | −2.0543E−16 |
| x**0*y**6 | 7.00415E−16 |
| x**6*v**1 | −5.36355E−20 |
| x**4*y**3 | −2.64719E−19 |
| x**2*y**5 | −5.38087E−19 |
| x**0*y**7 | −1.93547E−18 |
| x**8*y**0 | 3.11931E−23 |
| x**6*y**2 | −3.61395E−22 |
| x**4*y**4 | −6.46453E−22 |
| x**2*y**6 | 9.43321E−22 |
| x**0*y**8 | −1.10248E−20 |
| x**8*y**1 | 4.49529E−25 |
| x**6*y**3 | 1.31386E−24 |
| x**4*y**5 | 1.29922E−24 |
| x**2*y**7 | −2.13954E−24 |
| x**0*y**9 | 1.22758E−23 |
| x**10*y**0 | −2.51351E−27 |
| x**8*y**2 | 1.02336E−27 |
| x**6*y**4 | 1.27237E−26 |
| x**4*y**6 | 1.0755E−26 |
| x**2*y**8 | −4.65577E−27 |
| x**0*y**10 | 8.65142E−26 |
| x**10*y**1 | −9.64856E−30 |
| x**8*y**3 | −2.88813E−29 |
| x**6*y**5 | −6.45791E−29 |
| x**4*y**7 | −5.39806E−29 |
| x**2*y**9 | −1.17543E−28 |
| x**0*y**11 | −4.95065E−28 |
| x**12*y**0 | 3.3272E−32 |
| x**10*y**2 | −5.21762E−32 |
| x**8*y**4 | −5.15571E−31 |
| x**6*y**6 | −7.85329E−31 |
| x**4*y**8 | −4.39364E−31 |
| x**2*y**10 | 1.93388E−33 |
| x**0*y**12 | 1.82412E−30 |
| x**12*y**1 | 6.93472E−35 |
| x**10*y**3 | 2.0965E−34 |
| x**8*y**5 | 4.18527E−34 |
| x**6*y**7 | 8.60562E−34 |
| x**4*y**9 | −9.62865E−35 |
| x**2*y**11 | 3.0589E−34 |
| x**0*y**13 | 3.13837E−33 |
| x**14*y**0 | −1.87494E−37 |
| x**12*y**2 | 3.93349E−37 |
| x**10*y**4 | 4.63844E−36 |
| x**8*y**6 | 1.16358E−35 |
| x**6*y**8 | 9.71337E−36 |
| x**4*y**10 | 5.2114E−36 |
| x**2*y**12 | 5.2576E−36 |
| x**0*y**14 | −1.36067E−35 |

Table 5 for FIG. 5/6

| x [mm] | y [mm] |
|---|---|
| 181.6092081 | −4.239169596 |
| 178.2640052 | 10.81503645 |
| 167.9378582 | 25.39781188 |
| 151.0634342 | 38.94140903 |
| 128.3506036 | 50.87692631 |
| 100.734488 | 60.67874788 |
| 69.31743255 | 67.94995378 |
| 35.31306156 | 72.42736107 |
| 1.10808E−14 | 73.94119726 |
| −35.31306156 | 72.42736107 |
| −69.31743255 | 67.94995378 |
| −100.734488 | 60.67874788 |
| −128.3506036 | 50.87692631 |
| −151.0634342 | 38.94140903 |
| −167.9378582 | 25.39781188 |
| −178.2640052 | 10.81503645 |
| −181.6092081 | −4.239169596 |
| −177.8519544 | −19.19440122 |
| −167.187156 | −33.51432465 |
| −150.1024254 | −46.73646083 |
| −127.3347517 | −58.4559769 |
| −99.81783671 | −68.29382833 |
| −68.62939314 | −75.85135763 |
| −34.94522237 | −80.67244773 |
| −3.28908E−14 | −82.33807141 |
| 34.94522237 | −80.67244773 |
| 68.62939314 | −75.85135763 |
| 99.81783671 | −68.29382833 |
| 127.3347517 | −58.4559769 |
| 150.1024254 | −46.73646083 |
| 167.187156 | −33.51432465 |
| 177.8519544 | −19.19440122 |

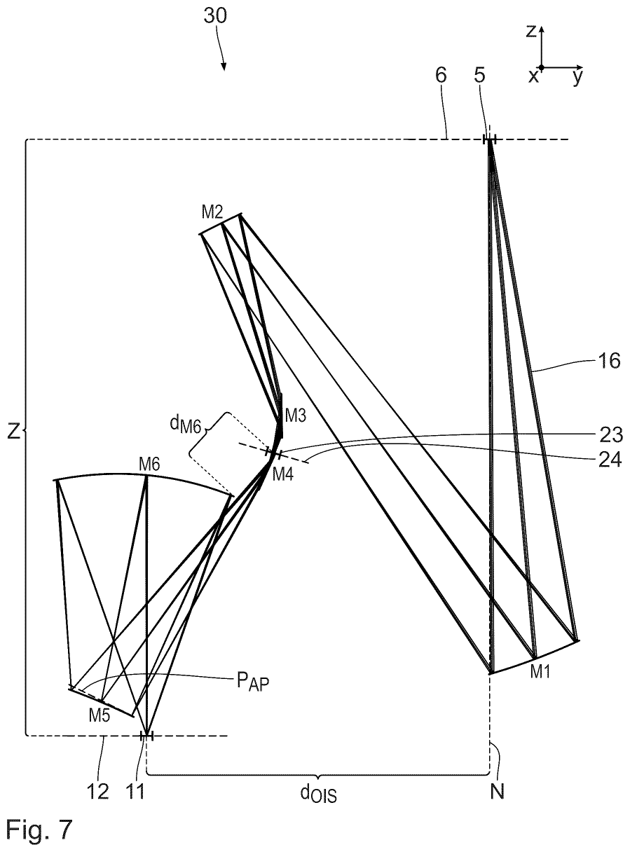

FIG. 7 shows a further embodiment of a projection optical unit or imaging optical unit 30, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

In the projection optical unit 30, the imaging light 16 is input coupled into the second mirror M2 via the first mirror M1 from the other side in relation to the y-direction when compared with the projection optical units 10 and 27 to 29. This leads to a large object-image offset d_{OIS} of approximately 950 mm in the case of the projection optical unit 30. A z-distance between the mirror M1 and the image plane 12 is only insignificantly larger than the z-distance of the penultimate mirror M6 from the image plane 12, with the result that portions of the imaging beam path between the object field 5 and the mirror M1 on the one hand and between the mirrors M1 and M2 on the other hand are greater than all other beam path portions between the further, adjacent mirrors and also greater than the beam path portion between the mirror M6 and the image field 11.

The distance d₂₃ of a further GI mirror M4 from the intermediate image 23 along the imaging beam path of the illumination light 16 is 56.22 mm in the case of the embodiment according to FIG. 7 for the projection optical unit 30; the distance d_{M6} between the intermediate image 23 and the last mirror M6 is 84.13 mm.

The projection optical unit 30 is telecentric, to a good approximation, on the object side.

The image field 11 is rectangular.

The following tables summarize parameters and the optical design of the projection optical unit 30. In terms of their structure, these tables correspond to those already explained above in conjunction with FIG. 2.

Table 1 for FIG. 7

| Wavelength | 13.5 | nm |
|---|---|---|
| Image-side numerical aperture | 0.33 | |
| Image field size in the x- and y- | 26 mm x 2.00 mm | |
| directions | | |
| βₓ | −4.00 (without intermediate | |
| | image) | |
| β_{y} | 4.00 (with intermediate image) | |
| Chief ray angle | 5.00° | |
| Étendue | 5.66 | mm² |
| Mean wavefront aberration RMS | 16.35 | mλ |
| Overall transmission | 12.78% | |
| Position of the entrance pupil (x) | −32766.32 | mm |
| Position of the entrance pupil (y) | −13988.99 | mm |
| Object-image offset in the y-direction | 948.67 | mm |
| Distance between M5 and image plane | 55 | mm |
| Distance between the object plane and | 1650.00 | mm |

| image plane | |
|---|---|
| Tilt between the object and | 0.0° |
| Image plane | |
| Installation space cuboid | (512 × 1442 × 1389) mm |

Table 2a for FIG. 7

| | M1 | M2 | M3 |
|---|---|---|---|
| Maximum angle of incidence [°] | 16.7 | 13.1 | 79.1 |
| Minimum angle of incidence [°] | 14.1 | 5.4 | 68.1 |
| Extent of the reflection surface | 347.3 | 427.6 | 418.4 |
| in the x-direction [mm] | | | |
| Extent of the reflection surface | 256.7 | 122.6 | 100.6 |
| in the y-direction [mm] | | | |
| Maximum mirror diameter [mm] | 347.8 | 427.7 | 419.3 |

Table 2b for FIG. 7

| | M4 | M5 | M6 |
|---|---|---|---|
| Maximum angle of incidence [°] | 86.4 | 22.7 | 10.8 |
| Minimum angle of incidence [°] | 73.9 | 2.2 | 2.4 |
| Extent of the reflection surface | 419.4 | 443.3 | 512.4 |
| in the x-direction [mm] | | | |
| Extent of the reflection surface | 98.8 | 181.1 | 486.4 |
| in the y-direction [mm] | | | |
| Maximum mirror diameter [mm] | 421.0 | 443.4 | 512.9 |

Table 3a for FIG. 7

| | x-distance [mm] | y-distance [mm] | z-distance [mm] |
|---|---|---|---|
| Object field | 0 | −948.6701073 | 1650.001756 |
| M1 | 0 | −1073.914761 | 212.8291522 |
| M2 | 0 | −207.1287432 | 1418.494031 |
| M3 | 0 | −374.0735488 | 877.0355224 |
| M4 | 0 | −338.6709296 | 743.9862335 |
| M5 | 0 | 125.9099326 | 94.15017845 |
| M6 | 0 | 0 | 721.740044 |
| Stop (AS) | 0 | 124.9352724 | 95.51349195 |
| Image field | 0 | 0 | 0 |

Table 3b for FIG. 7

| | Tilt about the x- | Tilt about the y- | Tilt about the z- |
|---|---|---|---|
| | axis [degrees] | axis [degrees] | axis [degrees] |
| Object field | 0.019452572 | 0 | 0 |
| M1 | −20.34697799 | 180 | 0 |
| M2 | −26.42460473 | 0 | 0 |
| M3 | 88.88228871 | 0 | 180 |
| M4 | 115.2310586 | 0 | 0 |
| M5 | 23.45303741 | 180 | 0 |
| M6 | 5.672167978 | 0 | 0 |
| Stop (AS) | 26.11186315 | 0 | 0 |
| Image field | 0 | 0 | 0 |

Table 4 for FIG. 7

| x**i * y**j | Coefficient |
|---|---|
| M1 | |
| RDX | −5869.291349 |
| RDY | −1980.997451 |
| CCX | 0 |
| CCY | 0 |
| x**2*y**1 | −4.0727E−09 |
| x**0*y**3 | 4.07328E−08 |
| x**4*y**0 | 1.08228E−12 |
| x**2*y**2 | −1.42159E−11 |
| x**0*y**4 | 6.8145E−11 |
| x**4*y**1 | 7.1871E−16 |
| x**2*y**3 | −6.8322E−15 |
| x**0*y**5 | 1.56481E−13 |
| x**6*y**0 | 3.82981E−18 |
| x**4*y**2 | 2.30501E−18 |
| x**2*y**4 | 5.41562E−18 |
| x**0*y**6 | 4.28135E−16 |
| x**6*y**1 | −3.28278E−20 |
| x**4*y**3 | −8.45044E−20 |
| x**2*y**5 | −1.30107E−20 |
| x**0*y**7 | 3.20707E−18 |
| x**8*y**0 | −1.26493E−22 |
| x**6*y**2 | −5.53758E−22 |
| x**4*y**4 | −8.94054E−22 |
| x**2*y**6 | −1.20206E−21 |
| x**0*y**8 | 1.88511E−21 |
| x**8*y**1 | 1.09121E−24 |
| x**6*y**3 | 3.61701E−24 |
| x**4*y**5 | 3.14767E−24 |
| x**2*y**7 | −2.86279E−24 |
| x**0*y**9 | −1.48561E−23 |
| x**10*y**0 | 3.42818E−27 |
| x**8*y**2 | 2.07519E−26 |
| x**6*y**4 | 5.05267E−26 |
| x**4*y**6 | 5.89735E−26 |
| x**2*y**8 | 6.38914E−26 |
| x**0*y**10 | 7.41541E−26 |
| x**10*y**1 | −1.34889E−29 |
| x**8*y**3 | −7.16775E−29 |
| x**6*y**5 | −1.45225E−28 |
| x**4*y**7 | 3.3767E−30 |
| x**2*y**9 | −3.14572E−29 |
| x**0*y**11 | −7.69402E−29 |
| x**12*y**0 | −3.66873E−32 |
| x**10*y**2 | −2.84921E−31 |
| x**8*y**4 | −9.43207E−31 |
| x**6*y**6 | −1.37453E−30 |
| x**4*y**8 | −1.45957E−30 |
| x**2*y**10 | −2.39803E−30 |
| x**0*y**12 | 7.75744E−31 |
| M2 | |
| RDX | −12488.01188 |
| RDY | −2707.109701 |
| CCX | 0 |
| CCY | 0 |
| x**2*y**1 | 2.0632E−08 |
| x**0*y**3 | −1.63233E−07 |
| x**4*y**0 | −1.87961E−11 |
| x**2*y**2 | −1.73914E−11 |
| x**0*y**4 | −1.52892E−10 |
| x**4*y**1 | 1.75889E−14 |
| x**2*y**3 | −3.61383E−14 |
| x**0*y**5 | 1.70934E−12 |
| x**6*y**0 | −9.0532E−18 |
| x**4*y**2 | −2.18226E−17 |
| x**2*y**4 | 6.58219E−16 |
| x**0*y**6 | 7.52031E−15 |
| x**6*y**1 | 8.05451E−20 |
| x**4*y**3 | 8.41062E−19 |
| x**2*y**5 | 1.1794E−17 |
| x**0*y**7 | −2.84303E−16 |
| x**8*y**0 | 2.88806E−23 |
| x**6*y**2 | 1.11469E−21 |
| x**4*y**4 | 1.98156E−20 |
| x**2*y**6 | 8.36996E−20 |
| x**0*y**8 | 4.28657E−18 |
| x**8*y**1 | −1.38375E−24 |
| x**6*y**3 | −1.92237E−23 |
| x**4*y**5 | −1.7401E−22 |
| x**2*y**7 | 1.02421E−21 |
| x**0*y**9 | 3.60207E−21 |
| x**10*y**0 | −3.68248E−28 |
| x**8*y**2 | −2.22137E−26 |
| x**6*y**4 | −6.31396E−25 |
| x**4*y**6 | −6.04593E−24 |
| x**2*y**8 | −1.01558E−23 |
| x**0*y**10 | −5.56917E−22 |
| x**10*y**1 | 9.2786E−30 |
| x**8*y**3 | 2.38728E−28 |
| x**6*y**5 | 4.49816E−27 |
| x**4*y**7 | 2.06386E−26 |
| x**2*y**9 | −1.47664E−25 |
| x**0*y**11 | 2.33369E−24 |
| x**12*y**0 | 2.32091E−33 |
| x**10*y**2 | 1.99322E−31 |
| x**8*y**4 | 7.51259E−30 |
| x**6*y**6 | 8.58609E−29 |
| x**4*y**8 | 7.5488E−28 |
| x**2*y**10 | 3.08112E−27 |
| x**0*y**12 | 8.51384E−28 |
| M3 | |
| RDX | 11604.40604 |
| RDY | −4026.744397 |
| CCX | 0 |
| CCY | 0 |
| x**2*y**1 | −3.81209E−08 |
| x**0*y**3 | −5.04423E−07 |
| x**4*y**0 | 1.19864E−10 |
| x**2*y**2 | −1.28713E−10 |
| x**0*y**4 | −2.60524E−09 |
| x**4*y**1 | 2.26003E−14 |
| x**2*y**3 | −9.344E−13 |
| x**0*y**5 | −1.39387E−11 |
| x**6*y**0 | 8.5224E−17 |
| x**4*y**2 | 4.59342E−16 |
| x**2*y**4 | −1.03E−14 |
| x**0*y**6 | −4.89462E−14 |
| x**6*y**1 | −1.65928E−19 |
| x**4*y**3 | −2.19021E−20 |
| x**2*y**5 | −1.72271E−16 |
| x**0*y**7 | 3.04594E−16 |
| x**8*y**0 | 1.50011E−22 |
| x**6*y**2 | 4.15547E−21 |
| x**4*y**4 | 3.23131E−20 |
| x**2*y**6 | −2.69569E−18 |
| x**0*y**8 | 3.95458E−18 |
| x**8*y**1 | 5.07674E−24 |
| x**6*y**3 | 1.25181E−22 |
| x**4*y**5 | 2.79251E−21 |
| x**2*y**7 | −2.6458E−20 |
| x**0*y**9 | 1.38761E−20 |
| x**10*y**0 | −1.98558E−28 |
| x**8*y**2 | −9.44888E−26 |
| x**6*y**4 | −6.88562E−25 |
| x**4*y**6 | 2.80052E−23 |
| x**2*y**8 | −2.60753E−22 |
| x**0*y**10 | 2.53046E−22 |
| x**10*y**1 | −2.35243E−29 |
| x**8*y**3 | −1.19598E−27 |
| x**6*y**5 | −3.65394E−26 |
| x**4*y**7 | 2.09218E−27 |
| x**2*y**9 | −2.0476E−24 |
| x**0*y**11 | 1.15703E−24 |
| x**12*y**0 | −8.31292E−33 |
| x**10*y**2 | 8.17974E−31 |
| x**8*y**4 | 1.56972E−29 |
| x**6*y**6 | 3.70433E−29 |
| x**4*y**8 | 8.69814E−28 |
| x**2*y**10 | 1.26084E−27 |
| x**0*y**12 | −1.95442E−27 |
| M4 | |
| RDX | 8624.079895 |
| RDY | 328696.9692 |
| CCX | 0 |
| CCY | 0 |
| x**2*y**1 | −9.45403E−10 |
| x**0*y**3 | 5.25145E−09 |
| x**4*y**0 | 1.53698E−10 |
| x**2*y**2 | 1.94399E−10 |
| x**0*y**4 | 1.03328E−09 |
| x**4*y**1 | 1.29208E−13 |
| x**2*y**3 | 9.53963E−13 |
| x**0*y**5 | 1.1819E−11 |
| x**6*y**0 | 1.35501E−16 |
| x**4*y**2 | 4.1143E−16 |
| x**2*y**4 | 5.33831E−15 |
| x**0*y**6 | 1.1021E−13 |
| x**6*y**1 | 2.60211E−19 |
| x**4*y**3 | −2.07846E−18 |
| x**2*y**5 | 1.66453E−17 |
| x**0*y**7 | 1.61355E−15 |
| x**8*y**0 | −7.48923E−23 |
| x**6*y**2 | 2.55621E−21 |
| x**4*y**4 | 2.11436E−20 |
| x**2*y**6 | 5.06427E−19 |
| x**0*y**8 | 2.60769E−17 |
| x**8*y**1 | −1.89796E−24 |
| x**6*y**3 | 9.18806E−23 |
| x**4*y**5 | 3.50268E−21 |
| x**2*y**7 | 2.02653E−20 |
| x**0*y**9 | 2.0966E−19 |
| x**10*y**0 | 1.57516E−30 |
| x**8*y**2 | −2.13588E−26 |
| x**6*y**4 | 8.28382E−25 |
| x**4*y**6 | 3.56784E−23 |
| x**2*y**8 | 8.16488E−23 |
| x**0*y**10 | 2.52561E−22 |
| x**10*y**1 | −7.05381E−31 |
| x**8*y**3 | −6.87654E−28 |
| x**6*y**5 | −4.86059E−26 |
| x**4*y**7 | −1.07244E−24 |
| x**2*y**9 | −1.73243E−24 |
| x**0*y**11 | 4.16929E−25 |
| x**12*y**0 | 1.73699E−32 |
| x**10*y**2 | 5.38256E−32 |
| x**8*y**4 | −1.41118E−29 |
| x**6*y**6 | −8.67116E−28 |
| x**4*y**8 | −1.43456E−26 |
| x**2*y**10 | 4.32856E−27 |
| x**0*y**12 | −8.44511E−28 |
| M5 | |
| RDX | −127231.0882 |
| RDY | 1265.852117 |
| CCX | 0 |
| CCY | 0 |
| x**2*y**1 | 1.05685E−07 |
| x**0*y**3 | 6.05895E−07 |
| x**4*y**0 | 6.60279E−11 |
| x**2*y**2 | 7.51564E−10 |
| x**0*y**4 | −1.00523E−10 |
| x**4*y**1 | 1.35603E−13 |
| x**2*y**3 | 4.76143E−13 |
| x**0*y**5 | 3.02089E−12 |
| x**6*y**0 | 6.74165E−17 |
| x**4*y**2 | 9.40773E−16 |
| x**2*y**4 | 2.91991E−15 |
| x**0*y**6 | −1.00254E−14 |
| x**6*y**1 | 1.81982E−19 |
| x**4*y**3 | 1.79299E−18 |
| x**2*y**5 | 1.14037E−18 |
| x**0*y**7 | 1.68018E−16 |
| x**8*y**0 | 7.35873E−23 |
| x**6*y**2 | 1.18324E−21 |
| x**4*y**4 | 3.23403E−21 |
| x**2*y**6 | 9.11542E−20 |
| x**0*y**8 | 4.98512E−19 |
| x**8*y**1 | 5.90315E−25 |
| x**6*y**3 | 7.94614E−25 |
| x**4*y**5 | 2.94096E−23 |
| x**2*y**7 | 5.94703E−22 |
| x**0*y**9 | −3.11833E−21 |
| x**10*y**0 | 1.95975E−28 |
| x**8*y**2 | 6.28546E−27 |
| x**6*y**4 | 6.40577E−26 |
| x**4*y**6 | 5.96686E−25 |
| x**2*y**8 | −2.79224E−24 |
| x**0*y**10 | −3.00691E−23 |
| x**10*y**1 | −2.58379E−31 |
| x**8*y**3 | 3.24873E−29 |
| x**6*y**5 | 3.89869E−28 |
| x**4*y**7 | −1.03284E−27 |
| x**2*y**9 | −1.93286E−26 |
| x**0*y**11 | −8.45285E−26 |
| x**12*y**0 | −6.3418E−34 |
| x**10*y**2 | −1.517E−32 |
| x**8*y**4 | −1.81374E−31 |
| x**6*y**6 | −2.62802E−30 |
| x**4*y**8 | −2.54943E−29 |
| x**2*y**10 | −1.14744E−28 |
| x**0*y**12 | 3.62708E−28 |
| M6 | |
| RDX | −1323.209682 |
| RDY | −841.8635731 |
| CCX | 0 |
| CCY | 0 |
| x**2*y**1 | −2.20913E−10 |
| x**0*y**3 | −2.29136E−08 |
| x**4*y**0 | −2.45626E−11 |
| x**2*y**2 | −7.6933E−11 |
| x**0*y**4 | −3.03426E−12 |
| x**4*y**1 | −4.67885E−15 |
| x**2*y**3 | −3.46684E−14 |
| x**0*y**5 | −5.9174E−14 |
| x**6*y**0 | −2.34059E−17 |
| x**4*y**2 | −1.18456E−16 |
| x**2*y**4 | −1.26641E−16 |
| x**0*y**6 | 2.58798E−17 |
| x**6*y**1 | −5.17423E−21 |
| x**4*y**3 | −5.2679E−20 |
| x**2*y**5 | −1.2283E−19 |
| x**0*y**7 | −2.64613E−19 |
| x**8*y**0 | −1.79554E−23 |
| x**6*y**2 | −1.14616E−22 |
| x**4*y**4 | −2.45117E−22 |
| x**2*y**6 | −1.60316E−22 |
| x**0*y**8 | 8.74906E−23 |
| x**8*y**1 | −2.44976E−26 |
| x**6*y**3 | −2.69321E−27 |
| x**4*y**5 | −1.58223E−25 |
| x**2*y**7 | −4.36191E−25 |
| x**0*y**9 | −2.80955E−25 |
| x**10*y**0 | −3.65338E−29 |
| x**8*y**2 | −3.3233E−28 |
| x**6*y**4 | −8.30234E−28 |
| x**4*y**6 | −8.23883E−28 |
| x**2*y**8 | 2.52772E−28 |
| x**0*y**10 | 1.58609E−27 |
| x**10*y**1 | 3.09692E−32 |
| x**8*y**3 | −4.58508E−31 |
| x**6*y**5 | −1.08066E−30 |
| x**4*y**7 | −1.31686E−30 |
| x**2*y**9 | −3.41623E−30 |
| x**0*y**11 | −2.20137E−30 |
| x**12*y**0 | 9.99169E−35 |
| x**10*y**2 | 7.59157E−34 |
| x**8*y**4 | 2.072E−33 |
| x**6*y**6 | 2.4682E−33 |
| x**4*y**8 | 1.62399E−33 |
| x**2*y**10 | 5.4698E−33 |
| x**0*y**12 | 4.50729E−33 |

Table 5 for FIG. 7

| x [mm] | y [mm] |
|---|---|
| 221.7816361 | −4.656190259 |
| 217.9494554 | 12.60201271 |
| 205.5568455 | 29.38650081 |
| 185.0961455 | 45.03007758 |
| 157.4103752 | 58.87371929 |
| 123.6341554 | 70.3149947 |
| 85.12219791 | 78.85539956 |
| 43.3792251 | 84.12866523 |
| 1.36134E−14 | 85.91149628 |
| −43.3792251 | 84.12866523 |
| −85.12219791 | 78.85539956 |
| −123.6341554 | 70.3149947 |
| −157.4103752 | 58.87371929 |
| −185.0961455 | 45.03007758 |
| −205.5568455 | 29.38650081 |
| −217.9494554 | 12.60201271 |
| −221.7816361 | −4.656190259 |
| −216.9448666 | −21.74673698 |
| −203.7137989 | −38.07412784 |
| −182.7130372 | −53.09733903 |
| −154.8612217 | −66.32353629 |
| −121.3053917 | −77.28960655 |
| −83.35591972 | −85.55112044 |
| −42.42885771 | −90.70607314 |
| −3.99297E−14 | −92.46079697 |
| 42.42885771 | −90.70607314 |
| 83.35591972 | −85.55112044 |
| 121.3053917 | −77.28960655 |
| 154.8612217 | −66.32353629 |
| 182.7130372 | −53.09733903 |
| 203.7137989 | −38.07412784 |
| 216.9448666 | −21.74673698 |

The projection optical unit 30 has a comparatively large reflection surface extent of the mirror M1, both in the x-direction and in the y-direction; the two extension directions are greater than 200 mm and for example also greater than 250 mm. This reduces a thermal load on the mirror M1 on account of a residual absorption of the imaging light 16.

In comparison with the projection optical units, explained above, with different folding at the mirror M2, the projection optical unit 30 has comparatively small angles of incidence at this mirror M2, which are less than 15°.

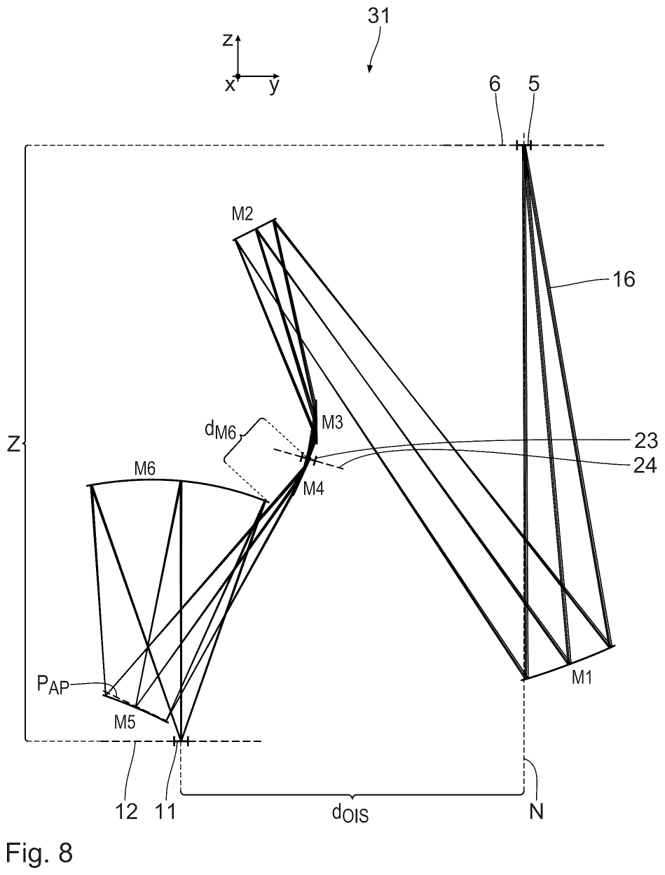

FIG. 8 shows a further embodiment of a projection optical unit or imaging optical unit 31, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

In principle, in terms of the arrangement of the mirrors, the projection optical unit 31 corresponds to the projection optical unit 30 according to FIG. 7.

In contrast with the projection optical unit 30, the projection optical unit 31 has an entrance pupil which is arranged upstream of the object field 5 in the imaging light beam path, at a distance of approximately 1750 mm. The second facet mirror 21 then embodied as the pupil facet mirror can be arranged there.

The distance d₂₃ of a further GI mirror M4 from the intermediate image 23 along the imaging beam path of the illumination light 16 is 87.99 mm in the case of the embodiment according to FIG. 8 for the projection optical unit 31; the distance d_{M6} between the intermediate image 23 and the last mirror M6 is 115.53 mm.

The image field 11 is rectangular.

The following tables summarize parameters and the optical design of the projection optical unit 31. In terms of their structure, these tables correspond to those already explained above in conjunction with FIG. 2.

Table 1 for FIG. 8

| Wavelength | 13.5 | nm |
|---|---|---|
| Image-side numerical aperture | 0.33 | |
| Image field size in the x- and y- | 26 mm x 2.00 mm | |
| directions | | |
| βₓ | −4.00 (without intermediate | |
| | image) | |
| β_{y} | 4.00 (with intermediate image) | |
| Chief ray angle | 5.60° | |
| Étendue | 5.66 | mm² |
| Mean wavefront aberration RMS | 24.21 | mλ |
| Overall transmission | 13.09% | |
| Position of the entrance pupil (x) | −1722.59 | mm |
| Position of the entrance pupil (y) | −1771.27 | mm |
| Object-image offset in the y-direction | 948.64 | mm |
| Distance between M5 and image plane | 56 | mm |
| Distance between the object plane and | 1971.66 | mm |

| image plane | |
|---|---|
| Tilt between the object and | −0.1° |
| Image plane | |
| Installation space cuboid | (524 × 1586 × 1716) mm |

Table 2a for FIG. 8

| | M1 | M2 | M3 |
|---|---|---|---|
| Maximum angle of incidence [°] | 10.5 | 11.6 | 77.7 |
| Minimum angle of incidence [°] | 8.3 | 4.2 | 67.8 |
| Extent of the reflection surface | 506.7 | 323.5 | 356.2 |
| in the x-direction [mm] | | | |
| Extent of the reflection surface | 316.4 | 137.6 | 121.6 |
| in the y-direction [mm] | | | |
| Maximum mirror diameter [mm] | 507.6 | 323.7 | 356.7 |

Table 2b for FIG. 8

| | M4 | M5 | M6 |
|---|---|---|---|
| Maximum angle of incidence [°] | 87.3 | 22.3 | 13.4 |
| Minimum angle of incidence [°] | 75.1 | 3.4 | 5.4 |
| Extent of the reflection surface | 371.3 | 458.3 | 523.6 |
| in the x-direction [mm] | | | |
| Extent of the reflection surface | 174.2 | 218.6 | 503.1 |
| in the y-direction [mm] | | | |
| Maximum mirror diameter [mm] | 372.5 | 458.5 | 524.5 |

Table 3a for FIG. 8

| | x-distance [mm] | y-distance [mm] | z-distance [mm] |
|---|---|---|---|
| Object field | 0 | −948.6386101 | 1971.656615 |
| M1 | 0 | −1126.386337 | 192.5976392 |
| M2 | 0 | −418.2490979 | 1752.422869 |
| M3 | 0 | −536.718386 | 995.6865935 |
| M4 | 0 | −449.645877 | 811.8096786 |
| M5 | 0 | 211.3286617 | 113.3304951 |
| M6 | 0 | 0 | 738.8770173 |
| Stop (AS) | 0 | 210.1767638 | 114.5477533 |
| Image field | 0 | 0 | 0 |

Table 3b for FIG. 8

| | Tilt about the x- | Tilt about the y- | Tilt about the z- |
|---|---|---|---|
| | axis [degrees] | axis [degrees] | axis [degrees] |
| Object field | −0.105549538 | 0 | 0 |
| M1 | −15.06144252 | 180 | 0 |
| M2 | −16.65746868 | 0 | 0 |
| M3 | −81.77915932 | 180 | 0 |
| M4 | 124.3795033 | 0 | 0 |
| M5 | 31.0431288 | 180 | 0 |
| M6 | 9.333267115 | 0 | 0 |
| Stop (AS) | 31.42819216 | 0 | 0 |
| Image field | 0 | 0 | 0 |

Table 4 for FIG. 8

| x**i * y**j | Coefficient |
|---|---|
| M1 | |
| RDX | −3009.587091 |
| RDY | −2304.277374 |
| CCX | 0 |
| CCY | 0 |
| x**2*y**1 | −1.56144E−10 |
| x**0*y**3 | 1.55335E−08 |
| x**4*y**0 | −3.10253E−13 |
| x**2*y**2 | −3.60485E−12 |
| x**0*y**4 | 1.64453E−11 |
| x**4*y**1 | −2.32955E−16 |
| x**2*y**3 | 1.55198E−15 |
| x**0*y**5 | 2.69809E−14 |
| x**6*y**0 | −2.53715E−20 |
| x**4*y**2 | −9.66833E−19 |
| x**2*y**4 | 1.19957E−18 |
| x**0*y**6 | 1.60422E−17 |
| x**6*y**1 | 1.12676E−21 |
| x**4*y**3 | 3.70412E−21 |
| x**2*y**5 | −6.65163E−21 |
| x**0*y**7 | 3.99124E−19 |
| x**8*y**0 | 3.68638E−24 |
| x**6*y**2 | 3.75861E−23 |
| x**4*y**4 | 1.07703E−22 |
| x**2*y**6 | 3.94164E−23 |
| x**0*y**8 | 9.29275E−22 |
| x**8*y**1 | −9.87178E−27 |
| x**6*y**3 | −6.17225E−26 |
| x**4*y**5 | −9.0138E−26 |
| x**2*y**7 | −9.81621E−26 |
| x**0*y**9 | −8.90447E−24 |
| x**10*y**0 | −2.51046E−29 |
| x**8*y**2 | −3.71935E−28 |
| x**6*y**4 | −1.21585E−27 |
| x**4*y**6 | −2.52457E−27 |
| x**2*y**8 | −2.43907E−27 |
| x**0*y**10 | −2.24431E−26 |
| M2 | |
| RDX | 4242.475652 |
| RDY | −5806.146324 |
| CCX | 0 |
| CCY | 0 |
| x**2*y**1 | −1.49124E−08 |
| x**0*y**3 | −4.17653E−08 |
| x**4*y**0 | −5.07154E−11 |
| x**2*y**2 | −6.11632E−11 |
| x**0*y**4 | 1.12437E−10 |
| x**4*y**1 | 5.45982E−14 |
| x**2*y**3 | 1.74854E−13 |
| x**0*y**5 | 6.89357E−13 |
| x**6*y**0 | −4.76124E−18 |
| x**4*y**2 | −1.29221E−16 |
| x**2*y**4 | 7.2141E−16 |
| x**0*y**6 | −3.99956E−15 |
| x**6*y**1 | −1.01137E−19 |
| x**4*y**3 | −1.83677E−19 |
| x**2*y**5 | 8.71903E−18 |
| x**0*y**7 | −1.1324E−17 |
| x**8*y**0 | −6.15056E−23 |
| x**6*y**2 | −3.19552E−21 |
| x**4*y**4 | −2.01383E−20 |
| x**2*y**6 | 9.53497E−20 |
| x**0*y**8 | −4.66492E−20 |
| x**8*y**1 | 1.10365E−24 |
| x**6*y**3 | 1.38143E−23 |
| x**4*y**5 | 8.57397E−23 |
| x**2*y**7 | −5.24898E−22 |
| x**0*y**9 | 1.54804E−20 |
| x**10*y**0 | 1.31061E−27 |
| x**8*y**2 | 8.3825E−26 |
| x**6*y**4 | 6.23074E−25 |
| x**4*y**6 | 2.56694E−24 |
| x**2*y**8 | 1.89321E−24 |
| x**0*y**10 | −7.17941E−23 |
| M3 | |
| RDX | 8997.286396 |
| RDY | −3102.040351 |
| CCX | 0 |
| CCY | 0 |
| x**2*y**1 | −2.65201E−08 |
| x**0*y**3 | −3.59608E−07 |
| x**4*y**0 | 1.81744E−10 |
| x**2*y**2 | −1.74989E−10 |
| x**0*y**4 | −1.04322E−09 |
| x**4*y**1 | −1.13497E−14 |
| x**2*y**3 | −8.29555E−13 |
| x**0*y**5 | −3.1905E−12 |
| x**6*y**0 | 1.36525E−16 |
| x**4*y**2 | 5.58729E−16 |
| x**2*y**4 | −3.73773E−15 |
| x**0*y**6 | −1.32063E−14 |
| x**6*y**1 | 3.86976E−19 |
| x**4*y**3 | −2.41894E−20 |
| x**2*y**5 | −5.74113E−17 |
| x**0*y**7 | −3.45314E−16 |
| x**8*y**0 | −1.27664E−23 |
| x**6*y**2 | 2.69426E−21 |
| x**4*y**4 | −8.26815E−21 |
| x**2*y**6 | −5.50564E−19 |
| x**0*y**8 | −3.8146E−18 |
| x**8*y**1 | 1.23974E−24 |
| x**6*y**3 | 2.56636E−23 |
| x**4*y**5 | 9.71993E−22 |
| x**2*y**7 | 1.1164E−20 |
| x**0*y**9 | 9.67983E−21 |
| x**10*y**0 | 8.38656E−28 |
| x**8*y**2 | −2.03407E−26 |
| x**6*y**4 | 8.61212E−25 |
| x**4*y**6 | 1.42975E−23 |
| x**2*y**8 | 1.73504E−22 |
| x**0*y**10 | 2.53119E−22 |
| M4 | |
| RDX | 5776.463209 |
| RDY | 60577.95264 |
| CCX | 0 |
| CCY | 0 |
| x**2*y**1 | 1.92962E−08 |
| x**0*y**3 | 5.89736E−08 |
| x**4*y**0 | 2.49081E−10 |
| x**2*y**2 | 1.98082E−10 |
| x**0*y**4 | 5.6939E−10 |
| x**4*y**1 | 3.73505E−13 |
| x**2*y**3 | 1.03822E−12 |
| x**0*y**5 | 4.19785E−12 |
| x**6*y**0 | 2.34591E−16 |
| x**4*y**2 | 7.6159E−16 |
| x**2*y**4 | 4.45524E−15 |
| x**0*y**6 | 2.89795E−14 |
| x**6*y**1 | 3.68352E−19 |
| x**4*y**3 | 1.0579E−18 |
| x**2*y**5 | 2.23374E−17 |
| x**0*y**7 | 2.70219E−16 |
| x**8*y**0 | 4.63368E−22 |
| x**6*y**2 | 7.37199E−21 |
| x**4*y**4 | 4.43446E−20 |
| x**2*y**6 | 3.71524E−19 |
| x**0*y**8 | 2.64411E−18 |
| x**8*y**1 | 1.75787E−24 |
| x**6*y**3 | 4.72502E−23 |
| x**4*y**5 | 5.00428E−22 |
| x**2*y**7 | 4.65915E−21 |
| x**0*y**9 | 1.56205E−20 |
| x**10*y**0 | −5.90657E−28 |
| x**8*y**2 | −7.51476E−26 |
| x**6*y**4 | −2.66355E−25 |
| x**4*y**6 | 3.01901E−24 |
| x**2*y**8 | 1.97628E−23 |
| x**0*y**10 | 3.73158E−23 |
| M5 | |
| RDX | −11754.77521 |
| RDY | 1889.532872 |
| CCX | 0 |
| CCY | 0 |
| x**2*y**1 | 9.28952E−08 |
| x**0*y**3 | 2.90242E−07 |
| x**4*y**0 | 6.32701E−11 |
| x**2*y**2 | 6.01071E−10 |
| x**0*y**4 | 6.84391E−11 |
| x**4*y**1 | 1.28222E−13 |
| x**2*y**3 | 2.56366E−13 |
| x**0*y**5 | 1.20633E−12 |
| x**6*y**0 | 6.24996E−17 |
| x**4*y**2 | 6.29035E−16 |
| x**2*y**4 | 1.71951E−15 |
| x**0*y**6 | −2.97226E−15 |
| x**6*y**1 | 1.72444E−19 |
| x**4*y**3 | 9.39246E−19 |
| x**2*y**5 | 1.40767E−18 |
| x**0*y**7 | 3.06537E−17 |
| x**8*y**0 | 6.17968E−23 |
| x**6*y**2 | 9.07915E−22 |
| x**4*y**4 | 4.22275E−21 |
| x**2*y**6 | 6.59953E−21 |
| x**0*y**8 | −1.01418E−19 |
| x**8*y**1 | 2.95634E−25 |
| x**6*y**3 | 2.66916E−24 |
| x**4*y**5 | 6.21951E−24 |
| x**2*y**7 | −3.57871E−24 |
| x**0*y**9 | −6.9072E−22 |
| x**10*y**0 | 8.23139E−29 |
| x**8*y**2 | 1.97598E−27 |
| x**6*y**4 | 1.86434E−27 |
| x**4*y**6 | −7.19586E−26 |
| x**2*y**8 | −7.51097E−25 |
| x**0*y**10 | 1.22891E−24 |
| M6 | |
| RDX | −1356.144811 |
| RDY | −911.1879105 |
| CCX | 0 |
| CCY | 0 |
| x**2*y**1 | 1.22958E−08 |
| x**0*y**3 | −4.94229E−09 |
| x**4*y**0 | −2.15189E−11 |
| x**2*y**2 | −8.06208E−11 |
| x**0*y**4 | −1.12631E−11 |
| x**4*y**1 | −4.18807E−17 |
| x**2*y**3 | −1.4622E−14 |
| x**0*y**5 | −3.26739E−14 |
| x**6*y**0 | −2.13472E−17 |
| x**4*y**2 | −1.04471E−16 |
| x**2*y**4 | −1.24622E−16 |
| x**0*y**6 | 4.79709E−18 |
| x**6*y**1 | −4.87969E−21 |
| x**4*y**3 | −2.7387E−20 |
| x**2*y**5 | −7.35276E−20 |
| x**0*y**7 | −1.36622E−19 |
| x**8*y**0 | −1.60453E−23 |
| x**6*y**2 | −1.10141E−22 |
| x**4*y**4 | −2.36879E−22 |
| x**2*y**6 | −1.01479E−22 |
| x**0*y**8 | 1.57626E−22 |
| x**8*y**1 | −6.67234E−27 |
| x**6*y**3 | −6.5999E−26 |
| x**4*y**5 | −2.21953E−25 |
| x**2*y**7 | −3.87374E−25 |
| x**0*y**9 | −3.95882E−26 |
| x**10*y**0 | −1.41096E−29 |
| x**8*y**2 | −1.33808E−28 |
| x**6*y**4 | −2.43179E−28 |
| x**4*y**6 | −1.90271E−28 |
| x**2*y**8 | 1.06517E−28 |
| x**0*y**10 | 4.29776E−28 |

Table 5 for FIG. 8

| x [mm] | y [mm] |
|---|---|
| 229.2789443 | −6.303958797 |
| 226.0777622 | 14.9471604 |
| 213.8889193 | 36.01200023 |
| 193.128275 | 55.99410495 |
| 164.6172732 | 73.96688625 |
| 129.5256599 | 89.04279033 |
| 89.29165682 | 100.4414503 |
| 45.53837879 | 107.5476122 |
| 1.42946E−14 | 109.962631 |
| −45.53837879 | 107.5476122 |
| −89.29165682 | 100.4414503 |
| −129.5256599 | 89.04279033 |
| −164.6172732 | 73.96688625 |
| −193.128275 | 55.99410495 |
| −213.8889193 | 36.01200023 |
| −226.0777622 | 14.9471604 |
| −229.2789443 | −6.303958797 |
| −223.5015615 | −26.92873358 |
| −209.1564879 | −46.22825022 |
| −186.9983666 | −63.62199848 |
| −158.0486663 | −78.62888737 |
| −123.5166048 | −90.83603498 |
| −84.73009225 | −99.87825148 |
| −43.08296736 | −105.4473377 |
| −4.05309E−14 | −107.3294827 |
| 43.08296736 | −105.4473377 |
| 84.73009225 | −99.87825148 |
| 123.5166048 | −90.83603498 |
| 158.0486663 | −78.62888737 |
| 186.9983666 | −63.62199848 |
| 209.1564879 | −46.22825022 |
| 223.5015615 | −26.92873358 |

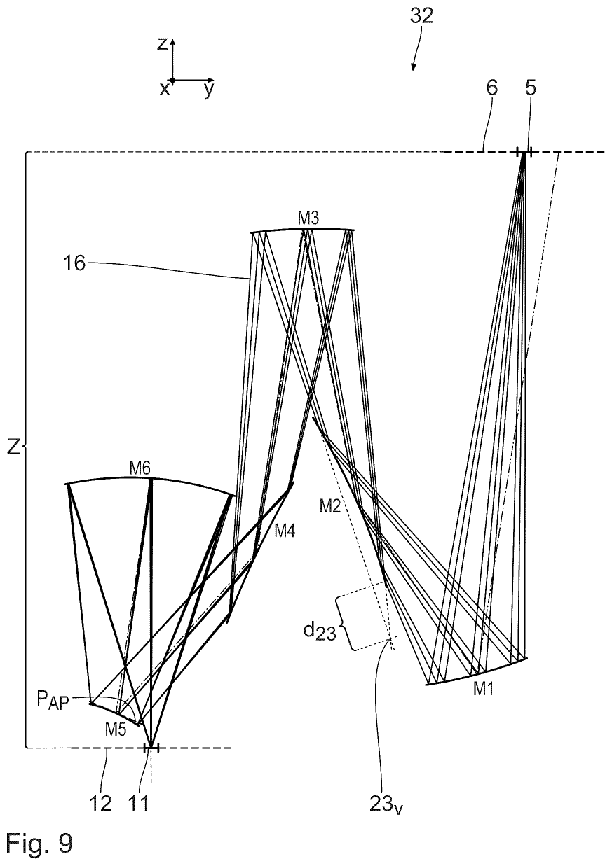

FIG. 9 shows a further embodiment of a projection optical unit or imaging optical unit 32, which can be used in the projection exposure apparatus 1 instead of the projection optical unit 10 of the embodiment according to FIG. 2. Components and functions corresponding to those which have already been explained above in conjunction with FIGS. 1 to 3, and for example in conjunction with FIGS. 2 and 3, are denoted by the same reference signs and are not discussed in detail again.

In the projection optical unit 32, the mirrors M1, M3, M5 and M6 are embodied as NI mirrors and the mirrors M2 and M4 are embodied as GI mirrors.

In the imaging beam path of the projection optical unit 32, the reflection at the two GI mirrors M2 and M4 is respectively assigned a virtual intermediate image 23v, which is elucidated in FIG. 9 using the example of the intermediate image 23v located adjacent to the mirror M2. Thus, in relation to this virtual intermediate image 23v, it is also true in the projection optical unit 32 that the intermediate image 23v in the meridional plane yz of the projection optical unit 32 has a spatial distance from the closest GI mirror, for example the mirror M2, which is less than 10% of a distance between the object field 5 and the image field 11.

The distance d₂₃ of a further GI mirror M4 from the intermediate image 23 along the imaging beam path of the illumination light 16 is 142.78 mm in the case of the embodiment according to FIG. 9 for the projection optical unit 32.

The image field 11 is rectangular.

The following tables summarize parameters and the optical design of the projection optical unit 32. In terms of their structure, these tables correspond to those already explained above in conjunction with FIG. 2.

Table 1 for FIG. 9

| Wavelength | 13.5 | nm |
|---|---|---|
| Image-side numerical aperture | 0.30 | |
| Image field size in the x- and y- | 26 mm x 2.00 mm | |
| directions | | |
| β | −4.00 | |
| Chief ray angle | 5.00° | |
| Étendue | 4.68 | mm² |
| Mean wavefront aberration RMS | 17.29 | mλ |
| Overall transmission | 11.73% | |
| Position of the entrance pupil (x) | −1281.46 | mm |
| Position of the entrance pupil (y) | −363.08 | mm |
| Object-image offset in the y-direction | 1029.95 | mm |
| Distance between M5 and image plane | 64 | mm |
| Distance between the object plane and | 1650.86 | mm |

| image plane | |
|---|---|
| Tilt between the object and | −0.1° |
| Image plane | |
| Installation space cuboid | (481 × 1266 × 1378) mm |

Table 2a for FIG. 9

| | M1 | M2 | M3 |
|---|---|---|---|
| Maximum angle of incidence [°] | 21.1 | 81.2 | 11.4 |
| Minimum angle of incidence [°] | 16.5 | 76.8 | 9.2 |
| Extent of the reflection surface | 439.9 | 362.4 | 199.6 |
| in the x-direction [mm] | | | |
| Extent of the reflection surface | 276.8 | 464.1 | 273.5 |
| in the y-direction [mm] | | | |
| Maximum mirror diameter [mm] | 443.8 | 492.5 | 281.7 |

Table 2b for FIG. 9

| | M4 | M5 | M6 |
|---|---|---|---|
| Maximum angle of incidence [°] | 75.5 | 24.5 | 9.3 |
| Minimum angle of incidence [°] | 71.8 | 8.4 | 2.2 |
| Extent of the reflection surface | 344.7 | 422.9 | 480.8 |
| in the x-direction [mm] | | | |
| Extent of the reflection surface | 395.7 | 141.4 | 456.7 |
| in the y-direction [mm] | | | |
| Maximum mirror diameter [mm] | 404.0 | 422.9 | 481.2 |

Table 3a for FIG. 9

| | x-distance [mm] | y-distance [mm] | z-distance [mm] |
|---|---|---|---|
| Object field | 0 | −1029.951474 | 1650.860803 |
| M1 | 0 | −904.7776233 | 205.1454886 |
| M2 | 0 | −578.1086266 | 660.4419322 |
| M3 | 0 | −431.6454255 | 1437.475091 |
| M4 | 0 | −282.5942689 | 519.5334863 |
| M5 | 0 | 89.53727048 | 91.39897412 |
| M6 | 0 | 0 | 745.8599045 |
| Stop (AS) | 0 | 89.53727048 | 91.39897412 |
| Image field | 0 | 0 | 0 |

Table 3b for FIG. 9

| | Tilt about the x- | Tilt about the y- | Tilt about the z- |
|---|---|---|---|
| | axis [degrees] | axis [degrees] | axis [degrees] |
| Object field | −0.051520958 | 0 | 0 |
| M1 | −15.35522267 | 180 | 0 |
| M2 | 246.833309 | 0 | 0 |
| M3 | −0.725762772 | 0 | 180 |
| M4 | 115.1099371 | 0 | 0 |
| M5 | 24.39362748 | 180 | 0 |
| M6 | 3.895156415 | 0 | 0 |
| Stop (AS) | 23.7156209 | 0 | 0 |
| Image field | 0 | 0 | 0 |

Table 4 for FIG. 9

| x**i * y**j | Coefficient |
|---|---|
| M1 | |
| RDX | −2160.405255 |
| RDY | −1172.552925 |
| CCX | 0 |
| CCY | 0 |
| x**2*y**1 | −1.24171E−08 |
| x**0*y**3 | −4.23603E−07 |
| x**4*y**0 | −2.76759E−12 |
| x**2*y**2 | −1.37758E−10 |
| x**0*y**4 | −5.09684E−10 |
| x**4*y**1 | −2.16082E−14 |
| x**2*y**3 | −2.42419E−13 |
| x**0*y**5 | −1.53046E−12 |
| x**6*y**0 | −2.82478E−18 |
| x**4*y**2 | −5.91171E−17 |
| x**2*y**4 | −7.04971E−16 |
| x**0*y**4 | −3.48715E−15 |
| x**6*y**1 | −1.21828E−20 |
| x**4*y**3 | −2.45563E−19 |
| x**2*y**5 | −1.475E−18 |
| x**0*y**7 | −9.52033E−18 |
| x**8*y**0 | 6.28189E−23 |
| x**6*y**2 | 8.49975E−22 |
| x**4*y**4 | 1.0267E−21 |
| x**2*y**6 | −3.23832E−21 |
| x**0*y**8 | 3.52626E−22 |
| x**8*y**1 | 1.49275E−24 |
| x**6*y**3 | 7.94978E−24 |
| x**4*y**5 | 1.82643E−23 |
| x**2*y**7 | −1.57713E−23 |
| x**0*y**9 | 1.39775E−22 |
| x**10*y**0 | −9.41546E−28 |
| x**8*y**2 | −2.1153E−26 |
| x**6*y**4 | −7.3212E−26 |
| x**4*y**6 | 6.01688E−27 |
| x**2*y**8 | −1.0203E−25 |
| x**0*y**10 | −9.60066E−25 |
| x**10*y**1 | −3.70608E−29 |
| x**8*y**3 | −2.97349E−28 |
| x**6*y**5 | −1.04634E−27 |
| x**4*y**7 | 2.27444E−29 |
| x**2*y**9 | 4.01293E−29 |
| x**0*y**11 | −6.705E−27 |
| x**12*y**0 | −5.60737E−33 |
| x**10*y**2 | 3.29042E−32 |
| x**8*y**4 | 5.23605E−31 |
| x**6*y**6 | −2.38662E−30 |
| x**4*y**8 | −1.08453E−30 |
| x**2*y**10 | 1.35468E−29 |
| x**0*y**12 | 6.95928E−30 |
| x**12*y**1 | 2.90587E−34 |
| x**10*y**3 | 3.17451E−33 |
| x**8*y**5 | 1.25135E−32 |
| x**6*y**7 | 2.49175E−32 |
| x**4*y**9 | −3.12837E−32 |
| x**2*y**11 | −1.33311E−32 |
| x**0*y**13 | 4.6746E−32 |
| x**14*y**0 | 1.90028E−37 |
| x**12*y**2 | 2.29215E−36 |
| x**10*y**4 | 1.25552E−35 |
| x**8*y**6 | 6.34037E−35 |
| x**6*y**8 | 1.36798E−34 |
| x**4*y**10 | −5.40266E−35 |
| x**2*y**12 | −4.74672E−34 |
| x**0*y**14 | −1.18012E−34 |
| M2 | |
| RDX | −3355.074805 |
| RDY | 1669.044937 |
| CCX | 0 |
| CCY | 0 |
| x**2*y**1 | 2.15744E−07 |
| x**0*y**3 | 2.0978E−07 |
| x**4*y**0 | 1.57302E−11 |
| x**2*y**2 | 1.10615E−10 |
| x**0*y**4 | 1.76919E−10 |
| x**4*y**1 | 7.89643E−14 |
| x**2*y**3 | 2.50849E−13 |
| x**0*y**5 | 7.05533E−14 |
| x**6*y**0 | 1.85555E−17 |
| x**4*y**2 | 2.80242E−17 |
| x**2*y**4 | −2.99236E−17 |
| x**0*y**4 | 1.05078E−16 |
| x**6*y**1 | −1.48525E−19 |
| x**4*y**3 | 3.19596E−19 |
| x**2*y**5 | −7.85502E−19 |
| x**0*y**7 | −1.13063E−18 |
| x**8*y**0 | 5.35696E−23 |
| x**6*y**2 | −3.3837E−21 |
| x**4*y**4 | −3.05196E−21 |
| x**2*y**6 | −5.37214E−21 |
| x**0*y**8 | −1.60875E−20 |
| x**8*y**1 | −9.79265E−24 |
| x**6*y**3 | −2.08041E−23 |
| x**4*y**5 | −2.58835E−23 |
| x**2*y**7 | −2.57087E−23 |
| x**0*y**9 | −5.75694E−23 |
| x**10*y**0 | −5.70336E−26 |
| x**8*y**2 | 2.72587E−26 |
| x**6*y**4 | 6.69201E−26 |
| x**4*y**6 | −1.15809E−25 |
| x**2*y**8 | −1.0253E−25 |
| x**0*y**10 | 5.996E−26 |
| x**10*y**1 | 2.54283E−28 |
| x**8*y**3 | 8.88769E−28 |
| x**6*y**5 | 1.56859E−27 |
| x**4*y**7 | −3.08795E−28 |
| x**2*y**9 | −1.58449E−28 |
| x**0*y**11 | 7.0035E−28 |
| x**12*y**0 | 2.8143E−30 |
| x**10*y**2 | 6.75951E−30 |
| x**8*y**4 | 6.91749E−30 |
| x**6*y**6 | 7.29882E−30 |
| x**4*y**8 | 1.79029E−30 |
| x**2*y**10 | 6.76418E−31 |
| x**0*y**12 | 5.30614E−31 |
| x**12*y**1 | −2.069E−34 |
| x**10*y**3 | −8.95033E−33 |
| x**8*y**5 | −1.67906E−32 |
| x**6*y**7 | −1.70647E−32 |
| x**4*y**9 | 1.17347E−32 |
| x**2*y**11 | 4.60897E−33 |
| x**0*y**13 | −3.12162E−33 |
| x**14*y**0 | −4.28095E−35 |
| x**12*y**2 | −1.55672E−34 |
| x**10*y**4 | −2.58572E−34 |
| x**8*y**6 | −2.57417E−34 |
| x**6*y**8 | −1.1975E−34 |
| x**4*y**10 | 1.33585E−35 |
| x**2*y**12 | 8.29842E−36 |
| x**0*y**14 | −5.03277E−36 |
| M3 | |
| RDX | 1129.619661 |
| RDY | −1414.159443 |
| CCX | 0 |
| CCY | 0 |
| x**2*y**1 | −4.66775E−08 |
| x**0*y**3 | 1.42711E−07 |
| x**4*y**0 | 1.45165E−10 |
| x**2*y**2 | −1.46275E−10 |
| x**0*y**4 | −2.27366E−10 |
| x**4*y**1 | −2.10037E−13 |
| x**2*y**3 | 5.70819E−13 |
| x**0*y**5 | −2.84924E−13 |
| x**6*y**0 | 4.23622E−16 |
| x**4*y**2 | −6.54588E−16 |
| x**2*y**4 | 2.4435E−15 |
| x**0*y**4 | −3.4197E−15 |
| x**6*y**1 | −6.98834E−19 |
| x**4*y**3 | −4.66446E−18 |
| x**2*y**5 | 1.20568E−17 |
| x**0*y**7 | 5.00711E−18 |
| x**8*y**0 | −5.01766E−20 |
| x**6*y**2 | −2.04972E−20 |
| x**4*y**4 | −2.0867E−21 |
| x**2*y**6 | 6.64208E−21 |
| x**0*y**8 | 2.1905E−19 |
| x**8*y**1 | 2.46054E−22 |
| x**6*y**3 | 7.39653E−22 |
| x**4*y**5 | 7.56294E−22 |
| x**2*y**7 | −3.84967E−22 |
| x**0*y**9 | 9.55599E−22 |
| x**10*y**0 | 8.94862E−24 |
| x**8*y**2 | 1.14364E−23 |
| x**6*y**4 | 4.63162E−24 |
| x**4*y**6 | 4.46327E−24 |
| x**2*y**8 | 7.58304E−25 |
| x**0*y**10 | −3.51065E−24 |
| x**10*y**1 | −1.29851E−26 |
| x**8*y**3 | −7.23492E−26 |
| x**6*y**5 | −1.28567E−25 |
| x**4*y**7 | −3.90546E−26 |
| x**2*y**9 | 3.66983E−26 |
| x**0*y**11 | −2.79782E−26 |
| x**12*y**0 | −7.87387E−28 |
| x**10*y**2 | −1.62851E−27 |
| x**8*y**4 | −1.42899E−27 |
| x**6*y**6 | −1.03226E−27 |
| x**4*y**8 | −3.79306E−28 |
| x**2*y**10 | 8.79007E−29 |
| x**0*y**12 | 2.48303E−29 |
| x**12*y**1 | 9.28743E−32 |
| x**10*y**3 | 1.85829E−30 |
| x**8*y**5 | 4.77139E−30 |
| x**6*y**7 | 4.33991E−30 |
| x**4*y**9 | 5.00756E−31 |
| x**2*y**11 | −9.56522E−31 |
| x**0*y**13 | 4.54075E−31 |
| x**14*y**0 | 2.74945E−32 |
| x**12*y**2 | 7.26863E−32 |
| x**10*y**4 | 1.0132E−31 |
| x**8*y**6 | 7.81441E−32 |
| x**6*y**8 | 4.29902E−32 |
| x**4*y**10 | 8.57192E−33 |
| x**2*y**12 | −3.9202E−33 |
| x**0*y**14 | 7.40843E−34 |
| M4 | |
| RDX | −15005.6435 |
| RDY | 4046.677549 |
| CCX | 0 |
| CCY | 0 |
| x**2*y**1 | −1.56683E−07 |
| x**0*y**3 | −1.08486E−07 |
| x**4*y**0 | 7.85845E−11 |
| x**2*y**2 | −1.1431E−10 |
| x**0*y**4 | 2.93502E−10 |
| x**4*y**1 | 1.46137E−13 |
| x**2*y**3 | −3.10591E−13 |
| x**0*y**5 | −5.90563E−13 |
| x**6*y**0 | 8.64798E−20 |
| x**4*y**2 | 1.66035E−16 |
| x**2*y**4 | 5.86133E−17 |
| x**0*y**4 | 1.90481E−15 |
| x**6*y**1 | 3.57373E−19 |
| x**4*y**3 | 7.13714E−19 |
| x**2*y**5 | −1.18154E−18 |
| x**0*y**7 | −6.71009E−18 |
| x**8*y**0 | 3.1839E−21 |
| x**6*y**2 | 2.99497E−21 |
| x**4*y**4 | −1.80692E−21 |
| x**2*y**6 | 3.00542E−22 |
| x**0*y**8 | 7.45813E−21 |
| x**8*y**1 | −1.88787E−23 |
| x**6*y**3 | −4.57233E−23 |
| x**4*y**5 | −3.09117E−23 |
| x**2*y**7 | −1.28801E−23 |
| x**0*y**9 | 5.71769E−24 |
| x**10*y**0 | −1.4944E−25 |
| x**8*y**2 | −3.74889E−25 |
| x**6*y**4 | −1.73827E−25 |
| x**4*y**6 | −2.30579E−27 |
| x**2*y**8 | 2.84823E−26 |
| x**0*y**10 | 2.20021E−26 |
| x**10*y**1 | 4.3374E−28 |
| x**8*y**3 | 1.4304E−27 |
| x**6*y**5 | 1.70693E−27 |
| x**4*y**7 | 3.68435E−28 |
| x**2*y**9 | −4.44235E−28 |
| x**0*y**11 | −4.30045E−28 |
| x**12*y**0 | 3.66415E−30 |
| x**10*y**2 | 1.2754E−29 |
| x**8*y**4 | 1.4717E−29 |
| x**6*y**6 | 8.25725E−30 |
| x**4*y**8 | 1.72152E−30 |
| x**2*y**10 | 1.21857E−30 |
| x**0*y**12 | 1.41774E−30 |
| x**12*y**1 | −4.34531E−33 |
| x**10*y**3 | −1.5396E−32 |
| x**8*y**5 | −2.13187E−32 |
| x**6*y**7 | −1.05231E−32 |
| x**4*y**9 | 3.35655E−33 |
| x**2*y**11 | 5.4647E−33 |
| x**0*y**13 | 1.47249E−34 |
| x**14*y**0 | −3.60572E−35 |
| x**12*y**2 | −1.45019E−34 |
| x**10*y**4 | −2.62971E−34 |
| x**8*y**6 | −2.41625E−34 |
| x**6*y**8 | −1.07797E−34 |
| x**4*y**10 | −2.73565E−35 |
| x**2*y**12 | −1.70797E−35 |
| x**0*y**14 | −4.70225E−36 |
| M5 | |
| RDX | −5902.397175 |
| RDY | 630.803537 |
| CCX | 0 |
| CCY | 0 |
| x**2*y**1 | 3.23386E−07 |
| x**0*y**3 | −1.55965E−06 |
| x**4*y**0 | 9.67425E−11 |
| x**2*y**2 | 4.05058E−10 |
| x**0*y**4 | 2.84851E−09 |
| x**4*y**1 | 2.63108E−13 |
| x**2*y**3 | 2.16733E−12 |
| x**0*y**5 | 4.20054E−12 |
| x**6*y**0 | 9.76343E−17 |
| x**4*y**2 | 1.22629E−15 |
| x**2*y**4 | −2.87287E−15 |
| x**0*y**4 | −1.21074E−13 |
| x**6*y**1 | 3.11977E−19 |
| x**4*y**3 | −6.38941E−19 |
| x**2*y**5 | −4.0813E−17 |
| x**0*y**7 | 1.04797E−15 |
| x**8*y**0 | −9.85929E−23 |
| x**6*y**2 | −1.05715E−21 |
| x**4*y**4 | 2.11091E−20 |
| x**2*y**6 | 8.00434E−19 |
| x**0*y**8 | 3.81021E−18 |
| x**8*y**1 | 3.01258E−24 |
| x**6*y**3 | 8.072E−23 |
| x**4*y**5 | 6.78483E−22 |
| x**2*y**7 | 1.06297E−20 |
| x**0*y**9 | −6.92393E−20 |
| x**10*y**0 | 5.30973E−27 |
| x**8*y**2 | 1.68824E−25 |
| x**6*y**4 | 7.96565E−25 |
| x**4*y**6 | 4.11922E−24 |
| x**2*y**8 | −8.23089E−23 |
| x**0*y**10 | 2.73419E−22 |
| x**10*y**1 | −2.0731E−29 |
| x**8*y**3 | −1.37042E−27 |
| x**6*y**5 | −1.296E−26 |
| x**4*y**7 | −5.63688E−26 |
| x**2*y**9 | −5.01941E−26 |
| x**0*y**11 | −4.06563E−24 |
| x**12*y**0 | −6.87246E−32 |
| x**10*y**2 | −3.07725E−30 |
| x**8*y**4 | −3.68306E−29 |
| x**6*y**6 | −1.35113E−28 |
| x**4*y**8 | −1.53472E−28 |
| x**2*y**10 | −3.78227E−27 |
| x**0*y**12 | 3.3708E−26 |
| x**12*y**1 | 6.24685E−35 |
| x**10*y**3 | 8.38098E−33 |
| x**8*y**5 | 8.5836E−32 |
| x**6*y**7 | 2.91838E−31 |
| x**4*y**9 | −2.57186E−30 |
| x**2*y**11 | 3.7924E−29 |
| x**0*y**13 | −9.74773E−29 |
| x**14*y**0 | 3.71346E−37 |
| x**12*y**2 | 1.90839E−35 |
| x**10*y**4 | 3.45926E−34 |
| x**8*y**6 | 2.98437E−33 |
| x**6*y**8 | 5.63404E−33 |
| x**4*y**10 | 1.08805E−32 |
| x**2*y**12 | −5.34833E−32 |
| x**0*y**14 | 1.46397E−31 |
| M6 | |
| RDX | −1394.572174 |
| RDY | −831.0901715 |
| CCX | 0 |
| CCY | 0 |
| x**2*y**1 | −4.55419E−08 |
| x**0*y**3 | 3.67064E−08 |
| x**4*y**0 | −3.1125E−11 |
| x**2*y**2 | −1.0037E−10 |
| x**0*y**4 | 4.74264E−12 |
| x**4*y**1 | −2.71248E−14 |
| x**2*y**3 | −4.21715E−14 |
| x**0*y**5 | 2.44791E−14 |
| x**6*y**0 | −2.70501E−17 |
| x**4*y**2 | −1.29025E−16 |
| x**2*y**4 | −1.45034E−16 |
| x**0*y**4 | −5.08747E−18 |
| x**6*y**1 | −1.77755E−20 |
| x**4*y**3 | −6.72263E−20 |
| x**2*y**5 | −5.70077E−21 |
| x**0*y**7 | 4.62028E−20 |
| x**8*y**0 | 4.69132E−23 |
| x**6*y**2 | 2.55592E−24 |
| x**4*y**4 | −2.50469E−22 |
| x**2*y**6 | −1.88893E−22 |
| x**0*y**8 | −2.92386E−22 |
| x**8*y**1 | −2.06961E−25 |
| x**6*y**3 | −6.55041E−25 |
| x**4*y**5 | −6.8029E−25 |
| x**2*y**7 | −1.39331E−24 |
| x**0*y**9 | −1.7148E−24 |
| x**10*y**0 | −1.41164E−27 |
| x**8*y**2 | −5.70847E−27 |
| x**6*y**4 | −6.86661E−27 |
| x**4*y**6 | −5.16124E−27 |
| x**2*y**8 | −6.45644E−27 |
| x**0*y**10 | −4.31102E−27 |
| x**10*y**1 | 1.78309E−30 |
| x**8*y**3 | 7.88097E−30 |
| x**6*y**5 | 1.07249E−29 |
| x**4*y**7 | −9.8944E−31 |
| x**2*y**9 | −3.34689E−30 |
| x**0*y**11 | 1.45239E−29 |
| x**12*y**0 | 1.5404E−32 |
| x**10*y**2 | 8.42293E−32 |
| x**8*y**4 | 1.58576E−31 |
| x**6*y**6 | 1.55737E−31 |
| x**4*y**8 | 7.12643E−32 |
| x**2*y**10 | 4.43445E−32 |
| x**0*y**12 | 6.88945E−32 |
| x**12*y**1 | −7.75048E−36 |
| x**10*y**3 | −4.48548E−35 |
| x**8*y**5 | −4.53242E−35 |
| x**6*y**7 | −3.79535E−36 |
| x**4*y**9 | 9.1168E−35 |
| x**2*y**11 | 4.50783E−35 |
| x**0*y**13 | 4.50486E−36 |
| x**14*y**0 | −6.84399E−38 |
| x**12*y**2 | −4.486E−37 |
| x**10*y**4 | −1.21023E−36 |
| x**8*y**6 | −1.58315E−36 |
| x**6*y**8 | −1.0257E−36 |
| x**4*y**10 | −2.04764E−37 |
| x**2*y**12 | −1.92856E−37 |
| x**0*y**14 | −2.25644E−37 |

Table 5 for FIG. 9

| x [mm] | y [mm] |
|---|---|
| 211.6797261 | −3.765204162 |
| 206.6453808 | 10.28786489 |
| 193.6252443 | 24.88686515 |
| 173.2801602 | 39.32500559 |
| 146.5494877 | 52.77566437 |
| 114.5714742 | 64.3745741 |
| 78.60578471 | 73.32362619 |
| 39.97032321 | 78.9784328 |
| 1.25342E−14 | 80.91354717 |
| −39.97032321 | 78.9784328 |
| −78.60578471 | 73.32362619 |
| −114.5714742 | 64.3745741 |
| −146.5494877 | 52.77566437 |
| −173.2801602 | 39.32500559 |
| −193.6252443 | 24.88686515 |
| −206.6453808 | 10.28786489 |
| −211.6797261 | −3.765204162 |
| −208.4103542 | −16.72697287 |
| −196.896086 | −28.22209826 |
| −177.5717796 | −38.02802678 |
| −151.2174051 | −46.03899397 |
| −118.9053839 | −52.22601547 |
| −81.93720628 | −56.60448274 |
| −41.7787258 | −59.20928286 |
| −3.93407E−14 | −60.07314149 |
| 41.7787258 | −59.20928286 |
| 81.93720628 | −56.60448274 |
| 118.9053839 | −52.22601547 |
| 151.2174051 | −46.03899397 |
| 177.5717796 | −38.02802678 |
| 196.896086 | −28.22209826 |
| 208.4103542 | −16.72697287 |

In the projection optical unit 32, there is no intermediate image between the object field 5 and the image field 11. Thus, in the case of the projection optical unit 32, the image plane 12 is the first field plane downstream of the object plane 6 in the imaging beam path, both for the meridional plane and for the sagittal plane perpendicular to the meridional plane.

In the projection optical unit 32, the NI mirror M6 is located between the two GI mirrors M2, M4. The two GI mirrors M2 and M4 are each located in the vicinity of virtual intermediate images.

Depending on the embodiment of the above-described projection optical units, these may also have a different number of NI mirrors and/or GI mirrors, for example precisely one GI mirrors or else precisely three GI mirrors. Fewer or more than four NI mirrors are also possible, for example two, three or five NI mirrors.

In order to produce a microstructured or nanostructured component, the projection exposure apparatus 1 is used as follows: First, the reflection mask 7 or the reticle and the substrate or the wafer 13 are provided. Subsequently, a structure on the reticle 7 is projected onto a light-sensitive layer of the wafer 13 with the aid of the projection exposure apparatus 1. Then, a microstructure or nanostructure on the wafer 13, and hence the microstructured component, is produced by developing the light-sensitive layer.

What is claimed is:

1. An imaging EUV optical unit configured to image an object field in an object plane into an image field in an image plane, the imaging EUV optical unit comprising:
a plurality of mirrors configured to guide EUV imaging light along an imaging beam path from the object field towards the image field, wherein:
the EUV imaging light has a wavelength of less than 30 nanometers;
the plurality of mirrors comprises two normal incidence (NI) mirrors and two grazing incidence (GI) mirrors;
the plurality of mirrors comprises a last mirror in the imaging beam path, a penultimate mirror in the imaging beam path and an antepenultimate mirror in the imaging beam path;
the penultimate mirror is an NI mirror lacking a passage opening for the imaging light;
the last mirror is an NI mirror lacking a passage opening for the imaging light;
the antepenultimate mirror comprises a reflection surface facing the last mirror; and
an overall transmission of the plurality of mirrors for the EUV imaging light is greater than 10%.

2. The imaging EUV optical unit of claim 1, wherein:
the imaging EUV optical unit has an object-image offset between a central object field point and a central image field point perpendicular to a normal of the object plane; and
the object-image offset is less than a distance between the object field and the image field.

3. The imaging EUV optical unit of claim 1, wherein:
the imaging EUV optical unit has an intermediate image in an imaging light plane containing a chief ray of a central field point; and
at least one of the GI mirror has a distance from the intermediate image along the imaging beam path which is less than 10% of a distance between the object field and the image field.

4. The imaging EUV optical unit of claim 1, wherein the penultimate mirror and the last mirror add in terms of their deflection effect for a chief ray of a central object field point.

5. The imaging EUV optical unit of claim 1, wherein the plurality of mirrors comprises at least four NI mirrors.

6. The imaging EUV optical unit of claim 1, wherein the plurality of mirrors comprises exactly two GI mirrors.

7. The imaging EUV optical unit of claim 1, wherein:
the imaging EUV optical unit has an intermediate image in a meridional plane of the imaging EUV optical unit; and
the intermediate image has a spatial distance from the last mirror which is less than 60% of a maximum extent of the last mirror in the meridional plane.

8. The imaging EUV optical unit of claim 1, wherein the imaging EUV optical unit has a meridional plane which is perpendicular to the image plane, and the image plane is the first field plane downstream of an object plane.

9. The imaging EUV optical unit of claim 1, wherein the overall transmission of the plurality of mirrors for the EUV imaging light is greater than 11%.

10. The imaging EUV optical unit of claim 1, wherein the image field has a maximum extent of greater than 26 millimeters in the image plane.

11. The imaging EUV optical unit of claim 1, wherein:
the imaging EUV optical unit has an object-image offset between a central object field point and a central image field point perpendicular to a normal of the object plane;
the object-image offset is less than a distance between the object field and the image field;
the imaging EUV optical unit has an intermediate image in an imaging light plane containing a chief ray of a central field point; and
at least one of the GI mirror has a distance from the intermediate image along the imaging beam path which is less than 10% of a distance between the object field and the image field.

12. The imaging EUV optical unit of claim 1, wherein:
the imaging EUV optical unit has an object-image offset between a central object field point and a central image field point perpendicular to a normal of the object plane;
the object-image offset is less than a distance between the object field and the image field; and
the penultimate mirror and the last mirror add in terms of their deflection effect for a chief ray of a central object field point.

13. The imaging EUV optical unit of claim 1, wherein:
the imaging EUV optical unit has an object-image offset between a central object field point and a central image field point perpendicular to a normal of the object plane;
the object-image offset is less than a distance between the object field and the image field; and
the plurality of mirrors comprises at least four NI mirrors.

14. The imaging EUV optical unit of claim 13, wherein:
the imaging EUV optical unit has an object-image offset between a central object field point and a central image field point perpendicular to a normal of the object plane;
the object-image offset is less than a distance between the object field and the image field; and
the plurality of mirrors comprises exactly two GI mirrors.

15. The imaging EUV optical unit of claim 1, wherein:
the imaging EUV optical unit has an object-image offset between a central object field point and a central image field point perpendicular to a normal of the object plane;
the object-image offset is less than a distance between the object field and the image field; and
the plurality of mirrors comprises exactly two GI mirrors.

16. The imaging EUV optical unit of claim 1, wherein:
the imaging EUV optical unit has an object-image offset between a central object field point and a central image field point perpendicular to a normal of the object plane;
the object-image offset is less than a distance between the object field and the image field;
the imaging EUV optical unit has a meridional plane which is perpendicular to the image plane; and
the image plane is the first field plane downstream of an object plane.

17. The imaging EUV optical unit of claim 1, wherein the plurality of mirrors comprises at least four NI mirrors and exactly two GI mirrors.

18. An optical system, comprising:
an illumination optical unit configured to illuminate an object field in an object plane with the imaging light; and
an imaging EUV optical unit according to claim 1.

19. An apparatus, comprising:
an EUV light source;
an illumination optical unit configured to illuminate an object field in an object plane with the imaging light; and
an imaging EUV optical unit according to claim 1,
wherein the apparatus is a projection exposure apparatus.

20. A method of using a projection exposure apparatus comprising an illumination optical unit and an imaging EUV optical unit, the method comprising:
using the illumination optical unit to illuminate an object in an object field in an object plane; and
using the imaging EUV optical unit to image the object into an image field in an image plane,
wherein the imaging EUV optical unit is an imaging EUV optical unit according to claim 1.
